(19) United States
(12) Patent Application Publication
(10) Pub. No.: US 2026/0289028 A1
(43) Pub. Date: Sep. 24, 2026

(54) AUTOMATED DETERMINATION OF AIRFLOW RELATED OBJECTIVE IN A BUILDING DESIGN PLAN

(71) Applicant: Togal.AI Inc., Miami, FL (US)

(72) Inventors: Patrick E Murphy, Miami, FL (US); Johnny Maghzal, Miami, FL (US)

(73) Assignee: Togal.AI Inc., Miami, FL (US)

(21) Appl. No.: 19/473,339

(22) PCT Filed: Aug. 30, 2024
(86) PCT No.: PCT/US2024/044838

§ 371 Date: Oct. 7, 2025

Related U.S. Application Data
(60) Provisional application No. 63/535,609, filed on Aug. 31, 2023.

(51) Int. Cl. G06F 30/13; G06F 30/12

(52) U.S. Cl. CPC G06F 30/13; G06F 30/12

(57) ABSTRACT

Methods and apparatus are provided for automated analysis of airflow objectives in architectural design plans using artificial intelligence (AI). A controller evaluates design plans, such as floor plans or architectural drawings, to identify, classify, and assess the placement, type, and configuration of airflow components, including air supply and exhaust vents, ducts, and HVAC systems. The controller examines these components against relevant building deployment objectives and preferred practices, evaluating spatial relationships, airflow patterns, and system configurations. When non-compliance is detected, the system generates automated suggestions for design revisions and optimizations, in order to facilitate adherence to building deployment objectives and functional efficiency before construction begins. The apparatus includes interactive tools for real-time simulation and collaboration, allowing designers, architects, and others to make informed adjustments to the design to achieve optimal airflow management and compliance with building deployment objectives.

### CROSS REFERENCE TO RELATED APPLICATIONS

This application is a U.S. National Phase of International Application Number PCT/US24/44838, which was filed Aug. 30, 2024, and entitled AUTOMATED DETERMINATION OF AIRFLOW RELATED OBJECTIVE IN A BUILDING DESIGN PLAN, which claims priority to U.S. Provisional Application No. 63/535,609, filed Aug. 31, 2023, and entitled ARTIFICIAL INTELLIGENCE DETERMINATION OF AIRFLOW RELATED REQUIREMENTS IN CONSTRUCTION OF A BUILDING, the entire disclosures of each of which is incorporated herein by reference.

### FIELD OF THE INVENTION

The present invention provides improved methods and apparatus for analyzing airflow compliance within building design plans using artificial intelligence (AI) technologies. The invention specifically relates to systems and methods that assess the adequacy of airflow fixtures, such as air supply and return vents, exhaust fans, windows, and HVAC ducts, within various spaces in a building. These systems evaluate whether the placement, size, and number of these fixtures meet the requirements of relevant building deployment objectives. The invention further involves generating interactive user interfaces that allow users to visualize and modify the compliance status of the airflow systems in real-time. Additionally, the invention encompasses the use of databases storing information on airflow and non-airflow fixtures, as well as relevant building deployment objectives, to support comprehensive compliance analysis.

### BACKGROUND OF THE INVENTION

For a building to be suitable for occupants, it is essential to implement air handling systems such as HVAC and air filtration systems within the building. These systems regulate the movement of air within the building, maintaining indoor air quality, and removing contaminants and particles from the air to enhance the health and comfort of occupants. By controlling temperature and humidity, these systems create a stable indoor climate, while their filtration capabilities help eliminate pollutants and contaminants, contributing significantly to occupant health and well-being. Additionally, these systems provide vital ventilation by exchanging stale indoor air with fresh outdoor air, thereby preventing issues such as mold growth and excessive moisture. Efficient air handling also contributes to energy conservation and facilitates compliance with indoor air quality and safety standards as required by building deployment objectives.

During conceptual building design for construction, balancing effective air management and control with aesthetics is sometimes more art than science and often involves an inefficient iterative process. Many variables, from walls and openings to areas and volumes of rooms, to ventilation, climate, and building contents, all contribute to the ability of a building to provide the desired management of calculated volumes of air.

Therefore, the regulation of airflow management in buildings is governed by a complex framework of preferred practices designed to protect public health, safety, and welfare. These preferred practices, particularly those in the United States, have evolved over time in response to the growing recognition of the risks associated with improper HVAC system design, installation, and maintenance. The airflow-related preferred practices provide a comprehensive set of rules that dictate how HVAC systems should be designed, installed, and maintained within a building. These rules encompass a wide range of aspects, including air distribution, ventilation rates, exhaust requirements, and the placement of air supply and return fixtures. The primary goal of these regulations is to maintain adequate indoor air quality, maintain comfortable environmental conditions for building occupants, and prevent the buildup of harmful contaminants, and.

In the United States, the most widely adopted HVAC-related preferred practices include the International Mechanical Code (IMC) and standards set by organizations such as the American Society of Heating, Refrigerating and Air-Conditioning Engineers (ASHRAE), including ASHRAE 62.1 and 62.2. These preferred practices provide detailed guidelines on various aspects of HVAC design, such as the minimum ventilation rates, the placement of air intakes and exhausts, and the proper sizing of ducts and equipment. While the IMC is commonly used in many states across the country, ASHRAE standards are often preferred for their comprehensive coverage of indoor air quality and ventilation requirements. These preferred practices are periodically updated to reflect new technologies, materials, and methods in HVAC design, as well as to address emerging concerns related to energy efficiency, environmental impact, and occupant health. In addition to these preferred practices, local jurisdictions may have their own regulations that supplement or modify the national preferred practices to address specific regional issues, such as climate conditions or air quality concerns.

Internationally, HVAC regulations vary widely from one country to another, depending on factors such as climate, building practices, and the availability of resources. For example, the European Union has its own set of ventilation practices, which are largely harmonized across member states but allow for some variation at the national level. In countries like India, specific preferred practices, such as the National Building Code (NBC) published by Bureau of Indian Standards (BIS) and Energy Conservation Building Code (ECBC) published by Bureau of energy efficiency, guides HVAC practices, providing requirements for everything from ventilation rates to the placement of exhaust fans. In many developing countries, however, HVAC regulations may be less stringent or less consistently enforced, leading to a higher incidence of non-compliant HVAC installations that pose risks to public health and building performance.

The need for HVAC compliance arises from the potential hazards associated with non-compliant airflow management systems. For example, if a building's ventilation system is not properly designed or maintained, there is a risk of inadequate fresh air supply, leading to poor indoor air quality, which can cause respiratory issues and other health problems for occupants. Similarly, improper exhaust system design can result in the buildup of harmful contaminants, such as carbon monoxide or radon, inside the building. The improper installation of HVAC components, such as air ducts, vents, and filters, can lead to inefficiencies, such as uneven temperature distribution, increased energy consumption, and system malfunctions, all of which can compromise the comfort and safety of building occupants.

Examples of compliant HVAC installations include the correct placement of air supply and exhaust vents to provide balanced airflow, the use of properly sized ducts and equipment to maintain consistent ventilation rates, and the integration of air filtration systems that meet the required building deployment objectives for indoor air quality. In contrast, non-compliant HVAC installations may involve the use of substandard materials that are prone to leakage or failure, the incorrect sizing of ducts that restrict airflow or lead to pressure imbalances, or the absence of necessary ventilation components, which can result in insufficient air circulation and the buildup of pollutants. These issues are often exacerbated by the lack of regular maintenance, leading to the gradual deterioration of the HVAC system over time.

The consequences of non-compliant HVAC systems can be severe, affecting not only the occupants of a building but also the wider community. For example, in areas where outdoor air quality is poor, non-compliant HVAC systems can exacerbate the problem by failing to filter out pollutants or by improperly recirculating contaminated air. In addition, the presence of non-compliant HVAC systems in a building can lead to costly repairs and renovations, as well as legal liabilities for property owners and contractors. In some cases, buildings with significant HVAC deficiencies may be deemed uninhabitable, resulting in the displacement of occupants and the loss of property value. Furthermore, non-compliant HVAC systems can have environmental impacts, such as increased energy consumption or the release of untreated exhaust into the atmosphere, which can contribute to environmental degradation and climate change.

Traditionally, for determinization of HVAC compliance, proposed design plans are physically and visually inspected one by one by a highly skilled workers such as engineers, architects, and building inspectors to ascertain compliance with desired airflow specifications. Determination of how to manage airflow within a building represented by a design plan may be complicated by various devices and/or equipment deployed at locations within a building, as represented on a design plan. Therefore, this process of the detailed review of the design plans and specifications for a building's HVAC system, followed by on-site inspections during and after construction to verify that the installation, meets the required building deployment objectives. This manual approach relies heavily on the expertise and experience of the professionals involved, who must be familiar with the relevant building deployment objectives, as well as the specific requirements of the project. They must also be able to identify potential issues and recommend corrective actions to bring the HVAC system into compliance.

However, the manual determination of HVAC compliance has several limitations. First, such manual processes are incredibly time intensive, as it requires a thorough examination of all aspects of the HVAC system, including air supply, exhaust, ventilation rates, and the installation of equipment. This process can be particularly challenging in large or complex buildings, where the HVAC system may involve multiple levels, zones, and subsystems. Second, it is often difficult to locate skilled personnel with the correct credentials to complete an analysis of a building design for the many types of building use. Third, even after hiring a skilled person, the manual process is still prone to human error, as even experienced professionals may overlook useful details or make incorrect assumptions about the design or installation. These errors can lead to the approval of non-compliant HVAC systems, which may not be detected until after the building is occupied, at which point corrective measures can be costly and disruptive. In addition, different workers may have slightly different approaches and interpretations of a design plan.

Another challenge associated with the manual determination of HVAC compliance is the variability in interpretations of the building deployment objectives. Different professionals may have different interpretations of the same building deployment objective provisions, leading to inconsistencies in the application of the building deployment objectives. This can result in disparities in the level of compliance across different projects, as well as disputes between contractors, inspectors, and property owners. Moreover, the manual approach does not easily lend itself to the tracking and documentation of compliance over time, which can be considered for long-term maintenance and liability purposes. As a result, many systems to move (or otherwise manage) airflow are subjective in nature.

The advent of digital technologies has opened up new possibilities for improving the process of determining HVAC compliance. Computer-aided design (CAD) software, building information modeling (BIM) systems, and other digital tools can facilitate the design and review of HVAC systems by allowing professionals to visualize the system in three dimensions, simulate its performance, and identify potential issues before construction begins. These tools can also help standardize the application of the building deployment objectives by providing built-in checks and validations against the relevant building deployment objectives. However, while these technologies represent a significant improvement over traditional manual methods, they still require significant input from skilled professionals and may not completely eliminate the risk of human error.

One of the needs in the field of HVAC compliance is the development of automated systems that can quickly and accurately determine whether an HVAC design or installation meets the required building deployment objectives. Such systems may need to be able to analyze a wide range of factors, including the layout and sizing of ducts, the placement and installation of vents and equipment, and the overall configuration of the HVAC system. They may also need to be capable of assessing the system's performance under various conditions, such as different temperatures, humidity levels, and occupancy rates, to determine if it functions as intended in all scenarios.

Another area where improvement is needed is in the integration of HVAC compliance determination with other aspects of building design and construction. For example, HVAC systems are often closely related to other building systems, such as the structural, electrical, and plumbing systems. Therefore, a comprehensive approach to compliance determination should consider the interactions between these systems to identify potential conflicts or issues that may affect the overall performance and safety of the building.

In addition to improving the accuracy and efficiency of HVAC compliance determination, there is also a need to enhance the transparency and accountability of the process. This may involve the use of digital records and documentation that provide a clear and auditable trail of the compliance determination process, from the initial design review to the final inspection and approval. Such records can be used to track the performance of the HVAC system over time, identify any issues that arise after the building is occupied, and provide evidence in the event of disputes or legal challenges.

Furthermore, the development of automated HVAC compliance systems can also support the training and education of professionals in the field. By providing real-time feedback and guidance, these systems can help engineers, architects, and inspectors better understand the requirements of the building deployment objectives and how to apply them in practice. This can lead to a higher standard of compliance across the industry, as well as a reduction in the number of errors and issues that arise during the design and construction process.

In conclusion, while traditional methods of determining HVAC compliance have served the industry well for many years, there is a clear need for improvement in terms of speed, accuracy, and consistency. The use of advanced digital technologies, such as AI and integrated design tools, offers the potential to transform the process of HVAC compliance determination, making it faster, more reliable, and less prone to human error. By addressing these needs, the industry can not only enhance the safety and performance of HVAC systems but also reduce the costs and risks associated with non-compliant installations, ultimately benefiting both building owners and occupants.

### SUMMARY OF THE DISCLOSURE

Accordingly, the present disclosure provides methods and apparatus for the analysis of two-dimensional (“2D”) or three dimensional (“3D”)references, including but not limited to floorplans, design plans, and blueprints, utilizing artificial intelligence (AI) to evaluate and optimize airflow management, air quality, and overall air circulation within a building.

Specifically, the present invention uses AI to auto-detect, measure, and classify various components within building plans, assessing whether the design's air management systems meet the standards set forth by user objectives.

In some specific examples, the invention employs machine learning and AI to identify architectural features such as elevator shafts, open upper stories, atriums, and other elements that pose challenges to effective airflow control. The invention not only identifies these architectural elements but also predicts their impact on airflow dynamics. Additionally, the AI-driven system may offer recommendations to modify the proposed or existing design to achieve optimal airflow management, enhancing the building's capability to handle air distribution efficiently.

In some embodiments of the present invention, a method is provided for analyzing airflow compliance in building design plans using an AI-driven system. The method begins with the controller receiving a design plan, which may include various architectural layouts such as floor plans or blueprints for at least a portion of a building. The controller then processes this design plan, breaking it down into multiple dynamic components that represent different elements of the building's layout, such as rooms, doors, HVAC systems, and ventilation components. These dynamic components are displayed on a first interactive user interface, where each component's parameters, such as dimensions, positions, and types, can be adjusted by the user.

The AI engine, integrated within the controller, then performs an analysis of the design plan to identify specific airflow components. These components may include air conditioners, ductwork, vents, and exhaust fans. Once identified, the AI engine determines both the type and quantity of these components within the design. For example, in a commercial office layout, the AI engine may identify multiple air conditioning units and ventilation ducts, catalog their exact types and locations, and determine if the airflow configuration meets the expected ventilation and cooling requirements.

Following this, the AI engine analyzes the spatial relationships and dimensions associated with these airflow components. It calculates useful metrics such as the distances between vents, the height and placement of air conditioning units, and the clearance around each component to determine if they meet necessary airflow related building deployment objectives. For example, the AI engine may evaluate whether the spacing of vents provides adequate airflow to all areas of a room or if the height of an air conditioning unit is appropriate for optimal performance.

Based on either user input or AI-driven analysis of the design plan (e.g., markings on the design plan), the system determines the proposed use of the portion of the building. This may range from residential to commercial or institutional use, each carrying different airflow and ventilation requirements. The AI engine then cross-references the determined proposed use with a set of conditions mandated by the relevant building deployment objectives. These conditions may include specifics such as the minimum required airflow rates, the acceptable types of ventilation systems, and the necessary placement of components, which may be dictated by the user objectives.

The AI engine then compares the identified airflow components in the design plan with the relevant building deployment objectives. It assesses whether the current design complies with the requirements set forth by objective. For example, the controller may check if a number of ventilation vents in a laboratory meets desired airflow amounts, and/or if ductwork layout is properly designed to provide efficient air distribution.

Ascertaining whether and objective is achieved may be indicated within an interactive user interface. A controller may provide visual indicators, such as a highlight to indicate whether a processed building design achieves a stated objective. For example, areas that meet an objective may be shown in green, while areas that do not meet an objective may be marked in red, allowing users to quickly identify and address issues. If the design is found to be deficient and fails to meet one or more objectives, the controller may provide suggestions for corrective actions, such as adding additional vents or adjusting the layout to improve airflow.

The present invention reduces inconsistencies in design plan analysis and mistakes. It also provides consistent feedback on the reasons why a building design will meet an objective, or which aspects of a design plan place the building design in a do not meet objectives. For example, if a design plan fails to provide proper airflow distribution or does not meet the required ventilation rates for a specified use, the AI engine will provide a detailed explanation of how the specified use will not be met. This may include identifying areas with insufficient air supply or exhaust, and suggesting corrective actions such as adding additional air vents, redistributing existing ventilation components, or modifying the layout to enhance airflow efficiency and compliance with ventilation related building deployment objectives.

Furthermore, according to some embodiments of the present invention, automated systems generate proposed modifications to achieve compliance with an applicable building deployment objective, or to adopt a best practice whether or not the best practice is required to meet an obligation dictated by a relevant building deployment objective. These modifications may include adding additional airflow components, adjusting the layout of existing components, or selecting alternative components that better meet building deployment objective requirements. For example, the AI engine may recommend installing additional air supply vents for adequate ventilation throughout the building, or suggest repositioning existing vents to improve airflow distribution and compliance with ventilation related building deployment objectives. The AI engine may also advise on the optimal placement of HVAC units and ductwork to enhance overall system efficiency and performance, and for the design to meet all relevant airflow and ventilation regulations.

A two-dimensional reference, such as a design floorplan is input into an AI engine and the AI engine converts aspects of the floorplan into components that may be processed by the AI engine, such as, for example, a rasterized version of the floorplan. The floorplan is then processed with machine learning to specify portions that may be specified as discernable components. Discernable components may include, for example, rooms, residential units, hallways, stairs, airflow paths, windows, or other discrete aspects of a building. For airflow compliance, discernible components may include specific HVAC elements, ductwork configurations, and spatial dimensions relevant to building deployment objective requirements. For example, the AI engine may identify the precise location and type of each airflow component, such as air supply vents, exhaust vents, air conditioning units, and fans, and assess their placement within the overall building design. The AI engine evaluates whether these components are positioned to provide adequate ventilation, maintain proper air circulation, and meet the standards outlined in relevant building deployment objectives.

A scaling process is applied to the floorplan and size descriptors are assigned to the discernable components. Additionally, the AI engine calculates distances relevant to airflow compliance, such as the distance between air supply vents and exhaust vents, the distance of vents from walls and other obstructions, and the placement of ducts for proper air distribution. The AI engine may also assess the angle and length of ductwork to determine if it supports efficient airflow, preventing issues like inadequate ventilation or uneven temperature distribution within the space. In addition, distances, such as, for example, the distance to an exit from the furthest point in a residential unit are calculated.

Variables are specified that will be used to assess whether an objective is met based upon values for the specified variables. In some embodiments, the variables may include some or all of: a heat load; equipment deployed within an area; occupancy load; For example, the AI engine may analyze whether the number of ducts in a heat load generated by equipment to be installed in area will be adequately cooled and provide feedback on whether the current layout meets building deployment objective requirements.

In general, the present invention provides for apparatus and methods related to receiving as input design plans (either physical or electronic) and generating one or more pixel patterns based upon automated processing of the design plans. The pixel patterns are analyzed using computerized processing techniques to mimic the perception, learning, problem-solving, and decision-making formerly performed by human workers (sometimes referred to herein as artificial intelligence or “AI”). The pixel patterns may represent various aspects of the airflow layout, including fixture placement, duct routes, and spatial relationships, which are used for determining compliance with relevant building deployment objectives.

Based upon AI analysis of pixel patterns derived from the two-dimensional references and knowledge accumulated from increasing volumes of analyzed two-dimensional references, interactive user interfaces may be generated that allow for a user to modify dynamic design plans of features gleaned from the two-dimensional reference. AI processing of the pixel patterns, based upon the two-dimensional references, may include mathematical analysis of polygons formed by joining select vectors included in the two-dimensional reference. Analysis of pixel patterns and manipulatable vector interfaces and/or polygon-based interfaces is advantageous over human processing in that AI analysis of pixel patterns, vectors and polygons is capable of leveraging knowledge gained from one or both of: a select group and learnings derived from similar previous bodies of work, whether or not a human requesting a current analysis was involved in the previous learnings. For example, the AI engine may compare the current design plan against a database of past projects to identify common compliance issues and recommend solutions based on best practices, such as optimal airflow fixture placement or efficient duct layouts.

In still another aspect, in some embodiments, enhanced interactive user interfaces may include one or more of: user definable and/or editable lines; user definable and/or editable vectors; and user definable and/or editable polygons. The interactive user interface may also be referenced to generate diagrams based on the lines, vectors and polygons defined in the interactive user interface. Still further, various embodiments include values for variables that are definable via the interactive user interface with AI processing and human input. For example, a user may adjust the slope of a duct within the interface, with the AI engine recalculating the duct's compliance with relevant building deployment objectives in real-time.

According to the present invention, analysis of pixel patterns and enhanced vector diagrams and/or polygon based diagrams may include one or more of: neural network analysis, opposing (or adversarial) neural networks analysis, machine learning, deep learning, artificial-intelligence techniques (including strong AI and weak AI), forward propagation, reverse propagation and other method steps that mimic capabilities normally associated with the human mind-including learning from examples and experience, recognizing patterns and/or objects, understanding and responding to patterns in positions relative to other patterns, making decisions, solving problems. The analysis also combines these and other capabilities to perform functions the skilled labor force traditionally performed. For example, the AI engine may use deep learning techniques to improve its accuracy in identifying airflow fixtures and their compliance status, thereby reducing the need for manual review and correction.

### BRIEF DESCRIPTION OF THE DRAWINGS

The accompanying drawings, which are incorporated into and constitute a part of this specification, illustrate several embodiments of the present invention. Together with the description, these drawings serve to illustrate some aspects of the present invention.

FIG. 1A illustrates method steps that may be implemented in some embodiments of the present invention.

FIG. 1B illustrates a high-level diagram of components included in a system that uses AI to generate an interactive user interface.

FIG. 1C illustrates an exemplary design plan that is illustrated with multiple dwelling units and is used by the AI engine for compliance analyses.

FIG. 1D illustrates an exemplary AI-powered system in accordance with the present invention.

FIGS. 1E-1F illustrate exemplary portions of design plans used by the AI engine for ascertaining different spaces, airflow aspects, and duct layouts for compliance analyses.

FIG. 1G illustrates an exemplary portion of a design plan highlighting a duct layout used by the AI engine for detailed airflow compliance analyses.

FIG. 1H illustrates another exemplary portion of a design plan extracted by the AI engine for detailed airflow compliance analyses.

FIGS. 2A, 2B, 2C and 2D illustrate a two-dimensional representation of a floor plan and an AI analysis of the same to assess boundaries.

FIG. 2E illustrates an exemplary design plan of a ward in a hospital showcasing how the AI engine can assess and recommend the most appropriate setup for a given space.

FIGS. 2F-2H illustrate different types of HVAC ducts along with duct supports analyzed for airflow compliance within in a building.

FIG. 2I illustrates an exemplary design plan for a water closet area analyzed by the AI engine in some embodiments of the present invention.

FIGS. 3A-3D show various views of the AI-analyzed boundaries overlaid on the original floorplan including a table illustrated to contain hierarchical dominance relationships between area types.

FIGS. 4A-4B illustrate various aspects of dominance-based area allocation.

FIGS. 5A-5D illustrate various aspects of region identification and area allocation.

FIGS. 6A-6C illustrate various aspects of boundary segmentation and classification.

FIG. 7 illustrates aspects of correction protocols.

FIG. 8 illustrates exemplary processor architecture for use with the present disclosure.

FIG. 9 illustrates exemplary mobile device architecture for use with the present disclosure.

FIGS. 10A-10B illustrate exemplary method steps that may be executed in some embodiments of the present invention.

FIG. 11 illustrates additional method steps that may be executed in some embodiments of the present invention.

FIGS. 12A-12B illustrate an exemplary design plan of a multi-story building which the AI engine analyzes for airflow compliance.

FIGS. 13-14 illustrate a schematic diagrams of airflow equipment items and occupancy areas analyzed by the AI engine for determining airflow compliance.

FIGS. 15A and 15B illustrate exemplary method steps that may be included in some embodiments of the present invention.

FIG. 16 illustrates an exemplary interactive user interface including exemplary egress compliance analysis in accordance with airflow requirements.

FIGS. 17A and 17B illustrate exemplary interactive user interfaces including selection of a space in a design plan for compliance analysis.

FIG. 18 illustrates a block diagram of exemplary aspects that may be used in building or refining design models.

FIGS. 19A and 19B illustrate exemplary method steps that may be included in some embodiments of the present invention.

### DETAILED DESCRIPTION

The present invention provides improved methods and apparatus for utilizing artificial intelligence-based conversion of a two-dimensional reference (or three-dimensional reference), such as a design plan, into an interactive user interface capable of evaluating whether the design plan meets the required airflow management and ventilation preferred practices and providing recommendations on air flow with a building constructed according to the design represented on the design plan. This includes assessing the adequacy of HVAC and/or air filtration systems for proper air movement and quality within the building. The designated building deployment objective can be selected by the user based on factors such as building use, occupancy, or location, and may reference relevant building deployment objectives or preferred practices based on user objectives.

The present invention includes methods and apparatus to analyze a building (or other structure) design based upon automated AI analysis of a two-dimensional reference and applying machine learning to determine if the design adequately supports the management of building interior atmospheric airflow. One specific example of interior atmosphere management includes HVAC control. The employment of AI delivers a level of consistency and accuracy in analyzing design plans for compliance with airflow-related building deployment objectives that is not achievable through manual methods. The automated processes reduce errors and inconsistencies by interpreting patterns from design plan images to identify airflow components and comparing these with building deployment objective requirements. The invention provides precise calculations of airflow management elements and offers consistent feedback on whether the design plan meets or deviates from building deployment objectives. Additionally, the system can suggest modifications to address non-compliance or adopt best practices where applicable.

AI and machine learning may follow a design analysis to recognize and/or recommend aspects of a building to passively or actively control the movement of air within a built environment in order to modify conditions related to proper movement of air to the benefit of airflow equipment, equipment installed in a building, and building occupants. For example, the AI engine may determine that an office building requires specific HVAC configurations to achieve optimal air distribution and comfort, and propose adjustments to meet these needs effectively.

In some embodiments, the AI and machine learning techniques may be combined with automated processes for analyzing airflow management techniques and/or simulate airflow movement in multizone structures. The automated processes presented herein may also be used to analyze the performance of an airflow control system, such as a pressurization and/or HVAC system, and make recommendations specifying the capabilities of a suggested airflow control system installed in a building. According to the present invention, analysis of airflow management within a building may be conducted to model disparate conditions within the building taking into consideration various architectural components and forces that affect airflow movement.

A two-dimensional reference may be input into an AI controller where an analysis of different scenarios based upon a building geometry ascertained by the AI controller (in some embodiments combined with user interaction) to provide data quantifying one or more of:
a. passive compartmentalization including the use of physical barriers to hinder the movement of airflow from a fire space into non-fire spaces. physical barriers may include, for example, one or more of AI ascertained and/or user defined: walls, partitions, floors, doors, screens, and airflow dampers. For example, these barriers are identified by AI controller to determine that the building design keeps the fire contained and prevents it from moving to other areas.
b. Dilution of harmful atmospheric constituents including removal of airflow from non-fire spaces to maintain acceptable levels of gas or particulates within the non-fire spaces. Dilution may include the provision of make-up air to dilute air borne constituents, such as airflow or combustion gases, which infiltrate a non-fire space as the air from that space is exhausted. For example, the AI Controller determines that exhaust is present to suck out combustion gases and a window or fan is present to bring in fresh air from outside to keep the air quality good and safe for people in that space.
c. Pressurization and atmospheric control including the use of mechanical ventilation systems (fans) to induce pressure differences across barriers having a relatively high resistance to airflow (e.g., small gaps) to control the movement of airborne constituents (including airflow) between compartments. Shaft pressurization and zoned airflow control may be variables applied to architectural aspects, such as, for example, a stairwell and an elevator. For example, in a stairwell or elevator shaft in a building, the AI Controller determines presence of a fan to blow air into these areas, to create higher pressure that pushes air out through small gaps. To help control the movement of smoke and gases and keep smoke and gases from spreading into other parts of the building.
d. Airflow management of atmospheric constituents via equipment and building design influences a flow of atmosphere through relatively large openings. For example, in some areas of a building, like large vents or open spaces, the AI Controller determines that sufficient design and equipment are present for managing airflow air flows through these openings in a way that maintains safety and comfort, handling things like ventilation and cooling efficiently.
e. Controlling buoyancy that influences venting of atmospheric gases, which may include combustion gases incorporating a natural buoyancy and supplemented with one or both of: fan-powered and passive vents. For example, the AI Controller determines that exhaust is present at a specific height to push hot gases like combustion gases out to keep the building safe from the buildup of harmful gases and helps with overall ventilation.

The interactive user interface is operative to generate values of variables useful to ascertain whether the submitted design plan meets or exceeds a designated building deployment objective related to airflow management pertaining to a geographic and/or geopolitical area. The interactive user interface may also include specific requirements of a building deployment objective related to airflow management and indications of whether some or all of the requirements are met.

In addition, the interactive user interface may include pictorial indications of portions of a design plan that have been associated with specific requirements of the building deployment objective related to airflow management during the AI analysis. The pictorial indications may include a description of why a particular portion meets, exceeds, or does not meet a compliance with building deployment objective requirement.

As described herein, a design plan may be associated with an existing building or a proposed project that includes construction of a building (or other structure, herein collectively referred to as a “building”). Generation of documentation quantifying whether airflow requirements for an indicated purpose of deployment of a building is also within the scope of the present invention. In some embodiments, automated suggested revisions to the design plan to bring the design plan into conformity with the building deployment objectives or preferred practices are also within the scope of the invention.

According to the present invention, a controller is operative to execute artificial intelligence (AI) processes and analyze one or more design plans of at least a portion of a building (or other structure) for which a requirement determination will be generated and provides values for variables used to ascertain a state of achievement of a requirement based upon descriptive content included in the design plans.

In some embodiments of the present invention, a method for analyzing airflow compliance involves several steps to enhance accuracy and thoroughness. Initially, the design plan is converted into a raster image format, allowing the AI engine to process the design with high precision. This includes identifying various airflow components such as ducts, vents, and filters, and calculating metrics like airflow rates, size of different components, distances between components, and clearance requirements.

The AI engine identifies these components by recognizing patterns based on stored templates and calculates specific metrics to determine if the design meets building deployment objective requirements. This includes evaluating distances between air vents, clearances around HVAC units, and airflow rates for compliance with relevant building deployment objectives.

An interactive user interface is generated, allowing users to modify parameters such as the placement, type, and dimensions of airflow components. This enables real-time adjustments to the design plan, facilitating iterative compliance checks as changes are made.

The AI engine determines the building's intended use and selects appropriate conditions for airflow management, including required airflow rates and component placements. These conditions are compared against the design plan to assess compliance.

If non-compliance is detected, the system provides automated suggestions for design modifications, such as relocating air vents or adjusting their sizes to meet building deployment objective requirements. For example, if a commercial space lacks sufficient airflow, the AI engine may recommend adding more vents or adjusting their positions.

The method includes determining the building's area and occupancy load so that the airflow system is adequate for the space's intended use. The AI engine prioritizes compliance analysis based on the space's dominance rank.

The AI engine also evaluates specific systems such as air conditioning units, filter systems, smart sensor systems, and ventilation systems to meet safety and efficiency related building deployment objectives. This includes checking component placement and performance to meet adequate airflow coverage.

The AI engine analyzes the routing, size, and connections of air ducts and ventilation components to verify compliance with building deployment objective requirements related to airflow rates and system efficiency. This comprehensive approach significantly improves the reliability and efficiency of the design review process.

In some embodiments, the design plan may include technical drawings such as blueprints, floor plans, design plans, and the like. The AI analysis may include the determination of boundaries and/or features indicated in the design plan. The design plan may be a two-dimensional static reference, or a two-dimensional or three-dimensional dynamic reference, such as a Revit compatible file. This boundary determination and feature identification that is useful for assessing airflow management may be used to provide useful information about a building such as determining room layouts, airflow paths, duct framework and locations of ventilation system components and the like. Based upon values of parameters derived from a two-dimensional reference, the AI engine may generate additional values related to building deployment objectives, such as one or more of: an egress capacity; an occupancy load; a function for a space; a width of duct opening; width of window and door; or other parameters to derive adequacy of ventilation in different rooms, air distribution efficiency, and compliance with airflow regulations.

In some embodiments, the present invention may analyze a two-dimensional reference and generate one or both of: compliant airflow paths and suggested modifications to a building described in the two-dimensional reference that may help the design comply with relevant building deployment objectives for airflow.

Some preferred embodiments include an interface that describes a condition for meeting objectives and illustrates a portion of the two-dimensional reference that indicates where and/or how an objective may be met. For example, if a room lacks sufficient ventilation, the interface may show proposed solutions, such as adding or relocating vents. Users can review and modify these suggestions through the interactive user interface, to make the design comply with airflow requirements. The system may identify areas where additional vents or adjustments are needed to meet airflow related building deployment objectives. The AI engine provides suggestions for changes that may help the design comply with relevant building deployment objective for airflow.

Similarly, the AI engine may apply machine learning to a design plan to determine values for variables that relate to other conditions for compliance, such as, by way of non-limiting examples: offices, classrooms, or industrial spaces. The AI system may also consider specific conditions like the placement of air handling units, the layout of ductwork, and the design of ventilation shafts.

AI generated values for parameters may also be useful in a variety of estimation elements related to airflow management and system modifications, such as (without limitation): airflow distribution components such as vents, ducts, air handling units, windows, doors, fans, exhaust, and other HVAC equipment. The estimation process can also consider structural elements like walls and ceilings that affect airflow patterns, as well as insulation and other materials influencing air movement. The cost calculations are based on AI-determined specifications, such as the placement and size of vents, ductwork configurations, and the integration of mechanical systems to enhance airflow efficiency. These estimates help determine the cost of adjustments needed to bring a building design into compliance with airflow related building deployment objectives and preferred practices.

### Heating, Ventilation, and Air Conditioning (HVAC) Airflow in Large Buildings: for Comfort and Efficiency

Large buildings, such as commercial complexes, office towers, shopping malls, and institutional facilities, play a pivotal role in modern society. These structures provide spaces for various activities, from work and leisure to education and healthcare. Effective management of indoor environments, and in particular airflow, within these edifices is a multifaceted challenge. One useful aspect of maintaining a comfortable and productive indoor environment is the regulation of Heating, Ventilation, and Air Conditioning (HVAC) airflow. The present invention analyzes a design plan to determine the adequacy and efficiency of a proposed HVAC airflow in large buildings, focusing on principles, challenges, and strategies that may contribute to one or more of: adequacy, comfort, energy efficiency, and indoor air quality.

Aspects of building interior airflow analyzed may include one or more of: HVAC airflow involves the controlled movement of air through a building's interior spaces. Analysis of HVAC may address three fundamental aspects: heating, ventilation, and air conditioning. Heating includes the ability to raise an indoor temperature to a comfortable level during colder periods. Ventilation for a continuous supply of fresh outdoor air while expelling stale indoor air, promoting indoor air quality, and preventing the accumulation of exhaled gases and/or other pollutants. Air conditioning maintains a pleasant indoor temperature during warmer seasons and offsets heat generated by equipment, lighting, fixtures, etc. installed in the building.

In some buildings, inadequate airflow can lead to discomfort, health issues, and reduced productivity. Stagnant air can cause temperature imbalances, humidity fluctuations, and the concentration of airborne contaminants, leading to the spread of illnesses and allergies among occupants. Moreover, improper airflow can lead to the development of mold and mildew, which pose serious health risks.

Challenges in HVAC Airflow Management: Large buildings present unique challenges when it comes to HVAC airflow management. The sheer size of these structures necessitates the implementation of intricate systems that can distribute air uniformly across various floors and rooms. Moreover, factors such as building orientation, occupancy density, and external climate conditions significantly influence airflow dynamics. Balancing the need for comfort with energy efficiency is another challenge. Inefficient airflow can result in high energy consumption and operational costs, which are environmentally unsustainable and economically burdensome.

Strategies for Optimal Airflow: Achieving optimal HVAC airflow in large buildings requires a comprehensive approach that integrates design, technology, and maintenance. Some strategies may include one or more of:
Zoning and Variable Air Volume (VAV) Systems: Divide the building into zones based on occupancy and usage patterns. VAV systems adjust airflow and temperature based on demand in different areas, improving energy efficiency.
Ductwork Design: Properly designed and sized ductwork so that conditioned air reaches all corners of the building without excessive pressure losses. This promotes uniform indoor comfort.
Air Filtration: High-quality air filters prevent the infiltration of outdoor pollutants and contaminants, safeguarding indoor air quality and occupant health.
Regular Maintenance: Scheduled inspections, cleaning, and maintenance of HVAC systems are useful to prevent blockages, malfunctions, and inefficiencies that may disrupt airflow.
Advanced Controls and Sensors: Implementing smart controls and sensors enables real-time monitoring of occupancy, temperature, and air quality, allowing for dynamic adjustments to airflow and temperature settings.
Natural Ventilation: Where feasible, incorporating natural ventilation through well-designed windows and openings can reduce reliance on mechanical systems, promoting energy savings and fresh air circulation.

The present invention utilizes AI to assess and provide a user interface indicating the adequacy of the management of HVAC airflow in buildings as it impacts indoor comfort, energy efficiency, and occupant health. It assesses and provides feedback on whether airflow design is effective for maintenance, and utilization of the building for the optimal functioning of heating, ventilation, and air conditioning systems. In some embodiments, the present invention provides a user interface indicating how a building design may strike a balance between occupant comfort and environmental sustainability is the key to creating indoor environments that promote well-being and productivity in the modern built environment.

Further, in some embodiments, AI analysis may include indications as to whether a design provides an effective (or adequate) HVAC system for a proposed building layout, occupancy patterns, and usage requirements. Some factors that may be analyzed include:
Load Calculations: Accurate load calculations to determine the heating and cooling requirements of different zones within the building. Load calculations may include assessing factors such as solar heat gain, occupancy, lighting, and equipment heat output. Load calculations may also be based on an AI determined use of space within a building.
Zoning: Dividing the building into zones based on factors such as, for example, occupancy density, usage patterns, and orientation helps tailor the HVAC system to specific needs. Each zone may require different temperature settings and airflow rates.
Ductwork Design: The design of the ductwork network may be analyzed to assess efficient airflow distribution. The size, shape, and layout of ducts must be analyzed to assess pressure losses and allow conditioned air to reach all areas effectively.
Airflow Patterns: Natural airflow patterns and potential air circulation within the building may be assessed. The present invention provides for designing air supply and return paths to counteract stagnant areas and dead zones for uniform comfort.
Air Quality Considerations: Incorporating air filtration, ventilation rates, and humidity control mechanisms may be designed to maintain optimal indoor air quality (or at least adequate) for occupant health.
Integration of Controls: Advanced control systems, including thermostats, sensors, and building automation systems, should be integrated into the design. These systems enable real-time monitoring and adjustment of airflow and temperature based on occupancy and environmental conditions.
Air Volume Control: The present invention allows a user of specific air volume control to be assessed as a central aspect of HVAC system design. In some embodiments, the air handling equipment, layout, and design may be analyzed to determine how it impacts energy consumption, occupant comfort, and system efficiency. Aspects that may be considered may include one or more of:
Variable Air Volume (VAV) Systems: VAV systems adjust the volume of conditioned air delivered to different zones based on demand. This approach not only provides comfort but also reduces energy consumption by avoiding over-conditioning.
Constant Air Volume (CAV) Systems: In CAV systems, the airflow remains constant regardless of the demand. While simpler, these systems may lead to energy wastage when zones have varying heating or cooling needs.
Dampers and Valves: Dampers and valves within the ductwork can be adjusted to control the airflow to different areas. This manual or automated adjustment allows for customized comfort settings and energy savings.
Pressure-Independent Control: This advanced approach combines VAV systems with pressure-independent control valves, maintaining a consistent airflow even as pressure variations occur. This enhances comfort and energy efficiency.
Demand-Controlled Ventilation (DCV): For areas with fluctuating occupancy, DCV adjusts the ventilation rate based on the actual number of occupants, optimizing indoor air quality and energy use.
Advanced Sensors and Feedback: Using sensors to measure temperature, humidity, occupancy, and air quality allows for real-time feedback and adjustments, enhancing air volume control accuracy.
Ventilation Rates: building deployment objectives often specify minimum ventilation rates that buildings must adhere to. These rates are based on factors like the type of space (residential, commercial, institutional), occupancy density, and intended use. Ventilation rates facilitate the introduction of an adequate amount of outdoor air to dilute indoor pollutants and maintain indoor air quality.
Air Distribution and Ductwork: building deployment objectives may include guidelines for the design and installation of HVAC systems, particularly ductwork. This can include requirements for duct insulation, sealing, sizing, and layout for efficient air distribution and prevent leaks that can compromise indoor air quality and energy efficiency.
Filtration and Air Cleaning: building deployment objectives often require the installation of air filters that meet specific efficiency standards. These filters help capture airborne particles and pollutants, contributing to improved indoor air quality. Depending on the type of building and its usage, building deployment objectives may mandate certain levels of air cleaning technologies.
Energy Efficiency Standards: Many building deployment objectives emphasize energy efficiency, which can indirectly impact airflow. Efficient HVAC systems are designed to deliver the necessary airflow while minimizing energy consumption. building deployment objectives may set requirements for equipment efficiency, duct insulation, and system controls to optimize energy use.
Occupancy Sensors and Controls: Modern building deployment objectives may include the provisions for occupancy sensors and controls that regulate airflow based on occupancy levels. This helps prevent over-conditioning of spaces with low occupancy, leading to energy savings.
Indoor Air Quality (IAQ): IAQ standards may be integrated into building deployment objectives to address issues related to indoor pollutants and contaminants. Ventilation and air cleaning requirements contribute to maintaining healthy indoor environments.
Mechanical Ventilation: For buildings that are tightly sealed for energy efficiency, building deployment objectives may require mechanical ventilation systems to provide an adequate supply of fresh outdoor air, reducing the buildup of pollutants and preventing discomfort.
Specialized Spaces: Certain spaces, such as kitchens, bathrooms, laboratories, and medical facilities, may have specific airflow requirements due to the nature of activities and potential pollutants generated. building deployment objectives provide guidelines for these specialized spaces.
Local Climate Considerations: building deployment objectives may take into account the local climate conditions, such as temperature, humidity, and outdoor air quality, to determine appropriate ventilation and airflow requirements.

Assessment of a design plan for HVAC systems in buildings may include detailed information about airflow and volumes to provide efficient and effective operation. Here are the types of information that may be included in such a design plan:

Zoning and Space Classification:
a. Identification of different zones or areas within the building based on usage patterns, occupancy density, and orientation.
b. Classification of spaces (e.g., offices, conference rooms, corridors, restrooms) with specific ventilation and air conditioning requirements.

Occupancy and Usage Patterns:
a. Data on expected occupancy levels in each zone throughout the day.
b. Information about the intended use of each space and any special requirements related to air quality and temperature control.

Air Supply and Return Locations:
a. Detailed layout showing the placement of air supply vents, return vents, and exhaust openings in relation to the zones.
b. Consideration of how air distribution may be affected by architectural features like partitions, walls, and obstacles.

Ductwork Design:
a. Schematic diagrams illustrating the layout of the ductwork system connecting air handling units (AHUs), supply vents, return vents, and exhaust outlets.
b. Duct sizing information based on required air volume, velocity, and pressure.

Airflow Rates and Volumes:
a. Specifications for required airflow rates (cubic feet per minute or cubic meters per hour) in each zone.
b. Calculation of air volumes needed to meet heating, cooling, and ventilation requirements.

Variable Air Volume (VAV) Design:
a. Details about the implementation of VAV systems, including the use of VAV boxes and dampers to regulate air volumes based on demand.
b. Information on the selection and placement of VAV boxes in different zones.

Constant Air Volume (CAV) Design:
a. For CAV systems, information about the consistent airflow rates for each zone and the rationale behind these choices.

Air Balancing:
a. Strategies for achieving balanced air distribution across all zones, providing uniform comfort, and preventing areas with inadequate airflow.

Diffuser and Grille Selection:
a. Selection of appropriate diffusers and grilles for supply and return vents, considering factors like airflow patterns, noise levels, and aesthetics.

Controls and Sensors:
a. Description of control strategies to regulate airflow and volume, including the use of thermostats, occupancy sensors, and pressure sensors.
b. Integration of building management systems (BMS) to monitor and control airflows dynamically.

Energy Efficiency Measures:
a. Integration of energy-saving features like demand-controlled ventilation (DCV) to adjust ventilation rates based on occupancy, providing optimal indoor air quality.

Outdoor Air Intake:
a. Location and sizing of outdoor air intake openings to provide an adequate supply of fresh air for ventilation.

Air Filtration:
a. Specifications for air filtration systems, including filter types, efficiency levels, and maintenance schedules to maintain indoor air quality.

Specialized Areas:
a. Specific design considerations for spaces with unique requirements, such as kitchens, laboratories, and medical facilities.

Maintenance and Access:
a. Plans for regular inspection, cleaning, and maintenance of ductwork, dampers, and filters to prevent airflow restrictions.

Building Envelope Considerations:
a. Assessment of how the building envelope affects natural ventilation and potential impact on airflow strategies.

By assessing these types of information as presented in an AI derived replication of an input design plan, HVAC engineers and designers may receive assistance in creating systems that efficiently manage airflow and volumes, providing occupant comfort, indoor air quality, and energy efficiency in large buildings.

Maintenance and access are useful aspects of HVAC system design in large buildings, especially when it comes to providing proper airflow and volume control. Developing a comprehensive plan for maintenance and providing easy access to certain components are essential for the long-term functionality, efficiency, and performance of the HVAC system. Let's delve deeper into the importance of maintenance and access in the context of HVAC airflow and volume control.

Importance of Maintenance: Regular maintenance is essential to keep HVAC systems operating optimally. Neglecting maintenance can lead to issues such as reduced airflow, increased energy consumption, compromised indoor air quality, and even system breakdowns. Proper maintenance allows the designed airflow and volume control strategies to be maintained over time, contributing to occupant comfort and system efficiency.

Maintenance Tasks: Maintenance tasks related to airflow and volume control may include one or more of: Filter Replacement: Air filters need to be cleaned or replaced regularly to prevent blockages that can impede airflow and reduce system efficiency; Duct Cleaning: Periodic cleaning of ductwork prevents the buildup of dust, debris, and contaminants that can obstruct airflow and reduce indoor air quality; Damper Inspection: Checking and adjusting dampers facilitates confirmation that they are functioning properly and allowing the intended airflow to different zones; VAV Box Calibration: If variable air volume (VAV) systems are in use, VAV box calibration and testing are necessary to provide accurate control of airflow rates; Sensor Calibration: Regular calibration of sensors, such as temperature, humidity, and pressure sensors, helps maintain accurate feedback for airflow control; Motor and Fan Maintenance: Motors and fans must be inspected and maintained to facilitate operation at their intended capacity, promoting proper airflow; Seal Inspection: Seals and gaskets in ductwork and equipment should be checked for leaks that can affect both airflow and energy efficiency; and Building Envelope Checks: Assessing the building envelope for any changes that may impact natural ventilation or affect airflow patterns.

In another aspect of the present invention, a design plan may be assessed to quantify the accessibility of airflow equipment. Providing easy access to HVAC components is conducive to proper maintenance efficiency. Ease of accessibility of airflow equipment components may include, one or more of: Duct Access Points: Designing ductwork with easily accessible access points for cleaning and maintenance helps technicians reach required areas without difficulty; Filters and Filter Housings: Filters should be placed in areas that are easy to access for quick replacement or cleaning; Dampers and VAV Boxes: Dampers and VAV boxes should be located in spaces where they can be reached for inspection and adjustments; Fan Assemblies: Fans and motors should be installed in areas that allow maintenance personnel to service them without major disruptions; Control Panels and Sensors: Control panels, sensors, and thermostats should be easily accessible for calibration and troubleshooting; and Maintenance Pathways: Creating designated pathways for maintenance personnel to access equipment without disturbing occupants or causing damage.

Maintenance tasks for which adequate access is analyzed may include one or more of:
Filter Replacement: Air filters need to be cleaned or replaced regularly to prevent blockages that can impede airflow and reduce system efficiency.
Duct Cleaning: Periodic cleaning of ductwork prevents the buildup of dust, debris, and contaminants that can obstruct airflow and reduce indoor air quality.
Damper Inspection: Checking and adjusting dampers facilitates proper functioning and allows the intended airflow to different zones.
VAV Box Calibration: If variable air volume (VAV) systems are in use, VAV box calibration and testing facilitate accurate control of airflow rates.
Sensor Calibration: Regular calibration of sensors, such as temperature, humidity, and pressure sensors, helps maintain accurate feedback for airflow control.
Motor and Fan Maintenance: Motors and fans may be inspected and maintained to facilitate operation at their intended capacity, promoting proper airflow.
Seal Inspection: Seals and gaskets in ductwork and equipment should be checked for leaks that can affect both airflow and energy efficiency.
Building Envelope Checks: Assessing the building envelope for any changes that may impact natural ventilation or affect airflow patterns is important.

Access to HVAC components that may be analyzed for maintenance efficiency may include:
Duct Access Points: Designing ductwork with easily accessible access points for cleaning and maintenance helps technicians reach required areas without difficulty.
Filters and Filter Housings: Filters should be placed in areas that are easy to access for quick replacement or cleaning.
Dampers and VAV Boxes: Dampers and VAV boxes should be located in spaces where they can be reached for inspection and adjustments.
Fan Assemblies: Fans and motors should be installed in areas that allow maintenance personnel to service them without major disruptions.
Control Panels and Sensors: Control panels, sensors, and thermostats should be easily accessible for calibration and troubleshooting.
Maintenance Pathways: Creating designated pathways for maintenance personnel to access equipment without disturbing occupants or causing damage is important.

In the following sections, detailed descriptions of examples and methods will be given. The descriptions of both preferred and alternative examples, though thorough, are exemplary only. It is understood that, to those skilled in the art, various modifications and alterations may be apparent and within the scope of the present invention. Unless otherwise indicated by the language of the claims, the examples do not limit the broadness of the aspects of the underlying invention as defined by the claims.

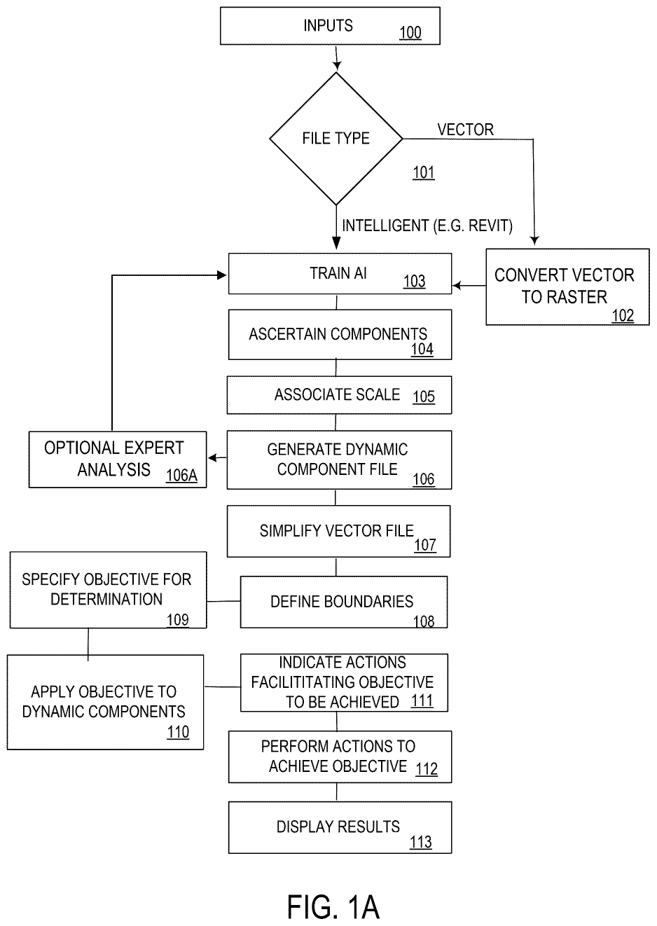

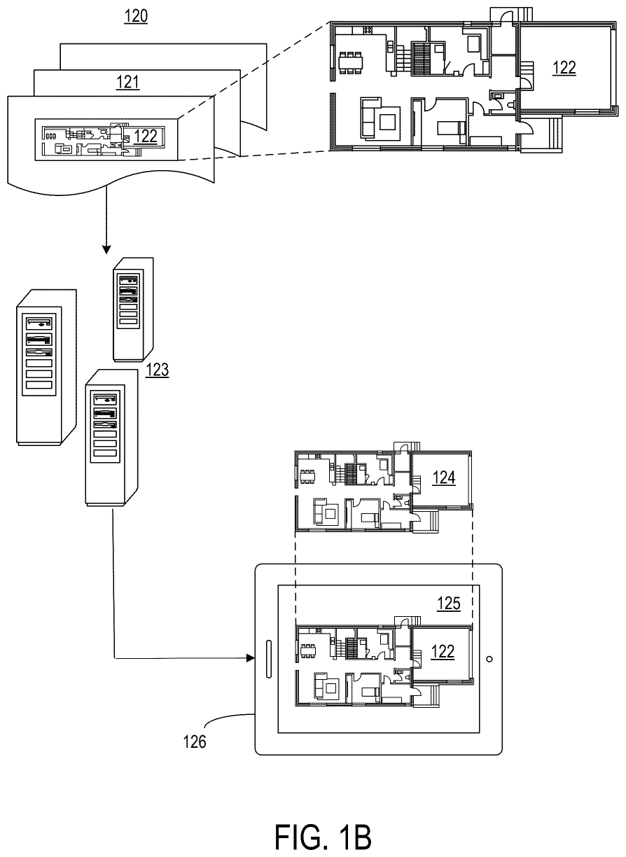

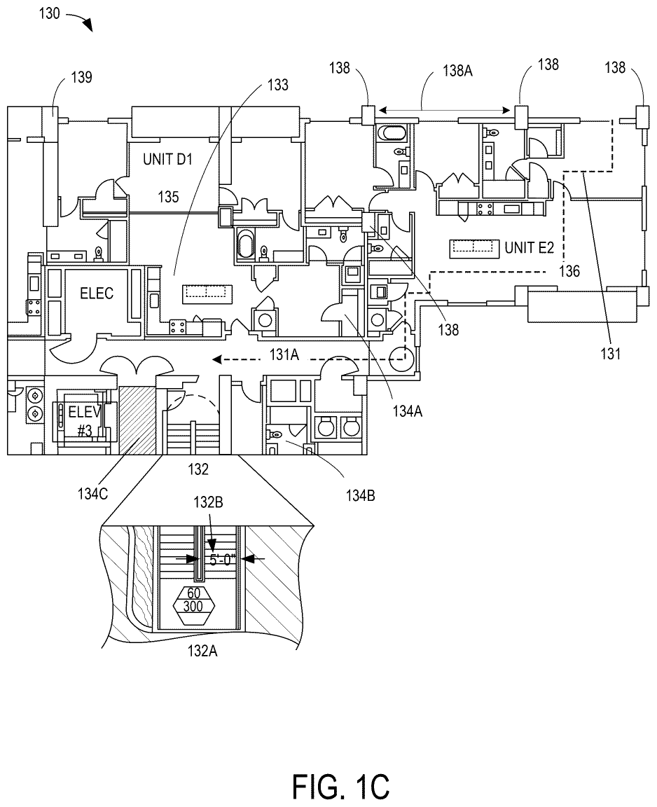

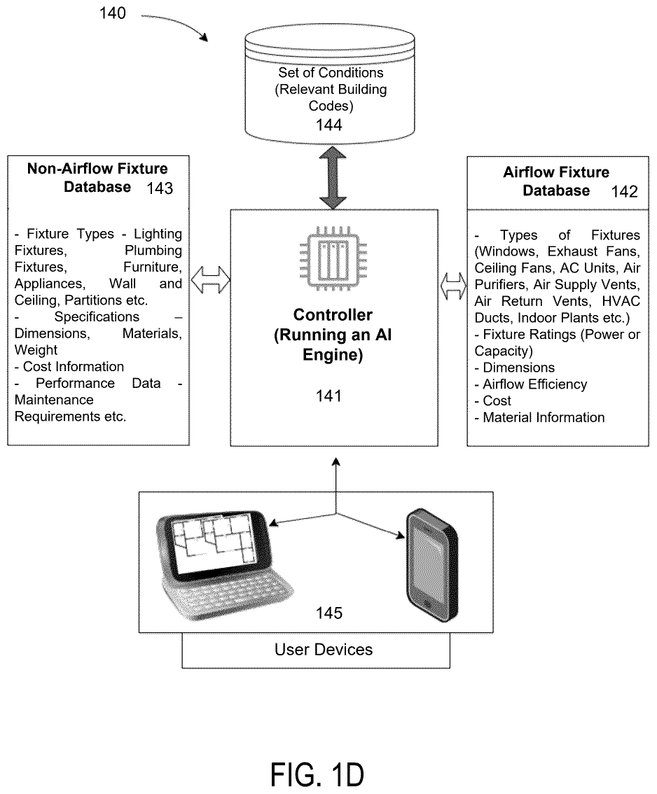

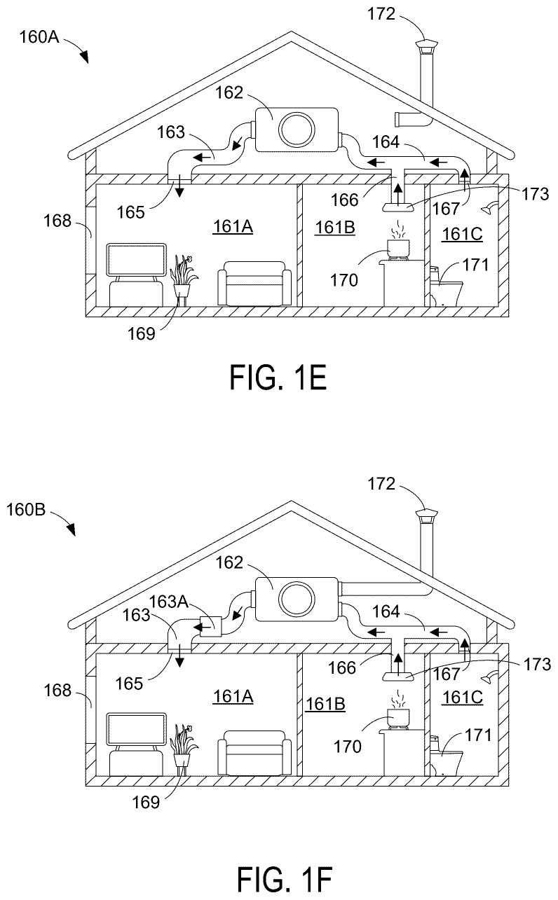

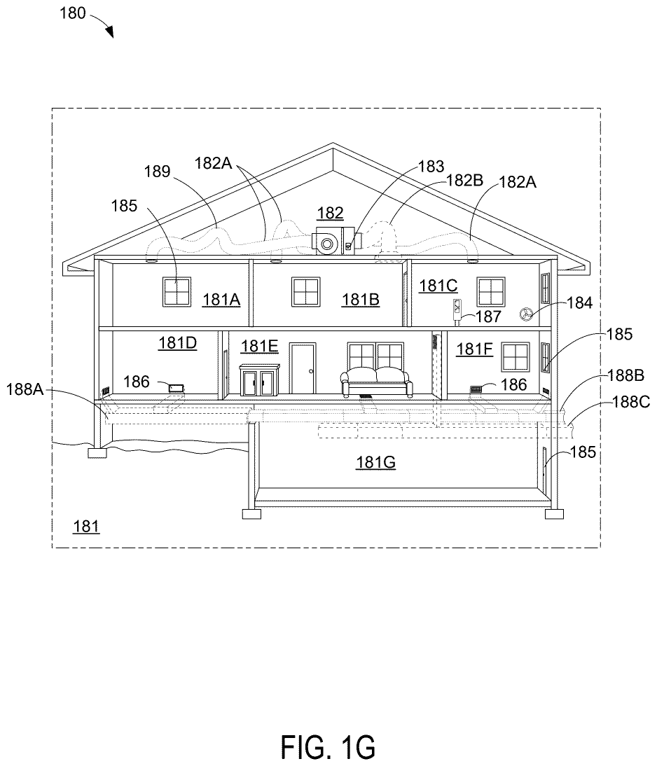

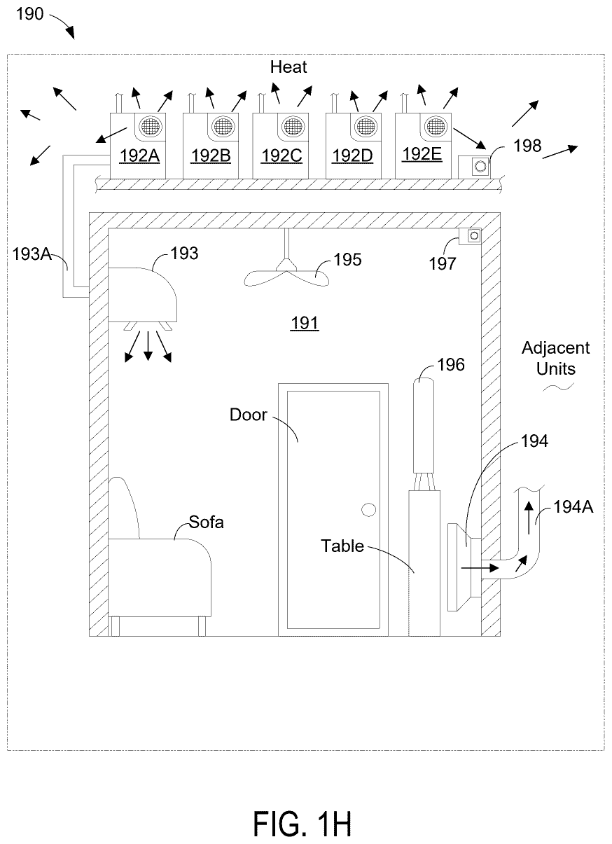

Referring to FIG. 1A, a general flow diagram showing some preferred embodiments of the present invention is illustrated. At step 100, a design plan (which may be a design plan or dynamic architectural design file (e.g., a Revit® compatible file) indicating aspects of a building; is input into a controller or other data processing system using a computing device. The design plan may include an item of a known size, such as, by way of non-limiting example, a scale bar that allows a user to obtain a scale of the drawing (e.g., 1″=100′ etc.) or an architectural aspect of a known dimension, such as a wall or doorway of a known length (e.g., a doorway known to be three feet wide).

Input of the two-dimensional reference into the controller may occur, for example, via known ways of rendering an image as a vector diagram, such as via a scan of paper-based initial drawings; upload of a vector image file (e.g., encapsulated postscript file (eps file); adobe illustrator file (ai file); or portable document file (pdf file). In other examples, a starting point for estimation may be a drawing file in an electronic file containing a model output for an architectural floor plan. In still further examples, other types of images stored in electronic files such as those generated by cameras may be used as inputs for automated processes that determine compliance with building deployment objective requirements for airflow.

In some embodiments, the design plan may be file extensions that include but are not limited to: DWG, DXF, PDF, TIFF, PNG, JPEG, GIF, or other type of file based upon a set of engineering drawings. Some design plans may already be in a pixel format, such as, by way of non-limiting examples, a two-dimensional reference in a JPEG, GIF or PNG file format. The engineering drawings may be hand drawings, or they may be computer-generated drawings, such as may be created as the output of CAD files associated with software programs such as AutoDesk™, Microstation™ etc. In other examples, such as for older structures, a drawing or other design plan may be stored in paper format or digital version or may not exist or may never have existed. The input may also be in any raster graphics image or vector image format.

The input process may occur with a user creating, scanning into, or accessing such a file containing a raster graphics image or a vector graphics image. The user may access the file on a desktop or standalone computing device or, in some embodiments, via an application running on a smart device. In some embodiments, a user may operate a scanner or a smart device with a charged coupled device to create the file containing the image on the smart device.

In some embodiments, a degree of the processing as described herein may be performed on a controller, which may include a cloud server, a standalone computing device or a smart device. In many examples, the input file may be communicated by the smart device to a controller embodied in a remote server. In some embodiments, the remote server, which is preferably a cloud server, may have significant computing resources that may be applied to AI algorithmic calculations analyzing the image for airflow related building deployment objective compliance.

In some embodiments, dedicated integrated circuits tailored for deep learning AI calculations (AI Chips) may be utilized within a controller or in concert with a controller. Dedicated AI chips may be located on a controller, such as a server that supports a cloud service or a local setting directly.

In some embodiments, an AI chip tailored to a particular artificial intelligence calculation may be configured into a case that may be connected to a smart device in a wired or wireless manner and may perform a deep learning AI calculation. Such AI chips may be configurable to match a number of hidden levels to be connected, the manner of connection, and physical parameters that correspond to the weighting factors of the connection in the AI engine (sometimes referred to herein as an AI model). In other examples, software only embodiments of the AI engine may be run on one or more of: local computers, cloud servers, or on smart device processing environments.

At step 101, a controller may determine if a design received into the controller includes a vector diagram. If a file type of the received design plan, such as an input architectural floor plan technical drawing, includes at least a portion that is not already in raster graphics image format (for example, that it is in vector format), then the input architectural floor plan technical drawing may be transformed to a pixel or raster graphics image format in step 102. The transformation process may be helpful in uniform analysis across various file formats. Vector-to-image transforming software may be executed by the controller, or via a specialized processor and associated software.

In some embodiments, the controller may determine a pixel count of a resulting rasterized file. The rasterized file will be rendered suitable for a controller hosting an artificial intelligence engine (“AI engine”) to process, where the AI engine may be optimized for detecting airflow elements and analyzing compliance criteria. the AI engine may function best with a particular image size or range of image sizes and may include steps to scale input images to a pixel count range in order to achieve a desired result. Pixel counts may also be assigned to a file to establish the scale of a drawing—for example, 100 pixels equals 10 feet.

In various examples, the controller may be operative to scale up small images with interleaved average values with superimposed gaussian noise as an example, or the controller may be operative to scale down large images with pixel removal. A desired result may be detectable by one or both of the controller and a user. For example, a desired result may be a most efficient analysis, a highest quality analysis, a fastest analysis, a version suitable for transmission over an available bandwidth for processing, or other metrics.

At step 103, training (and/or retraining) of the AI engine is performed. Training may include, for example, manual identification of patterns in a rasterized version of an image included in a design plan that corresponds with architectural aspects, walls, windows, airflow fixtures, exhaust fan, duct work, wiring or other airflow features that may be present in the two-dimensional reference. The training may also include one or more of: identification of relative positions and/or frequencies and sizes of identified patterns in a rasterized version of the image included in the design plan.

In some embodiments, and in a non-limiting sense, an AI engine used to analyze the design plan may be based on a deep learning artificial neural network framework. The AI engine image processing may extract different aspects of an image included in the design plan that is under analysis. At a high level, the processing may perform segmentation to define boundaries between important features. In engineering drawings defined boundaries may be based upon the presence of architectural features, such as walls, doorways, windows, airflow components, stairs, and the like.

In some embodiments, a structure of the artificial neural network may include multiple layers, such as input layers and hidden layers with designed interconnections with weighting factors. For learning optimization, the input architectural floor plan technical drawings may be used for artificial intelligence (AI) training to enhance the AI's ability to detect what is inside a boundary. A boundary is an area on a digital image that is defined by a user and tells the software what needs to be analyzed by the AI. Boundaries may also be automatically defined by a controller executing software during certain process steps, such as a user query. Using deep artificial neural networks, original architectural floor plans (along with any labeled boundaries) may be used to train AI models to make predictions about what is inside a boundary. For airflow-specific applications, additional training data including labeled airflow fixtures and duct configurations may be incorporated. In exemplary embodiments, the AI model may be given over ~50,000 similar architectural floor plans to improve boundary-prediction capabilities.

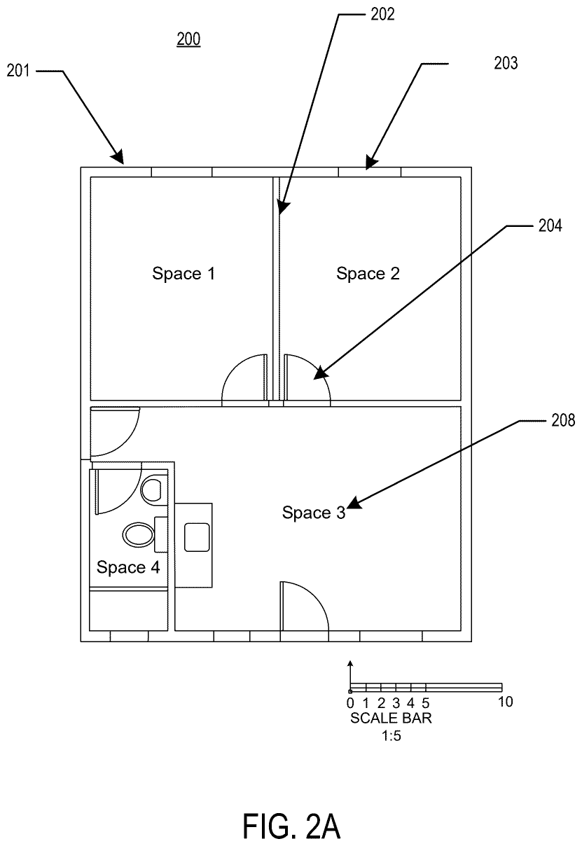

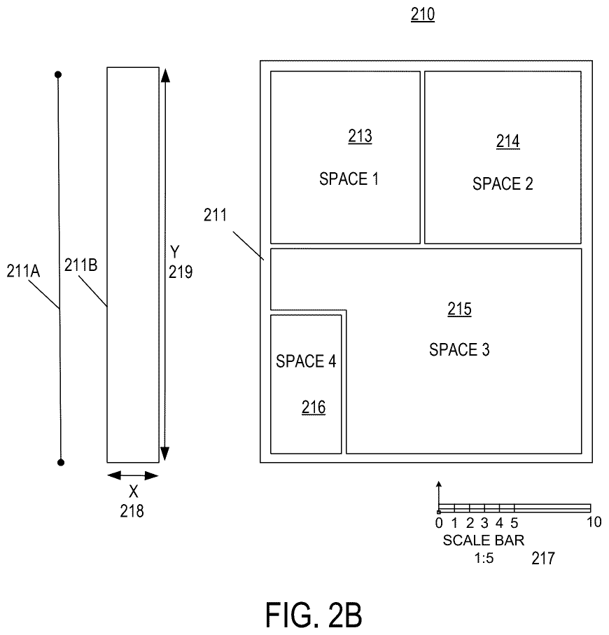

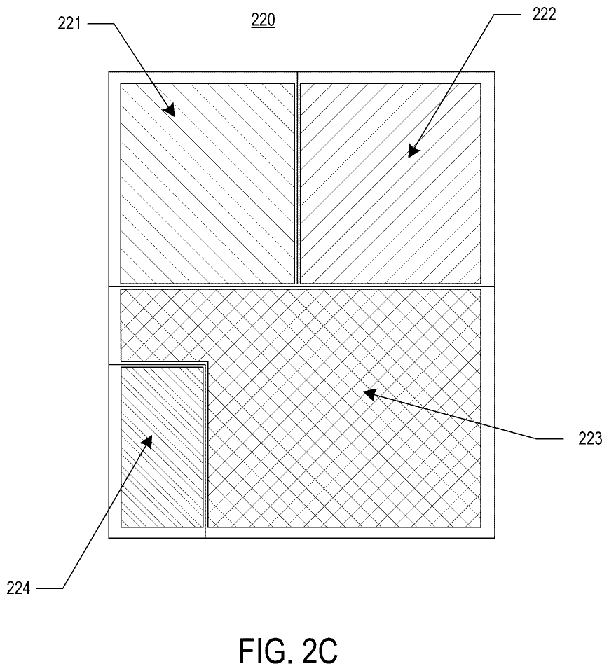

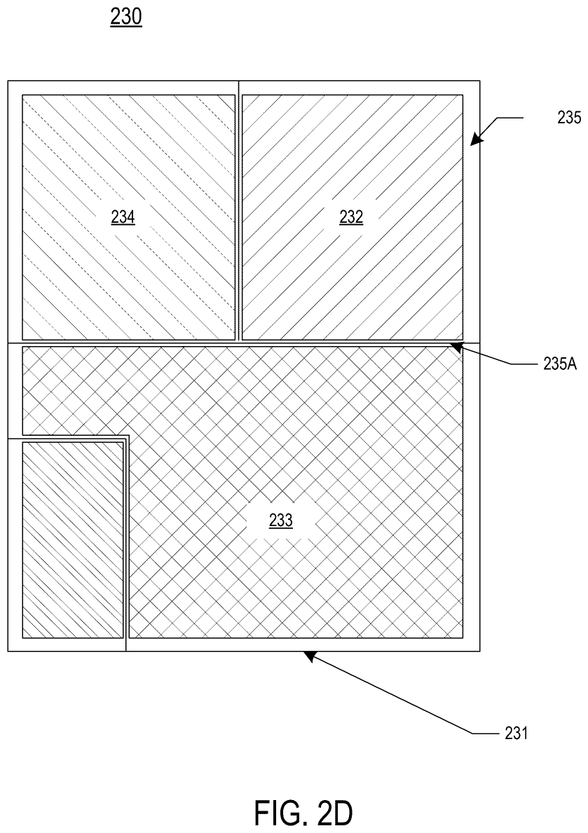

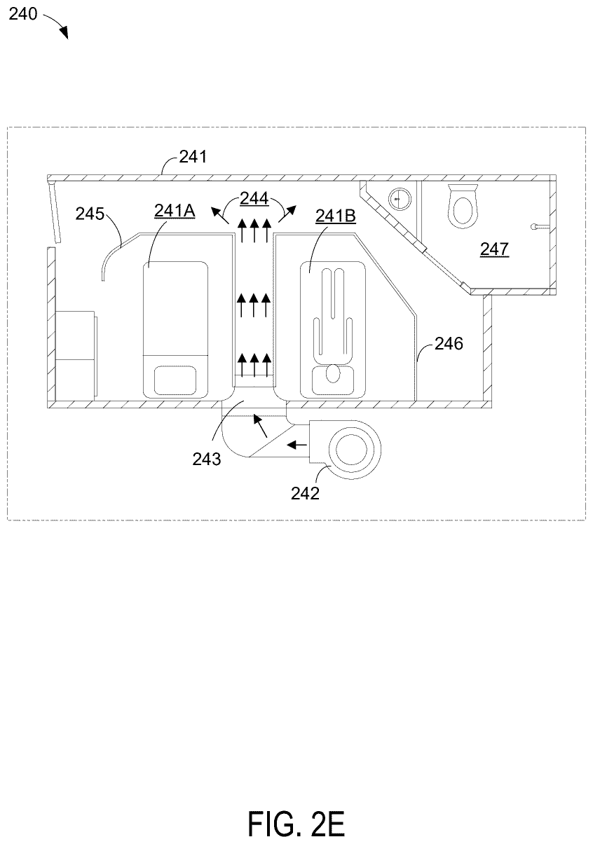

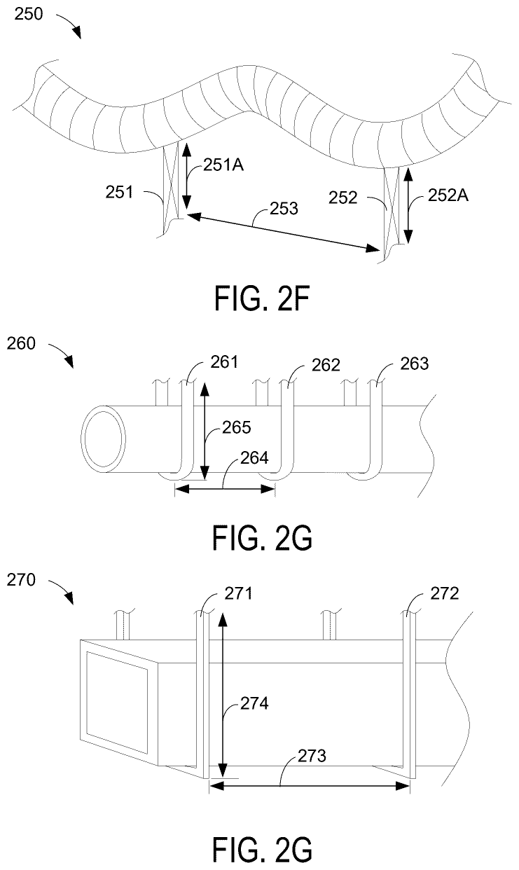

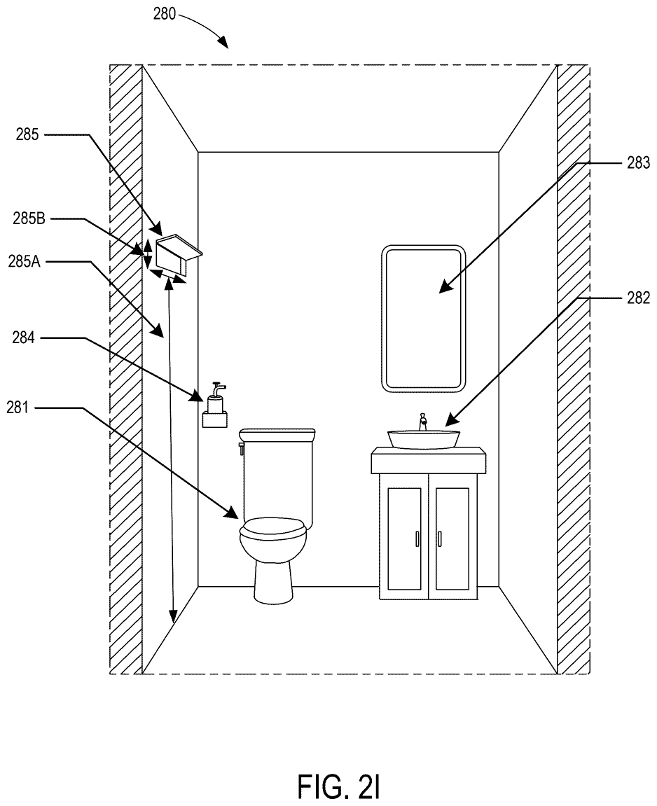

In some embodiments, a training database may utilize a collection of design data that may include one or more of: a combination of a vector graphic two-dimensional references such as floor plans and associated raster graphic version of the two-dimensional references; raster graphic patterns associated with features; and a determination of boundaries may be automatically or manually derived. The training database can be specialized to focus on airflow-related elements and compliance criteria. (An exemplary AI-processed two-dimensional reference that includes a design pan and/or a floorplan 210, with boundaries 211 predicted, is shown in FIG. 2B, based on the floorplan of FIG. 2A.) In still another aspect, in some embodiments, a controller may access data from various types of BIM and Computer Aided Drafting (CAD) design programs and import dimensional and shape aspects of select spaces or portions of the designs as they relate to a design plan. This capability allows the AI engine to integrate various data sources for a more comprehensive airflow compliance analysis.

At step 104, an AI engine may ascertain features included in the design plan, the AI engine may additionally ascertain that a feature is located within a particular set of boundaries or external to the set of boundaries. Features may include, by way of non-limiting example, one or more of: architectural aspects like physical barriers to hinder the movement of airflow, airflow fixtures, duct work, window, fans, exhaust, sensors, or other items included in a two-dimensional reference submitted to be analyzed. The features and boundaries may be determined, for example, via algorithmically processing an input design plan image with a trained AI model. As a non-limiting example, the AI engine may process a raster file that is converted for output as an image file of a floorplan (as illustrated in FIG. 2B, a boundary is represented as a line, a boundary may also be represented as a polygon, which may be a patterned polygon or other user discernable representation, such as a colored line etc.). Features may also be designated on a user interface. A feature may be represented via an artifact, such as, for example, one or more of: a point, a polygon, an icon, or other shapes.

At step 105, a scale (e.g. ; FIG. 2B item 217) is associated with the two-dimensional reference. In preferred embodiments, the scale is based upon a portion of the two-dimensional reference dedicated for indicating a scale, such as a ruler of a specific length relative to features included in a technical drawing included in the two-dimensional reference. The software then performs a pixel count on the image and applies this scale to the bitmapped image. Alternatively, a user may input a drawing scale for a particular image, drawing or other two-dimensional reference. The drawing scale may, for example, be in inches: feet, centimeters: meters, or any other appropriate scale. For example, in an embodiment where the design plan is a scanned image of a historical building, the AI engine may require manual input of the scale by the user to accurately assess dimensions, as the original scale may be inconsistent or missing.

In some embodiments, a scale may be determined by manually measuring a room, a component, or other empirical basis for assessing a scale (including the ruler discussed above). Examples therefore include a scale included as a printed parameter on two-dimensional reference or obtained from dimensioned features in the drawing. For example, if it is known that a particular wall is thirty feet in length, a scale may be based upon a length of the wall in a particular rendition of the two-dimensional reference and proportioned according to that length. In another embodiment, if the exact dimensions of a common element like a standard door are known, the AI engine may use that as a reference to automatically adjust the scale across the entire plan.

At step 106, a controller is operative to generate a user interface with dynamic components that may be manipulated by one or both of user interaction and automated processes. Any or all of the components in a user interface may be converted to a version that allows a user to modify an attribute of the component, such as the length, size, beginning point, end point, thickness, or other attribute. In some embodiments, a boundary may be treated as a component and manipulated in like manner.

Other components included in the user interface may include, one or more of: AI engine predicted components, user training aspects, and AI training aspects. In some non-limiting examples of the present invention, a generative adversarial network may include a controller with an AI engine operative to generate a user interface that includes dynamic components. In some embodiments, a generative adversarial network may be trained based on a training database for initial AI feature recognition processes.

An interactive user interface may include one or more of: lines, arcs, or other geometric shapes and/or polygons. In some embodiments, the geometric shapes and/or polygons may comprise boundaries. The components may be dynamic in that they are further definable via user and/or machine manipulation. Components in the interactive user interface may be defined by one or more vertices. In general, a vertex is a data structure that can describe certain attributes, like the position of a point in a two-dimensional or three-dimensional space. It may also include other attributes, such as normal vectors, texture coordinates, colors, or other useful attributes.

At step 107, some embodiments may include a simplification or component refinement process that is performed by the controller. The component refinement process is functional to reduce a number of vertices generated by a transformation process executed via a controller generating the user interface and to further enhance an image included in the user interface. Improvements may include, by way of non-limiting example, one or more of: smooth an edge, define a start, or end point, associate a pattern of pixels with a predefined shape corresponding with a known component or otherwise modify a shape formed by a pattern of pixels.

In addition, some embodiments that utilize the recognition step may transform features such as windows, doorways, vias and the like to other features and may be removed and/or replaced as elements—such as line segments, vectors, or polygons referenceable to other neighboring features. In a simplification step, one or more steps the AI performs (which may in some embodiments be referred to as an algorithm or a succession of algorithms) may make a determination that wall line segments, and other line segments represent a single element and then proceeds to merge them into a single element (line, vector, or polygon). In some embodiments, straight lines may be specified as a default for simplified elements, but it may also be possible to simplify collections of elements into other types of primitive or complex elements including polylines, polygons, arcs, circles, ellipses, splines, and non-uniform rational basis spline (NURBS) where a single feature object with definitional parameters may supplant a collection of lines and vertices.

The interaction of two elements at a vertex may define one or more new elements. For example, an intersection of two lines at a vertex may be assessed by the AI as an angle that is formed by this combination. As many construction plan drawings are rectilinear in nature, it may be that the simplification step inside a boundary can be considered a reduction in lines and vertices and replacing them with elements and/or polygons.

In another aspect, in some embodiments, one or both a user and a controller may indicate a component type for a boundary. Component types include, for example, one or more line segments, polygons, multiple line segments, multiple polygons, and combinations of line segments and polygons.

At step 106A, in some embodiments, components presented in an interactive user interface may be analyzed by a user and refinements may be made to one or more components (e.g., size, shape and/or position of the component). In some embodiments, user modifications may also be input back to the AI engine train the AI engine. User modifications provided back to the AI Engine may be referenced to make subsequent AI processes more accurate and/or enable additional types of AI processes.

At step 108, a controller (such as, by way of non-limiting example, a cloud server) operative as an AI engine may create AI-predicted dynamic boundaries that are arranged to form a representation of the submitted design plan that does not include the boundaries that bound it.

In various embodiments, a boundary may be used to define a unit, such as a residential unit, a commercial office unit, a common area unit, a manufacturing area, a recreational area, a dining area, or other area delineated according to a permitted use.

Some embodiments include an interface that enables user modifications of boundaries and areas defined by the modified boundaries. For example, a boundary may be selected and “dragged” to a new location. The user interface may enable a user to select a line end, a polygon portion, an apex, or other convenient portion and move the selected portion to a new position and thereby redefine the line and/or polygon. An area that includes a boundary as a border will be redefined based upon the modification to the boundary. As such, an area of a room or unit may be redefined by a user via the user interface. Changing an area of a room and/or unit may, in turn, be used as a basis for modifying an occupant load, evaluating airflow fixture requirements, defining an egress path, classifying a space, or other purposes.

For example, a change in a boundary may make an area larger. The larger area may be a basis for an increase in occupancy load necessitating adjustments in the airflow system to maintain proper ventilation. Additionally, the expanded area may result in a longer path for airflow distribution or for the movement of air from the furthest point in the defined space to an exhaust point or vent, particularly if a user opts to evaluate airflow efficiency based on a worst-case scenario for airflow distribution.

At step 109, one or both of the user and an automated process on a controller may specify a building deployment objective which the controller may make a determination of whether the plan meets the objective based upon the AI generated boundaries. In some embodiments, a selection of building deployment objectives to apply to the floor plan may be automated, for example, based upon a geographic or geopolitical area in which the building resides or will be constructed. In other embodiments, a user may specify a set of building deployment objectives, such as, for example, a drop-down menu may indicate available building deployment objectives, and a user may select one or more sets of building deployment objectives to apply to the floor plan. Accordingly, by way of non-limiting example, a user may select that a set of floorplans be analyzed with the AI engine to assess airflow objectives, cooling objectives, heating objectives, and energy conservation objectives.

At step 110, a set of parameters or conditions for a selected building deployment objective (e.g., related to airflow compliance) is applied to some or all of the dynamic components generated via the AI engine.

At step 111, the user interface or other output may be caused to display an indication of whether a design plan is in compliance with the selected set(s) of building deployment objectives. In some preferred embodiments, a list of conditions required in order for a building to meet objectives, and an indication of why one or more of the objectives is met may be illustrated within a user interface or other output. For example, if the ADA is the basis for a set of building deployment objectives to ascertain compliance with, a set of floorplans may be input into an AI engine and the AI engine will determine a value, and/or a range of values, which may be compared to the building deployment objectives and a determination may be generated indicating whether the design plans describe a building that is in compliance with a selected set of building deployment objectives.

In generating a value for such as variable, the AI engine and/or the user may need to that one or more boundaries define a specific type of area, such as a manufacturing space, storage space, cold storage space, residential space, a bedroom, a hallway, or a stairwell. Each specific type of area may have specified variables associated with it. By way of non-limiting example, the user interface may employ a simple yes/no indicator for compliance with a requirement of a selected building deployment objective.

Some specific embodiments may include a first portion of a user interface with delineated conditions for meeting building deployment objectives.

At step 112, in another aspect, the present invention may use the AI to generate suggested modifications to a design plan in order to transition the design plan from a state of not meeting one or more objectives to meeting a noted objective. The modifications may include adjusting airflow, increasing or decreasing duct sizes, increasing or decreasing number of in-vents and out-vents, or modifying other elements of airflow to meet airflow-specific requirements. In addition, the user interface may indicate other actions, in addition to a modification to the design plan, (e.g., reduce a heat load) in order to conform to the building deployment objectives.

At step 113, a conclusion of whether a design plan meets an objective may be displayed as a user interface in an integrated fashion in relation to a replication of the two-dimensional reference(such as the design plan, architectural floor plan, or technical drawing). The user interface may also be shown in a form that includes user modifiable elements, such as, but not limited to: polylines, polygons, arcs, circles, ellipses, splines, line segments, icons, points and other drawing features or combinations of lines and other elements. This comprehensive display allows users to interact with and refine their designs based on the AI-generated compliance analysis, for example, for airflow-related aspects of the building design.

Referring now to FIG. 1B, a high-level diagram illustrates components included in a system 120 that uses AI to generate an interactive user interface 125 and programmable apparatus (controller) 123 operative to execute method steps useful in determining compliance with a design plan or other architectural description. The system 120 integrates advanced AI algorithms that may specifically be designed for analyzing airflow elements within architectural plans.

According to some embodiments of the present invention, a two-dimensional reference 121, such as a design plan, floorplan, blueprint, or other document includes a pictorial representation 122 of at least a portion of a building. The pictorial representation 122 may include, for example, a portable document format (PDF) document, jpeg, png, or other essential non-dynamic file format, or a hardcopy document. The pictorial representation 122 includes an image descriptive of architectural aspects of the building, such as, by way of non-limiting example, one or more of: walls, doors, doorways, hallways, rooms, residential units, office units, bathrooms, stairs, stairwells, windows, airflow fixtures, real estate accouterments, and the like. This representation serves as the foundation for AI-driven compliance analysis, particularly focusing on airflow related building deployment objective adherence.

The two-dimensional reference 121 may be electronically provided to a controller 123 running an AI engine. The controller 123 may include, for example, one or more of: a cloud server, an onsite server, a network server, or other computing device, capable of running executable software and thereby activating the AI engine. The AI engine may be optimized for interpreting architectural and airflow features, and cross-referencing them with relevant airflow related building deployment objectives. Presentation of the two-dimensional reference may include, for example, scanning a hardcopy version of the two-dimensional document into electronic format and transmitting the electronic format to the controller 123 running the AI engine.

The controller is operative to generate a user interface 125 on a user computing device 126. The user computing device may include a smart device, workstation, tablet, laptop or other user equipment with a processor, a storage, and a display. The user interface 125 is designed to facilitate real-time interaction with the design plan, allowing users to review and modify design aspects including those related to airflow compliance.

The user interface 125 includes a reproduction of the pictorial representation 122 and an overlay 124 with one or more user manipulatable components, such as, by way of non-limiting examples: boundaries, line segments, polygons, images, icons, points, and the like. These components may represent elements of the airflow system, such as airflow routes, fixture locations, windows, fans, exhausts, air conditioners, heat pumps, and duct layouts The line segments may have calculated lengths that may be mathematically manipulated and/or summarized. Aspects such as polygons, line segments, shapes, icons, and points may be counted, added, subtracted, extrapolated, and other functions performed on them. This functionality may particularly be useful for evaluating the spatial requirements of airflow related building deployment objectives, such as minimum distances between fixtures or distance between duct supports or duct diameters or clearances for different devices of the airflow system.

In addition, renditions of the user interface 125 may be created and saved, and/or communicated to other users, or controllers, compared to subsequent interface renditions, archived and/or submitted to additional AI analysis. These renditions may allow for iterative refinement of the design plan, so that each revision aligns more closely with the relevant airflow related building deployment objectives.

In some embodiments, a first user interface 125 rendition may be modified by a user to create a second user interface 125, and submitted to AI analysis to ascertain compliance with a selected building deployment objective. This feature may enable users to weigh the financial and logistical impacts of making the necessary modifications to achieve airflow compliance. Some embodiments may also calculate costs, expenses, man hours or other variables associated with changes to a design plan in order to bring the design plan into compliance. Change order renditions provided as options to bring a design plan into compliance with a selected building deployment objective may also be provided with a unique identifier, time and/or date stamped to create a continuum of work, as related to original projects and compliance-initiated changes. Each of the items in the continuum of work may be stored and subsequently used for ascertaining the eventual compliance of a building with each selected building deployment objective. This creates a transparent, traceable history of design iterations, making it easier to demonstrate compliance with regulatory authorities.

Referring now to FIG. 1C, an exemplary design plan 130 serves as a foundational document for airflow compliance analysis performed by a controller equipped with an AI engine. The design plan 130 is illustrated with multiple dwelling units 135-136 and a path of travel 131, and a blow-up/detailed view of the stairwell 132A of a portion of the design plan determined by the AI engine to be a stairwell 132. The blowup of the stairwell 132A includes a dimension 134 indicating that ½ of the stairwell 132A (commonly, either ascending or descending side of a stairwell 132A) is equal to five feet. A dimensional end cap 134A is illustrated and indicates one side of the dimension 134. In addition, the controller identifies various airflow variables within the stairwell 132, such as the placement of ventilation ducts and size of ventilation ducts etc.

In some embodiments, the end cap 134A will be placed on a user interface with dynamic components by a controller as a result of a determination by an AI engine in communication with the controller. Furthermore, some embodiments allow placement of the end cap 134A that may be a result of a user action. Still further, one or both of the controller and the user may adjust the placement of an end cap 134A initially placed by either the controller and/or the user. The varied placement of end caps 134A can influence the airflow dynamics within the stairwell 132. For example, adjusting the placement of an end cap 134A may change the location of air intake or exhaust points, thereby affecting the overall distribution of air within the stairwell. Therefore, the placement of an end cap 134A is an integral part of the building's fire protection strategy, and the AI engine assesses whether the placement of an end cap 134A has adequate airflow to function effectively during an emergency.

According to the present invention, once a dimension 134 has a value associated with it, the dimension may be used to extrapolate other dimensions, such as, for example, one or more of: a length and/or width of a loading ramp 133, a length 131A of a path 131, an area of a unit 135-136 or other distance and/or area. As discussed in more detail herein, a length 131A of a path 131 may be used to calculate a length of a path from a furthest point to a point of egress.

The illustrated end cap 134A is shown as a line, other and caps 134A may also be within the scope of the present invention that may better suit a particular aspect of a design plan interface 103, such as, by way of non-limiting example, one or more of: a perpendicular corner, a dot, an arrow, a circle, angled lines joined at a defined number of degrees, such as thirty degrees, forty-five degrees, ninety degrees or an angle provided by one or both of the AI engine and the user.

Referring now to FIG. 1D, it illustrates an exemplary AI-powered system 140 designed for comprehensive airflow compliance analysis of building design plans in accordance with the present invention. The AI-powered system 140 is structured around a controller 141, which serves as the central processing unit of the system. This controller 141 may be embedded within or connected to user devices 145, which may include various types of hardware such as computers, tablets, or smartphones. These user devices 145 enable users, such as architects, engineers, or building inspectors, to interact with the system for evaluating and determining the airflow compliance of design plans with relevant building deployment objectives.

The user devices 145, equipped with the controller 141, may possess a processor and a memory or storage area where executable software codes or programs are stored. When these software codes are executed by the processor, they prompt the controller 141 to perform detailed airflow compliance analyses on design plans of at least a portion of a building. The design plans, which may be in digital formats such as CAD files, PDFs, or image files, are input into the system for analysis. The user device 145 facilitates this process by allowing the user to upload or access these design plans directly through the device.

The user device 145 also includes a display, providing an interface for the interaction between the user and the system. The display is used to generate a first interactive user interface that serves multiple functions. Firstly, it renders the design plans in a detailed and scalable format, allowing the user to zoom in on specific areas, rotate views, or switch between different layers of the plan. The dynamic components of the design, which may include elements like walls, windows, doors, HVAC units, air ducts, and other airflow fixtures, are visually represented on this interface.

In addition to rendering the design, the first interactive user interface allows the user to define and view boundaries within the design plan. These boundaries may represent rooms, zones, or sections of the building where specific airflow compliance analyses are to be conducted. The user can interact with these boundaries by adjusting their size, shape, or position directly on the interface. This flexibility may be useful for tailoring the compliance analysis to specific areas of interest within the building design.

The first interactive user interface may allow users to modify changeable parameters associated with the dynamic components of the design plan. For example, if the analysis reveals that the airflow is insufficient in a particular room due to the size of the air ducts, the user can adjust the dimensions of the ducts or change their placement directly through the interface. The system then re-runs the compliance analysis based on these modifications, providing updated results. This iterative process enables a dynamic and efficient workflow where design revisions can be made and assessed in a continuous loop.

The AI-powered system 140 is further detailed in its operation of analyzing airflow compliance within a building design plan. The process begins with the AI engine embedded within the controller 141 receiving a design plan of at least a portion of a building. The design plan, which can include various architectural elements such as rooms, corridors, HVAC systems, windows, and doors, is input into the system through user devices 145. These user devices 145 facilitate the interaction between the user and the system, allowing the design plan to be uploaded in various digital formats.

Upon receiving the design plan, the controller 141 initiates the process of converting the design plan into multiple dynamic components. This step breaks down the complex architectural drawings into manageable and analyzable components. Each dynamic component represents a distinct element of the building, such as a wall, a window, an HVAC duct, or an air vent. The conversion process involves identifying these elements based on their geometric properties, dimensions, and spatial relationships within the design plan.

Once the design plan is converted into dynamic components, the controller 141 generates a first interactive user interface on the display of the user device 145. The user interface is a powerful tool that allows the user to interact with the design plan in a dynamic and flexible manner. The interface visually represents the multiple dynamic components, enabling the user to view, select, and modify them as needed. For example, the user can zoom in on a particular area of the design plan, select a specific HVAC duct, and adjust its dimensions or placement within the building. The dynamic components displayed on the interface are not static; instead, they are interactive, with each component including a parameter that can be changed by the user through the interface. These parameters may include dimensions, material specifications, airflow capacities, or even spatial positioning within the building.

The controller 141 also arranges the multiple dynamic components within the first interactive user interface to form a first set of boundaries. These boundaries are used for defining distinct zones or units within the building, such as individual rooms, corridors, or larger open spaces. Each boundary is characterized by a respective first length and a first area, which are calculated based on the geometric properties of the dynamic components it encloses. For example, if the boundary defines a room, the length may correspond to the perimeter of the room, and the area would be the total square footage of the room. The controller 141 performs this boundary formation not just for a single unit but for all relevant units within the design plan, so that the entire building is divided into appropriately defined spaces for further analysis.

Following the formation of boundaries, the controller 141 proceeds to ascertain various airflow fixtures within each unit or the entire building as depicted in the design plan. The controller 141 may reference an airflow fixture database 142 to identify various types of airflow fixtures. The airflow fixture database 142 contains comprehensive information on various types of airflow fixtures, such as windows, exhaust fans, ceiling fans, air conditioners, air purifiers, air supply vents, air return vents, HVAC ducts, and even indoor plants that contribute to natural ventilation. Each type of airflow fixture in the database 142 may be cataloged with detailed specifications, including dimensions, airflow capacity, efficiency ratings, cost, and material information.

To identify the type of an airflow fixture within the design plan, the controller 141 cross-references the visual or geometric characteristics of the components in the design plan with the entries in the airflow fixture database 142. For example, if the design plan shows a rectangular opening near the ceiling in a room, the controller 141 may reference the database 142 to determine whether this component is a standard air supply vent based on its size and placement. Similarly, if the design plan includes a cylindrical object with connected ductwork, the controller 141 may identify it as an HVAC duct or air purifier by comparing it to the known specifications in the database 142.

Moreover, the database 142 allows the controller 141 to ascertain specific details about each identified airflow fixture. For example, if a window is detected within a room, the controller 141 can determine whether it is a standard single-pane window, a double-glazed window, or a specialized window designed for enhanced natural ventilation. This determination is made by matching the window's dimensions, frame material, and placement with the corresponding data in the airflow fixture database 142. The controller 141 may also analyze exhaust fans by verifying their size, airflow capacity, and placement against the database entries.

For example, in a kitchen unit, the controller 141 may identify the presence of an exhaust fan by recognizing a circular or square-shaped fixture on the ceiling or wall near the cooking area. The system cross-references this visual cue with the airflow fixture database 142 to confirm it is indeed an exhaust fan designed for kitchen use. The database 142 provides further details on the fan's specifications, such as its capacity to remove cooking fumes, its noise level, and its energy consumption. This information may then be used to determine if the fan meets the relevant building deployment objectives for kitchen ventilation.

Similarly, the controller 141 can identify indoor plants as natural airflow fixtures that contribute to air quality and ventilation. The airflow fixture database 142 may include entries for various types of indoor plants known for their air-purifying qualities, such as snake plants, spider plants, or peace lilies. When the system detects a potted plant in a room based on the design plan, it can reference the database 142 to classify the plant type and assess its contribution to the room's overall ventilation. The database 142 may provide information on the plant's effectiveness in removing airborne toxins, its oxygen-producing capabilities, and the recommended placement for optimal airflow impact.

Similarly, the controller 141 may ascertain non-airflow fixtures within the building design by referencing a non-airflow fixture database 143. The database 143 may be a comprehensive repository of various fixtures that, while not directly related to airflow, play a significant role in the overall functionality and compliance of the building's design. The non-airflow fixture database 143 may include detailed information on fixture types such as lighting fixtures, plumbing fixtures, furniture, appliances, wall and ceiling partitions, and other structural elements that contribute to the building's utility and habitability.

When the controller 141 analyzes a design plan, it identifies non-airflow fixtures by cross-referencing the visual and geometric properties of components within the design plan with the entries in the non-airflow fixture database 143. For example, if the design plan shows a rectangular object placed along a wall in a living room area, the controller 141 (or the AI engine) may recognize it as a sofa or a cupboard based on its dimensions and placement. The database 143 provides a wealth of information about such fixtures, including their dimensions, materials, weight, and cost. Additionally, it may contain data on the maintenance requirements for these fixtures, which is useful for long-term building management.

For example, in a bathroom unit, the controller 141 may detect the presence of a sink, a toilet, and a mirror by analyzing the shapes and placements of these objects within the design plan. By referencing the non-airflow fixture database 143, the system can determine the type and specifications of each fixture. For the sink, the database 143 may provide details about its dimensions, the material used (such as porcelain or stainless steel), and any integrated features like a soap dispenser or a faucet type. The toilet may be classified based on its flushing mechanism, size, and installation type (wall-mounted or floor-mounted), all of which are documented in the database.

In addition to furniture and plumbing fixtures, the non-airflow fixture database 143 may also include entries for lighting fixtures. When the design plan indicates the presence of a ceiling fixture or wall-mounted lights, the controller 141 can identify the type of lighting being used, such as recessed lighting, chandeliers, or sconces, by cross-referencing the fixture's dimensions and placement with the database entries. The database 143 may further provide information on the power rating of the lights, their energy efficiency, and whether they are compatible with dimmer switches or smart home systems.

Another example may involve the identification of partitions within the design plan. Partitions are structural elements that divide spaces within a building, such as walls that separate rooms or cubicle dividers in an office setting. The controller 141 can detect these partitions by recognizing their linear or segmented nature in the design plan. The non-airflow fixture database 143 may categorize these partitions by material (e.g., drywall, glass, wood) and thickness, and also include data on their acoustic properties or fire ratings, which are required for meeting building deployment objectives related to safety and privacy.

Furthermore, the database 143 may include performance data and cost information for non-airflow fixtures, enabling the controller 141 to evaluate the economic and operational efficiency of the building design. For example, if a design plan includes high-end kitchen appliances, the database 143 can provide insights into their energy consumption, lifespan, and overall cost, which may influence decisions about design revisions or compliance with energy efficiency regulations.

The controller 141 also assesses the spatial relationships between airflow fixtures, non-airflow fixtures, and their positioning relative to each other. For example, the placement of large furniture items like a sofa or a bed near an air vent may obstruct airflow, reducing the efficiency of the HVAC system. By referencing the non-airflow fixture database 143, the system can identify such issues and suggest modifications, such as repositioning the furniture or selecting more appropriately sized fixtures to enhance airflow and overall room functionality.

After the controller 141 has successfully ascertained the type and count of all the fixtures within the design plan, both airflow fixtures and non-airflow fixtures, it proceeds to the next step in the airflow compliance analysis. This step involves determining a comprehensive set of conditions that are required for a thorough airflow compliance analysis of the building design. These conditions are used to evaluate whether the design plan meets the necessary standards for airflow, ventilation, and indoor air quality, as stipulated by the relevant building deployment objectives.

To determine these conditions, the controller 141 references a building deployment objective database 144 that contains a detailed compilation of relevant building deployment objectives. The building deployment objective database 144 encapsulates all the regulatory requirements, whereby adherence provides safe and effective building designs. It includes building deployment objectives and preferred practices related to various aspects of construction, such as ventilation requirements, air quality standards, energy efficiency, fire safety, occupancy limits, and more. These objectives and practices may typically be specified by local, regional, or national authorities, and they vary depending on the type of building (e.g., residential, commercial, industrial) and its intended use.

When the controller 141 accesses the building deployment objective database 144, it first determines the type of each unit within the building design. The type of unit may range from a residential apartment to a commercial office, an industrial workspace, or a healthcare facility, among others. Each of these unit types has specific requirements for airflow and ventilation, which are dictated by the relevant building deployment objectives. For example, a healthcare facility may require more stringent ventilation systems to control the spread of airborne pathogens, while a commercial office may have different requirements focused on occupant comfort and energy efficiency.

In addition to determining the type of unit, the controller 141 also calculates the area of each unit. The area of a unit is a useful factor in determining the airflow requirements, as larger spaces typically require more airflow fixtures (such as vents and fans) to maintain adequate ventilation. The controller 141 uses the dimensions of the unit, which have been previously identified and represented as dynamic components in the interactive user interface, to calculate the area accurately. This calculation is used for determining if the airflow system can adequately service the entire unit without leaving any dead zones where air circulation may be insufficient.

Furthermore, the controller 141 takes into account the proposed use of the building. The proposed use refers to the function that each unit within the building is intended to serve, which directly influences the airflow requirements. For example, a restaurant kitchen will have different airflow needs compared to a residential living room, due to the presence of cooking equipment that generates heat and smoke. Similarly, a manufacturing plant may require specialized ventilation to manage fumes and particulate matter, while a classroom in a school may need to maintain high air quality to support the health and concentration of students. The controller 141 cross-references this information with the building deployment objective database 144 to determine the specific types and quantities of airflow fixtures that are required for each unit based on its area and intended use.

Once the controller 141 has determined the required types and quantities of airflow fixtures, it performs a detailed comparison between these requirements and the actual airflow fixtures that were identified in the design plan. This comparison may be useful in identifying any discrepancies between the required and existing airflow systems. The controller 141 examines various parameters of the airflow fixtures, including their count, type, dimensions, and placements, to assess whether they align with the requirements specified by the building deployment objectives.

For example, the building deployment objective database 144 may specify that a certain room size requires a minimum of two air supply vents and one exhaust vent, placed at specific heights and distances from each other to provide proper air circulation. The controller 141 will compare this requirement against the actual design plan to verify if these conditions are met. If the design plan only includes one air supply vent or places the exhaust vent too close to a heat source, these discrepancies are flagged by the controller 141.

Discrepancies may also involve the dimensions of the fixtures. If the building deployment objective database 144 specifies that an air vent must have a minimum diameter to support adequate airflow for a room of a certain size, but the identified vent in the design plan is smaller, this may lead to insufficient ventilation. Similarly, the placement of airflow fixtures is another useful factor. The controller 141 analyzes whether the fixtures are placed in locations that support optimal airflow patterns, such as avoiding placements where airflow can be obstructed by furniture or partitions.

When the controller 141 identifies such discrepancies, it doesn't just flag them; it also provides detailed recommendations for corrective actions. For example, if the number of airflow fixtures is insufficient, the controller may suggest adding additional vents or upgrading existing ones to larger sizes. If the placements are not ideal, the controller may recommend repositioning the fixtures to improve airflow. These recommendations are presented to the user through the interactive user interface, allowing for easy modifications and real-time re-analysis of the design plan.

Referring now to FIG. 1E, an exemplary portion of a design plan 160A serves as a fundamental document for the compliance analysis executed by a controller equipped with an AI engine. The design plan 160A represents the floor layout of a house or building, encapsulating architectural and airflow elements integral to the building's design. The controller, through its AI capabilities, assesses various features of the design plan 160A to determine its compliance with relevant building deployment objectives, particularly those related to airflow, governing airflow, ventilation, and indoor air quality.

The AI engine initiates its analysis by identifying the overall structure and layout of the design plan 160A. It recognizes and categorizes the different rooms within the house, such as 161A, 161B, and 161C, as well as the attic area where a main HVAC system is installed. The identification process is based on the AI engine's ability to interpret architectural elements such as walls, doors, and windows, which define each room's boundaries. Furthermore, the AI engine determines the presence of multiple airflow fixtures distributed across the building, including air supply and return vents, windows, indoor plants, doors, and ducts, which are analyzed for determining airflow compliance.

Within the house 160A, the AI engine identifies specific rooms 161A, 161B, and 161C, by analyzing the configuration and types of fixtures present in each. For example, the AI system detects a kitchen area 161B based on the presence of kitchen-related fixtures such as sinks, countertops, and stove placements 170, which indicates specific ventilation standards to be met, particularly in managing the exhaust of cooking fumes. Similarly, the AI engine recognizes a water closet area 161C by detecting fixtures such as a water closet 171, sink, and showerhead, which indicates requirement of adequate exhaust systems to remove moisture and odors. In addition, the AI engine identifies a drawing room area 161A by recognizing the presence of fixtures like a television and sofa, which indicates a living space that must meet natural ventilation requirements. The AI engine also recognizes the attic space, where the main HVAC system 162 is located, recognizing it as a central hub for the building's ventilation and climate control.

In some embodiments, the AI engine may determine the type of space (unit) based on the markings or annotations present on the design plan itself. Labels such as “Living Room,” “Kitchen,” or “WC” (Water Closet) on the design plan 160A guide the AI engine in accurately categorizing each space. This cross-referencing with the design allows the AI engine to evaluate the compliance of each space with relevant building deployment objectives more effectively, determining if the ventilation requirements for each room type are properly met. In some embodiments, users may also specify types of spaces through the interactive user interface.

Once the AI engine identifies and categorizes all the spaces within the design plan 160A, it proceeds with a detailed compliance analysis. The compliance analysis may include examining the airflow fixtures within each space (161A-161C) to determine whether they align with the relevant building deployment objectives. The AI engine analyzes the number and types of airflow fixtures within each identified space to determine if the airflow fixtures are appropriate for the intended function of the room. For example, in the water closet area 161C, the AI engine detects a return vent 167, which is required to expel moist air and prevent the buildup of humidity that may lead to mold growth. In the kitchen area 161B, the AI engine identifies a return vent 166, required for removing cooking odors and smoke. In the drawing room area 161A, the AI engine determines the presence of an air supply vent 165, a window 168, and an indoor plant 169.

In some embodiments, the AI engine verifies that each of the rooms 161A, 161B, and 161C is equipped with the necessary number of supply and return vents to manage airflow effectively, considering the number of occupants in each room, type of the rooms, and area of each room. This calculation helps in verifying if the ventilation system is capable of maintaining indoor air quality standards, particularly in spaces with high occupancy levels. For example, in the drawing room 161A, while the AI engine recognizes the air supply from the supply vent 165 and the window 168, it also detects the lack of an air return vent back to the HVAC system 162, which may result in inadequate ventilation. This issue may cause discomfort for the occupants or lead to the accumulation of airborne contaminants. Similarly, in the kitchen area 161B and water closet area 161C, the AI engine detects the presence of return vents (166-167) but notes the absence of corresponding supply vents from the HVAC system 162. The lack of supply vents may impede proper air circulation, leading to negative pressure zones that can draw contaminants from other areas into these spaces.

In some embodiments, the AI engine also inspects the size and shape of airflow fixtures to confirm that they meet building deployment objectives. For example, the AI engine measures the dimensions of the window 168 and ducts like supply vent 165 and return vents 166 and 167 to verify that it meets the minimum size requirements for ventilation in a residential unit.

Additionally, the AI engine may assess the spacing between fixtures, such as the connection between various vents and ducts, to determine whether they are appropriately connected to the central HVAC system. This may verify if the airflow pathways are efficient and capable of supporting the required ventilation rates. For example, in the design plan 160A, the AI engine analyzes the connections between the return vents 166 and 167 in the kitchen area 161B and the water closet area 161C respectively, which are coupled to a common or main air return line 164 connected to the main HVAC system 162. However, the AI engine identifies a significant compliance issue involving the exhaust chimney 173. The intended function of the exhaust chimney 173 is to channel smoke and combustion byproducts from a heating source, such as a stove or fireplace (170), in kitchen 161B, safely out of the building through the chimney outlet 172. The AI engine detects that the exhaust chimney 173 is improperly connected to the return vent 166 of the HVAC system 162 instead of the chimney outlet 172.

The return vent 166 is part of the HVAC system 162, which is designed to circulate air throughout the building, maintaining temperature control and air quality. By connecting the exhaust chimney 173 to the return vent 166, smoke, carbon monoxide, and other harmful gases from the heating source 170 are inadvertently introduced into the HVAC system 162. This may result in these hazardous substances being circulated throughout the entire building, posing significant health risks to the occupants. The HVAC system 162 is not equipped to handle or filter out such contaminants effectively, leading to potential exposure to toxic fumes and severe air quality degradation. Moreover, this design flaw may lead to the accumulation of soot and other particulate matter within the HVAC system 162, which may cause mechanical failures, reduce the system's efficiency, and increase the risk of fires.

To rectify this issue, the AI engine may suggest several modifications to the building design. For example, the AI engine may recommend disconnecting the exhaust chimney 173 from the return vent 166 and correctly routing it to the chimney outlet 172. The AI engine may also propose the installation of sensors within the HVAC system 162 to detect any future contamination or improper connections.

Furthermore, the AI engine may also determine whether sufficient natural ventilation is provided by the existing window 168 and the presence of the indoor plant pot 169 in the drawing room area 161A. Natural ventilation is a specific aspect of indoor air quality, and the AI engine evaluates whether the current window size is adequate for the room's occupancy and size. In some embodiments, the AI engine may cross-reference the window size with external environmental factors, such as the prevailing wind direction and the presence of natural obstructions like neighboring buildings or trees. For example, if the window 168 is located on a side of the house that faces a dense cluster of trees, the AI engine may conclude that these natural obstructions limit the airflow into the room, even if the window size meets the regulatory requirements. As a result, the AI engine may recommend enlarging the window or adding additional ventilation features, such as louvered vents or operable skylights, to enhance natural ventilation.

Additionally, the presence of the indoor plant pot 169 may influence the AI engine's assessment of natural ventilation. In some embodiments, the AI engine considers the role of indoor plants in improving air quality by absorbing carbon dioxide and releasing oxygen. However, the AI engine may also recognize that an indoor plant, particularly in a pot of significant size, may impede air circulation if placed directly in front of the window 168 or in a location that blocks the flow of air from the window 168 into the room 161A. In such cases, the AI engine may suggest repositioning the plant to avoid obstructing the ventilation path or recommend additional airflow features to compensate for any reduction in natural ventilation caused by the plant's placement.

The AI engine's analysis may extend to determining whether the window 168 allows for effective cross-ventilation within the drawing room area 161A. For example, in a scenario where the drawing room has multiple openings or is connected to adjacent rooms with windows or doors, the AI engine may evaluate whether these openings facilitate air movement across the room, thereby enhancing overall ventilation. If the AI engine detects that the current configuration of windows and doors does not promote effective cross-ventilation, it may suggest structural modifications, such as the installation of transom windows above doors or additional side windows, to improve the natural ventilation and maintain indoor air quality.

In some embodiment, the AI engine may recommend adding additional natural ventilation features, such as operable windows or ventilation grilles, to complement the mechanical ventilation system. For example, in the kitchen area 161B, the AI engine may suggest the installation of an operable window to provide an additional source of natural ventilation, especially during cooking activities that generate heat and odors. This recommendation may be based on an analysis of the room's airflow requirements, taking into account factors such as the size of the space, the number of occupants, and the type of activities performed within the room (e.g., type of a room).

The AI engine also considers the role of occupancy in determining the required ventilation capacity. For example, the AI engine may analyze the drawing room 161A's intended use and calculate the necessary airflow requirements based on the expected number of occupants. If the room is designed to host a large number of people, the AI engine may recommend increasing the size of the window or adding more air supply and return vents to accommodate the higher ventilation demand and to keep the indoor air quality at an acceptable level, even during periods of peak occupancy.

In some embodiments, the AI engine evaluates kitchen ventilation systems for compliance with regulatory requirements, for example, those outlined in building deployment objectives regarding the placement of exhaust fans in the kitchen area 161B. For example, in the kitchen area 161B, where a stove 170 is situated beneath an exhaust chimney 173, the AI engine assesses whether the height of the exhaust chimney 173 above the stove 170 meets the minimum requirement of 24 inches and maximum 30 inches. For example, if the height is found to be insufficient, the AI engine identifies the exhaust chimney 173 as non-compliant with the building deployment objectives set by the International Residential Code (IRC) and provides the recommendations from the National Fire Protection Association (NFPA). An exhaust hood of the chimney 173 installed too low impairs its ability to effectively capture and expel contaminants, leading to smoke and grease particles bypassing the hood. This results in the accumulation of contaminants within the kitchen 161B, deteriorating indoor air quality, increasing grease buildup on surfaces, and raising fire hazards.

The AI engine's analysis also extends to the attic space, where the main HVAC system 162 is located. The AI engine evaluates whether the size or member of the main HVAC system 162 is sufficient for the overall ventilation needs of the house 160A/160B based on the occupancy load. For example, the AI engine may analyze the ductwork connected to the HVAC system 162 to determine if it is adequately sized and positioned to deliver air to each room without creating imbalances or pressure drops that may affect the system's efficiency.

In addition to evaluating the mechanical ventilation system, the AI engine also considers the potential for passive ventilation strategies. For example, the AI engine may assess the orientation of the building and the placement of windows and vents to determine if natural airflow patterns can be harnessed to improve ventilation. In the drawing room 161A, the AI engine may analyze the prevailing wind direction and recommend positioning the window 168 to take advantage of cross-ventilation.

In some embodiments, the AI engine may calculate the areas of each of the defined spaces, such as the living room 161A, the kitchen area 161B, and the water closet area 161C. This calculation may be based on the dimensions extracted from the architectural layout (or design plan 160A), which may include the length, width, and height of each space. In some embodiments, the dimensions may be measured based on a scaling process as discussed in FIG. 2B below. By computing the total volume of air each room can hold, the AI engine can accurately assess the effectiveness of the ventilation system in place. In its analysis, the AI engine identifies that while the living room 161A is equipped with an air supply vent 165 connected to the HVAC system 162, it lacks a corresponding return vent, which is required for maintaining a balanced and efficient airflow. The absence of a return vent in this area may result in stagnant air, potentially leading to discomfort and diminished indoor air quality.

Moving to the kitchen area 161B and the water closet area 161C, the AI engine detects a more significant issue: both spaces are missing air supply vents altogether. The kitchen area 161B, which houses heat-generating appliances like the stove 170, requires an adequate air supply to counteract the heat and odors produced during cooking. Similarly, the water closet area 161C, which includes a toilet 171 and shower, needs a consistent air supply to prevent the accumulation of moisture that may lead to mold growth and other health hazards. The lack of air supply vents in these spaces raises concerns about the overall air circulation within the building, which the AI engine flags as a useful compliance issue.

In addition to assessing the air supply and return vent configurations, the AI engine also evaluates the presence or absence of ceiling fans and exhaust fans within each room. Ceiling fans, particularly in the living room 161A and kitchen area 161B, can significantly enhance airflow by circulating air and preventing hot spots or areas of stagnant air. The AI engine notes whether these fans are present and functioning correctly, and if they are missing, the AI engine may recommend their installation as a means to improve air distribution. Similarly, exhaust fans are required in areas like the kitchen 161B and water closet 161C for removing moisture, odors, and airborne contaminants. The AI engine scrutinizes these areas for the presence of exhaust fans, assessing their placement and effectiveness. If the AI engine determines that these fans are absent or inadequately placed, it may suggest specific locations for their installation to optimize air extraction and prevent the buildup of harmful substances.

The AI engine's analysis extends beyond mechanical ventilation and includes a holistic approach to improving indoor air quality. For example, in the living room area 161A, the AI engine considers the benefits of introducing indoor plants, such as the plant pot 169. Plants have the ability to naturally purify the air by absorbing carbon dioxide and releasing oxygen, as well as filtering out certain toxins. The AI engine may recommend placing additional plant pots in the living room 161A or other areas of the house to enhance natural air purification. The system evaluates the potential impact of plant placement on airflow, considering factors such as the size of the plants, their location relative to air vents, and their ability to contribute to a healthier indoor environment.

The AI engine may also analyze the ductwork of the HVAC system 162, the AI engine assesses the diameters of the main air supply line 163 and the main air return line 164. These diameters determine the volume of air that can be effectively circulated through the building. The AI engine calculates whether the existing diameters are sufficient to meet the airflow demands of the rooms (e.g., 161A-161C) based on their size, occupancy, and function. If the AI engine determines that the diameters are too small, leading to restricted airflow and inefficient system performance, it may suggest resizing the ducts (e.g., 163-164) to improve the system's capacity to deliver and return air throughout the building.

Further scrutiny by the AI engine may reveal potential issues with the duct layout itself, particularly concerning the presence of uneven bends in the main air supply line 163 and the main air return line 164. Uneven bends in ductwork can create turbulence, increase resistance, and reduce the efficiency of airflow through the system. The AI engine analyzes the angles and curvature of these bends, identifying areas where the ductwork may be improperly installed or where airflow is likely to be impeded. The AI engine may then recommend modifications to straighten the ducts or to replace sharp bends with gradual curves to reduce resistance and maintain smooth airflow, thereby enhancing the overall efficiency of the HVAC system.

The AI engine may also identify the absence of a filter in the main air supply line 163. Filters are integral to HVAC systems as they trap dust, pollen, and other airborne particles, preventing them from circulating through the ducts and into the living spaces. Without a filter, these contaminants are freely distributed throughout the house, degrading indoor air quality and potentially leading to respiratory issues for the occupants. The AI engine identifies this missing component and suggests the immediate installation of an appropriate filter in the main air supply line 163. It may also recommend the type of filter that should be used, taking into consideration factors such as the level of filtration needed, the type of contaminants likely to be present, and the maintenance schedule required to keep the system functioning effectively.

In some embodiments, the AI engine may determine a proposed use for the building, which is then used in determining the suitability of the design plan 160A. The use for which the building is proposed, whether residential, commercial, or mixed-use, fundamentally influences the types of spaces within the building, such as living areas, kitchens, and water closets. Each of these spaces, 161A, 161B, and 161C, has distinct functional requirements and therefore demands specific airflow fixtures to maintain adequate ventilation and indoor air quality. The AI engine identifies these spaces based on architectural elements and spatial configurations and then assigns each space a use category according to its intended function within the building. The use category forms the basis for determining what types of airflow fixtures are necessary to comply with relevant building deployment objectives.

The AI engine next calculates the area of each identified space within the building. It computes the total square footage of the living room 161A, the kitchen area 161B, and the water closet area 161C by analyzing the design plan 160A. The AI engine uses these area calculations to determine the volume of air each space can hold, which is directly related to the ventilation requirements. Larger spaces generally require more extensive ventilation systems to circulate air effectively, while smaller spaces may suffice with fewer fixtures. The AI engine considers the specific characteristics of each space, including the room's shape, ceiling height, and the presence of any obstacles that may affect airflow. By accurately measuring these areas, the AI engine establishes a baseline for assessing whether the current design provides sufficient airflow fixtures for the proposed use of the building.

After establishing the areas, the AI engine predicts the expected occupancy level for each space based on its intended use. For example, the living room 161A, as a common gathering area, is expected to accommodate more occupants than the kitchen area 161B or the water closet 161C. The AI engine uses this predicted occupancy level to calculate the required ventilation rates, which are expressed in terms of air changes per hour (ACH). Higher occupancy levels necessitate increased ventilation to prevent the accumulation of carbon dioxide and other contaminants, thereby maintaining air quality. The AI engine also considers factors such as the duration of occupancy and the activities performed within each space, which influence the type and intensity of ventilation needed. By analyzing the proposed occupancy, the AI engine can determine the quantity of airflow fixtures required to meet the ventilation needs.

Based on the proposed use, space types, area measurements, and predicted occupancy levels, the AI engine determines the types and quantities of airflow fixtures that should be installed in each space to comply with relevant building deployment objectives. For the living room 161A, which serves as a primary living space, the AI engine may determine that a combination of air supply vents, return vents, and windows is necessary to provide both mechanical and natural ventilation. The kitchen area 161B, where cooking activities generate heat and airborne contaminants, may require additional exhaust vents to remove smoke and odors. In contrast, the water closet area 161C, with its high moisture content, may need sufficient exhaust ventilation to prevent mold growth and maintain hygiene. The AI engine references building deployment objectives that specify the minimum requirements for airflow fixtures in different types of spaces and uses these guidelines to establish the ideal configuration for each room within the building.

With the ideal configuration in mind, the AI engine then assesses the actual type and quantity of airflow fixtures present in each space as depicted in the design plan 160A. For the living room 161A, the AI engine identifies the presence of an air supply vent 165 and a window 168 but notes the absence of a return vent. In the kitchen area 161B and the water closet area 161C, the AI engine detects return vents 166 and 167, respectively, but finds no air supply vents. The AI engine catalogs these findings and cross-references them with the requirements it previously determined based on the space type, area, and occupancy levels. This comparison is used to identify discrepancies between the necessary and available ventilation systems.

Through this comparison, the AI engine identifies discrepancies that may lead to non-compliance with building deployment objectives. For the living room 161A, the absence of a return vent means that while fresh air is supplied through the air supply vent 165, stale air cannot be adequately removed, leading to potential air stagnation and discomfort for occupants. In the kitchen area 161B, the lack of air supply vents means that there is no mechanism for introducing fresh air to replace the air being exhausted by the return vent 166. This may result in negative pressure, drawing contaminated air from adjacent spaces into the kitchen 161B, thereby compromising air quality. Similarly, in the water closet area 161C, the absence of an air supply vent combined with the presence of a return vent 167 may lead to insufficient air circulation, causing humidity levels to rise and creating a breeding ground for mold and mildew.

The AI engine also assesses the size and placement of the existing airflow fixtures to determine whether they are adequate for the building's ventilation needs. For example, the AI engine measures the dimensions of the window 168 in the living room 161A and evaluates its ability to provide sufficient natural ventilation based on the room's area and predicted occupancy level. The window's size and the number of air changes per hour it can support are compared against the requirements established by building deployment objectives. If the window is too small, it may not allow enough air exchange to meet the room's ventilation needs, even if mechanical ventilation is present. Similarly, the AI engine examines the ductwork connected to the vents 165-167, checking whether the ducts are appropriately sized and positioned to facilitate efficient airflow throughout the building.

In its analysis, the AI engine may find that the types of airflow fixtures present in the spaces do not match what is required by the building deployment objectives. For example, in the kitchen area 161B, where a higher volume of air changes is necessary due to cooking activities, the AI engine may determine that additional exhaust vents are needed beyond the single return vent 166 identified in the design plan 160A. The water closet area 161C may also be found lacking in terms of exhaust capacity if the AI engine determines that the existing vent 167 is insufficient to handle the moisture levels anticipated during peak usage. These findings prompt the AI engine to recommend modifications to the design plan 160A, such as the installation of additional vents or the enlargement of existing ones, to align the building's ventilation system with building deployment objective requirements.

In some cases, the AI engine may also evaluate the positioning of airflow fixtures within each space. The location of vents and windows relative to the room's layout can significantly affect airflow patterns. For example, if an air supply vent is placed too close to a return vent, the fresh air may be immediately extracted without circulating through the room, reducing the effectiveness of the ventilation system. The AI engine analyzes the spatial distribution of the fixtures and may recommend repositioning them to optimize airflow. This may involve moving a vent to a different wall or adjusting the height at which a window is installed. Such recommendations are based on the AI engine's understanding of airflow dynamics and the need to create a balanced and efficient ventilation system.

By incorporating all these factors into its analysis, the AI engine offers a detailed and nuanced evaluation of the building's ventilation system. Its ability to cross-reference the proposed use, space types, area measurements, and occupancy levels with building deployment objectives allows it to identify not just obvious deficiencies but also subtle issues that may otherwise go unnoticed. For example, the AI engine may detect that the living room 161A is over-ventilated, leading to energy inefficiencies, or that the water closet area 161C lacks sufficient exhaust capacity, risking moisture-related damage. These insights enable stakeholders to make informed decisions about how to optimize the building's design, ultimately leading to a safer, more comfortable, and building deployment objective-compliant environment for occupants.

Throughout the process, the AI engine maintains a focus on compliance with building deployment objectives, but it also considers factors such as energy efficiency, indoor air quality, and occupant comfort. This holistic approach allows the recommendations it provides to be not only compliant but also aligned with best practices in building design. For example, the AI engine may suggest the use of energy recovery ventilators (ERVs) in the kitchen area 161B to reclaim energy from exhaust air, or it may recommend incorporating passive ventilation strategies in the living room 161A to reduce reliance on mechanical systems. These recommendations are grounded in the AI engine's extensive database of building deployment objectives, standards, preferred practices, and design principles, making them both practical and effective.

In some embodiments, the AI engine may also simulate different scenarios to test the effectiveness of the proposed ventilation system under various conditions. For example, it may model how the system would perform during extreme weather events, such as a heatwave or cold snap, to determine if it can maintain indoor air quality and comfort under all circumstances. This simulation capability allows the AI engine to identify potential weaknesses in the system before construction begins, providing an opportunity to address them proactively. The AI engine may also use these simulations to optimize the placement and configuration of airflow fixtures, so that the system performs efficiently in both typical and extreme conditions.

The AI engine's recommendations are not limited to airflow fixtures alone; they may also extend to other aspects of the building's design that impact ventilation. For example, the AI engine may suggest modifying the building's insulation or installing energy-efficient windows to reduce the load on the HVAC system 162. It may also recommend the use of advanced control systems that automatically adjust ventilation rates based on real-time data from sensors placed throughout the building. These control systems can help maintain optimal indoor air quality while minimizing energy consumption, thereby enhancing both the comfort and sustainability of the building.

Referring now to FIG. 1F, the illustration presents another exemplary design plan 160B, which the AI engine meticulously analyzes for compliance with relevant building deployment objectives, particularly those related to airflow and ventilation. The design plan 160B shares similarities with the previously discussed design plan 160A in FIG. 1E, but introduces a significant difference: the chimney outlet 172, which is intended to vent smoke and combustion byproducts safely to the outside environment, is improperly connected to the HVAC system 162.

The AI engine identifies this misconnection as a design flaw that has serious implications for the building's ventilation and overall air quality. The chimney outlet 172 is supposed to expel smoke, carbon monoxide, and other combustion byproducts directly outside, preventing these harmful substances from entering the building's interior. However, in this design, the chimney outlet 172 is connected to the HVAC system 162, which is designed to recirculate air throughout the building. This improper connection does not actually introduce smoke into the HVAC system but indicates a potential flaw in how the system is intended to operate.

The AI engine recognizes that while the chimney outlet 172 does vent outside, its connection to the HVAC system 162 may interfere with the proper functioning of both systems (e.g., HVAC system 162 and chimney 173). For example, this misconnection may create issues with pressure differentials within the HVAC system 162, leading to inefficient operation of the HVAC system 162 and potential backdrafts where exhaust gases may not be expelled as intended. Additionally, the AI engine may analyze whether this connection may lead to mechanical failures within the HVAC system 162 over time, due to the strain of improper airflow dynamics. To correct this issue, the AI engine may recommend disconnecting the chimney outlet 172 from any HVAC system 162 and rerouting it directly to the exhaust hood of the chimney 173.

In some embodiments where the AI engine determines the types and quantities of airflow fixtures necessary for adequate ventilation within a building, the AI engine first analyzes the design plan to categorize each space within the building, such as living rooms, kitchens, water closets, hallways, and other areas. The AI engine's goal is to assess whether the ventilation within these spaces aligns with relevant building deployment objectives, which dictate specific requirements for air quality, airflow rates, and the removal of contaminants.

The AI engine begins by identifying the types of airflow fixtures that are required for each space. These fixtures typically include air supply vents, return vents, exhaust fans, ceiling fans, and possibly additional elements like windows or natural ventilation options, depending on the room's function and the building's overall design. For example, in a kitchen area, exhaust fans may particularly be important to remove cooking fumes, while supply and return vents help circulate fresh air. In contrast, a living room may require a balance of supply and return vents, possibly supplemented by ceiling fans to enhance air movement. In a water closet, exhaust fans are required to remove moisture and odors, along with supply vents to introduce fresh air.

Once the AI engine has identified the necessary airflow fixtures, it calculates the required quantity of each type based on several factors, including the size of each space, the expected occupancy levels, and the specific use of the space. For example, a large living room with high occupancy may require multiple air supply vents and a corresponding number of return vents to maintain balanced airflow, whereas a smaller water closet may need just one exhaust fan and a small supply vent. The AI engine uses predefined standards from relevant building deployment objectives to determine these requirements.

The AI engine also considers the spatial relationship between these fixtures. It examines whether the placement of supply and return vents allows for effective air circulation, whether exhaust fans are positioned correctly to remove air contaminants, and whether ceiling fans are optimally located to aid in the distribution of air within the space. For example, if a supply vent is placed too close to a return vent, it may result in short-circuiting of airflow, where air is recirculated without properly ventilating the entire room. The AI engine identifies such issues by analyzing the layout and distances between fixtures.

After determining the required types, quantities, and spatial relationships of airflow fixtures, the AI engine compares them against the existing fixtures detailed in the design plan (e.g., 160B). It checks for discrepancies such as missing fixtures, improperly placed vents, or inadequate quantities of fans or exhaust systems. For example, if a kitchen area is missing an exhaust fan or if the existing fans are insufficient to handle the expected volume of cooking fumes, the AI engine flags this as a non-compliance issue. Similarly, if a living room has an adequate number of supply vents but lacks corresponding return vents, leading to potential airflow imbalance, the AI engine identifies this discrepancy.

When the AI engine identifies non-compliance issues, it provides recommendations for modifications to bring the design plan into alignment with relevant building deployment objectives. These modifications may include adding additional airflow fixtures, relocating existing ones to improve efficiency, or resizing ducts and vents to better match the room's requirements. For example, the AI engine may suggest adding an exhaust fan in the kitchen area if none is present or increasing the number of return vents in a large living room to prevent air stagnation. It may also recommend installing ceiling fans in larger rooms to enhance air circulation and prevent hot spots.

In cases where the AI engine identifies that exhaust fans or vents are not properly connected to the HVAC system or are venting into inappropriate areas (such as venting moisture-laden air into a sealed attic space), the AI engine suggests rerouting these fixtures to provide proper ventilation. It may also recommend the installation of additional ductwork, filters, or dampers to optimize the airflow system and prevent any potential hazards, such as the accumulation of moisture or contaminants.

In some embodiments, the AI engine provides recommendations for enhancing indoor air quality through the installation of air purifiers and indoor plants. The AI engine begins by evaluating the overall air quality needs of each space within the building. It considers factors such as the presence of pollutants, allergens, and other airborne contaminants that may compromise the health and comfort of occupants. For example, in a kitchen area where cooking fumes and odors are prevalent, or in a living room where dust and pet dander may accumulate, the AI engine identifies these spaces as candidates for enhanced air purification measures.

Based on this analysis, the AI engine may recommend the installation of air purifiers in specific locations where they may be most effective. It considers various types of air purifiers, such as those with HEPA filters, activated carbon filters, or UV-C light technology, depending on the types of pollutants present in the environment. For example, in a space prone to high levels of dust and allergens, the AI engine may suggest a HEPA filter air purifier, known for its ability to capture fine particles. In areas where chemical fumes or odors are a concern, an air purifier with activated carbon filters may be recommended for its ability to absorb gases and odors.

In addition to air purifiers, the AI engine may also consider the role of indoor plants in improving air quality. The AI engine recognizes that certain indoor plants are highly efficient at filtering pollutants and increasing oxygen levels in the air. It evaluates the potential benefits of placing indoor plants, such as the one indicated by reference numeral 169 in FIG. 1F, within various spaces of the building.

The AI engine assesses the efficiency of various types of indoor plants in air purification. For example, the snake plant (Sansevieria trifasciata), also known as the mother-in-law's tongue, is renowned for its ability to filter out formaldehyde, xylene, toluene, and nitrogen oxides, making it suitable for areas exposed to pollutants from household products or car exhaust. The peace lily (Spathiphyllum), another effective air-purifying plant, is known for removing ammonia, benzene, formaldehyde, and trichloroethylene from the air. The AI engine may recommend these plants for placement in spaces such as living rooms, offices, or bathrooms where such pollutants are more likely to accumulate.

Furthermore, the AI engine may consider the size and placement of these plants for maximum efficiency. It may suggest placing larger plants in areas with higher foot traffic or greater pollutant levels, while recommending smaller plants in compact spaces or areas with lower occupancy. The AI engine also takes into account the maintenance needs of the plants, recommending species that are easy to care for and thrive in the specific lighting conditions of the room. For example, the spider plant (Chlorophytum comosum) is suggested for its ability to thrive in low light and its effectiveness at removing carbon monoxide and xylene from the air.

The AI engine may also recommend combining air purifiers with indoor plants to create a comprehensive air purification strategy. For example, in a room with limited ventilation, the AI engine may suggest the installation of a HEPA filter air purifier to handle airborne particles, while also recommending the placement of peace lilies to absorb chemical vapors.

To further optimize the air purification strategy, the AI engine may analyze the spatial arrangement and airflow patterns within the room. It may recommend placing air purifiers near pollution sources, such as cooking areas or windows facing busy streets, and positioning indoor plants where they can receive sufficient light and maximize their air-filtering capabilities. The AI engine may also suggest regular maintenance schedules for both air purifiers and indoor plants, such as replacing filters in air purifiers and watering plants appropriately, to maintain their effectiveness over time.

Referring now to FIG. 1G, an exemplary design plan 180 of a building 181 is depicted, providing a comprehensive representation of the internal layout, airflow system, and structural components of the building 181. The AI engine, upon analyzing the design plan 180, systematically identifies various units such as rooms 181A-181G within the building 181, categorizing them based on their intended use, spatial dimensions, and relative location within the structure. Each room, whether it is a living area, kitchen, bathroom, or any other designated space, is scrutinized to assess its role in the overall layout of the building 181. The AI engine also ascertains the presence of an HVAC system 182, which is installed in the attic space of the building 181, and determines its significance in maintaining the indoor climate and air quality within the building 181. The HVAC system 182, depicted with components such as air supply ducts 182A (flexible duct unit) and air return ducts 182B, forms the backbone of the ventilation and temperature control mechanisms within the building 181.

The AI engine undertakes a detailed analysis of the ductwork associated with the HVAC system 182, focusing on several useful aspects that directly impact the efficiency and compliance of the system. The analysis involves evaluating the diameters of both the air supply ducts 182A and the air return ducts 182B, determining if they are appropriately sized for the building's needs. The diameters of these ducts are useful for facilitating the correct volume of airflow through the building 181, thereby maintaining a desired temperature and air quality levels in each room. If the AI engine identifies any discrepancies in the duct sizes, such as undersized ducts that may restrict airflow or oversized ducts that may lead to inefficiencies, it flags these as potential issues that require rectification.

Furthermore, the AI engine examines the installation network of the ductwork, particularly analyzing the presence and nature of any bends, such as bend 189, in the duct system. The AI engine evaluates whether these bends are within acceptable parameters, as improper bends can cause significant airflow resistance, leading to reduced efficiency of the HVAC system 182. Sharp or uneven bends can disrupt the smooth flow of air, causing pressure drops and leading to uneven temperature distribution within the building. The AI engine may flag any such non-compliant bends and recommend modifications to optimize airflow, such as smoothing out sharp bends or re-routing the ducts to minimize unnecessary turns.

In addition to the ductwork analysis, the AI engine also determines whether the HVAC system 182 is effectively covering all the rooms 181A-181G within the building 181. This may involve assessing the presence and adequacy of both supply and return vents in each room. The AI engine meticulously checks whether each room is receiving the necessary airflow to maintain comfort and air quality. For example, the AI engine may identify that certain rooms, such as 181D, 181E, and 181F, are not being adequately covered by the HVAC system 182, as they are missing both supply and return vents. This lack of coverage can lead to significant issues such as temperature imbalances, poor air circulation, and the buildup of pollutants or moisture in these rooms.

The AI engine flags the absence of HVAC coverage in rooms 181D-181F as a significant compliance issue and suggests specific modifications to address this problem. These modifications may include the installation of additional supply and return vents in these rooms so that they are properly integrated into the building's overall climate control system. The AI engine may also recommend adjustments to the existing ductwork, such as extending the ducts to reach these previously uncovered areas (181D-181F) or adding new branches to the duct network to facilitate airflow to these rooms. Additionally, the AI engine may suggest the use of alternative ventilation solutions, such as localized air conditioning units or exhaust fans, if extending the existing HVAC system 182 is not feasible.

The AI engine also analyzes the overall layout and spatial relationship between the various rooms 181A-181G and the HVAC system 182, considering factors such as the relative location of each room, the length of duct runs, and the positioning of vents. It evaluates whether the current duct layout allows for efficient airflow distribution throughout the building 181, or if certain areas may experience uneven heating or cooling due to the ductwork configuration. The AI engine may recommend reconfiguring the duct network to optimize airflow and reduce energy consumption, such as by shortening duct runs, increasing insulation on ducts passing through unconditioned spaces, or repositioning vents to more effectively distribute air.

Another aspect of the AI engine's analysis involves evaluating the potential impact of external factors on the building's HVAC system. For example, the AI engine may assess the building's orientation, insulation levels, and exposure to sunlight or prevailing winds, and how these factors interact with the HVAC system's performance. It considers whether the existing ductwork and vent placement adequately account for these external influences, and whether any adjustments are necessary to improve the system's efficiency in different seasons or weather conditions.

Moreover, the AI engine examines the integration of the HVAC system 182 with other building systems, such as electrical and plumbing systems. It checks whether the ductwork intersects with these systems in ways that may cause interference or inefficiencies, such as ducts running too close to electrical wiring, which may lead to energy loss or safety hazards. The AI engine also considers whether the ductwork is properly insulated to prevent condensation and energy loss, particularly in areas where the ducts pass through unconditioned spaces such as attics or crawl spaces.

In cases where the AI engine identifies non-compliance or inefficiencies in the HVAC system 182, it provides detailed recommendations for modifications to bring the system into compliance with relevant building deployment objectives. These recommendations may include specific changes to the ductwork, such as resizing ducts, reconfiguring duct runs, or adding insulation. The AI engine may also suggest upgrades to the HVAC equipment itself, such as installing a more efficient air handler, upgrading the system's filtration capabilities, or adding zoning controls to allow for more precise temperature regulation in different parts of the building.

The AI engine may also take into account the potential impact of these modifications on the building's energy efficiency and overall operational costs. It provides a cost-effective analysis of the recommended changes, helping building owners and operators make informed decisions about which modifications to implement. The AI engine may also suggest ways to offset the costs of these modifications through energy savings or rebates available for energy-efficient upgrades.

In addition to analyzing the design and operational aspects of the HVAC system 182, the AI engine also takes into account the long-term maintenance requirements of the system, particularly focusing on the accessibility and serviceability of the ductwork. For example, the AI engine performs a detailed analysis of the ducts 188A-188C (rigid duct units) located in the basement area 181G of the building 181. The AI engine evaluates each duct not only for its current condition and configuration but also for how easily it can be accessed for maintenance purposes over the life of the building.

Specifically, the AI engine identifies that duct 188A is encased in concrete within the basement area 181G. While this installation method may provide certain benefits, such as protection from physical damage and potential insulation from temperature variations, it also presents significant challenges from a maintenance perspective. The AI engine analyzes the potential difficulties associated with servicing duct 188A, particularly in the event of an issue such as a blockage, a leak, or a need for internal cleaning or inspection. Unlike ducts that are more accessible, a duct encased in concrete may require extensive work to access, potentially involving the removal of concrete, which may be both labor-intensive and costly.

The AI engine further considers the long-term implications of having a duct 188A encased in concrete. It assesses the risk of the duct deteriorating over time due to factors such as corrosion, condensation, or pressure fluctuations, which may be exacerbated by the surrounding concrete. The AI engine calculates the likelihood of such issues arising and compares this with the cost and complexity of accessing the duct for repairs. This analysis helps to determine whether the current installation method is sustainable or if it presents a significant risk to the building's HVAC system 182 reliability over time.

In light of this analysis, the AI engine may recommend alternative approaches for future duct installations or suggest modifications to the existing setup to improve serviceability. For example, the AI engine may propose the installation of access points or service panels near duct 188A, allowing for easier access without the need to remove large sections of concrete. These access points may be strategically placed to align with known weak spots or areas prone to issues, such as bends or junctions in the ductwork.

Additionally, the AI engine may advise against encasing new ducts in concrete and instead suggest using protective coverings that provide similar benefits without the associated maintenance challenges. These coverings may include insulated jackets or rigid protective sleeves that shield the ducts from external damage while still allowing for relatively easy removal if maintenance is required. The AI engine may also recommend routing new ducts through more accessible areas of the basement 181G, where they can be more easily inspected and serviced.

Further, the AI engine may also examine the presence and arrangement of various airflow fixtures across the different spaces 181A-181G. These fixtures include, but are not limited to, windows 185, exhaust fans 186, and air purifiers 187. The AI engine identifies each of these fixtures within the spaces 181A-181G, analyzing their dimensions, placements, and overall contribution to the airflow and ventilation system within the building 181.

When evaluating windows 185, the AI engine determines not only their sizes and locations within the walls of the spaces but also their orientation relative to the building's layout. The AI engine assesses whether the windows 185 are correctly positioned to facilitate natural ventilation, taking into account factors such as the direction of prevailing winds, the sun's path, and the overall airflow patterns within the building. The dimensions of the windows 185 are compared against the required standards for the specific room sizes and intended uses, to assess whether they provide adequate ventilation or if additional airflow fixtures are necessary.

In the case of exhaust fans 186, the AI engine examines their placement in rooms such as kitchens, bathrooms, and other areas prone to moisture and odors. The AI engine analyzes the exhaust fans' capacity, including their airflow rates measured in cubic feet per minute (CFM), to determine whether they are adequate for removing humidity, odors, and airborne contaminants from the spaces. The AI engine also considers the exhaust fans' positions, determining if they are located strategically to draw air efficiently from the entire room rather than just one corner.

For air purifiers 187, the AI engine identifies their presence and assesses their effectiveness in maintaining indoor air quality. It evaluates the type of air purifiers used, including their filtration capabilities, such as HEPA filters, activated carbon filters, or UV light purifiers. The AI engine determines whether the placement of these air purifiers is optimal for covering the entire space. It checks if the purifiers are positioned away from obstructions and are capable of drawing in air from all parts of the room without being blocked by furniture or walls.

Beyond airflow fixtures, the AI engine may also identify the presence of non-airflow fixtures within the spaces, such as beds, tables, cupboards, and other furniture. The AI engine assesses the spatial relationships between these non-airflow fixtures and the airflow fixtures. It considers whether the placement of a furniture obstructs the airflow from vents, windows, exhaust fans, or air purifiers. For example, the AI engine may detect that a large cupboard is placed directly in front of a window, severely limiting the flow of fresh air into the room.

The AI engine uses this information to evaluate the effectiveness of the ventilation system in each space. If it identifies that the placement of furniture is hindering airflow, it provides recommendations for rearranging the furniture to enhance air circulation. For example, the AI engine may suggest moving a bed or table that is blocking an air vent to a different location within the room. It may recommend repositioning cupboards or large pieces of furniture so that air can flow freely throughout the space.

The AI engine may also identify and verify the presence of indoor sensors 184 within various spaces 181A-181G in the building 181, focusing on their necessity and functionality. The AI engine evaluates the necessity of these sensors based on the specific requirements of each space, such as occupancy levels, intended use, and existing airflow fixtures. Indoor sensors 184 may include, but are not limited to, air quality sensors, temperature sensors, humidity sensors, and carbon dioxide (CO2) sensors. The AI engine identifies the presence of these sensors, assesses their placement within the rooms, and determines whether their current locations are optimal for accurate readings and effective control of the HVAC system 182.

The AI engine first examines the type of indoor sensors 184 present within each space, analyzing whether these sensors are appropriate for the room's purpose and environmental conditions. For example, in a high-occupancy area e.g., the living room 181A, the AI engine identifies the need for an air quality sensor to monitor pollutants and a CO2 sensor to track occupancy levels and adjust ventilation accordingly. In the kitchen area 181B, the AI engine may detect the absence of temperature and humidity sensors to control the HVAC system's response to cooking activities, which generate heat and moisture. Similarly, in a water closet area, the AI engine looks for humidity sensors to manage moisture levels that may lead to mold growth.

Next, the AI engine examines the placement of these indoor sensors 184, analyzing whether their positions within each room allow for accurate monitoring of environmental conditions. The AI engine evaluates the proximity of the sensors 184 to airflow fixtures such as vents, windows, and exhaust fans. It determines if the sensors 184 are positioned in areas where they can effectively measure the air quality and temperature of the space without interference from direct drafts or obstructions. For example, an air quality sensor should not be placed too close to a vent, where the airflow from supply ducts (e.g., from 182A) may skew its readings. The AI engine identifies whether sensors 184 are optimally placed for accurate data collection and provides recommendations for repositioning if necessary.

In addition to evaluating the presence and placement of indoor sensors 184, the AI engine also considers the integration of these sensors with outdoor sensors 183. The outdoor sensors 183 monitor external environmental conditions, such as outdoor air quality, temperature, humidity, and pollutant levels. The AI engine analyzes how data from both indoor and outdoor sensors can be used in conjunction to control the HVAC system 182 more effectively. It identifies the sensors' communication with the HVAC system 182, assessing whether the system is equipped to respond dynamically to changes in both indoor and outdoor conditions.

The AI engine determines how the data from the indoor sensors 184 and outdoor sensors 183 can be used to optimize the HVAC system's operation. For example, if an indoor air quality sensor detects that the air inside the building 181 is cleaner and less polluted than the air detected by an outdoor sensor, the AI engine may recommend reducing the intake of outdoor air and recirculating the indoor air to maintain indoor air quality while conserving energy. Conversely, if the outdoor air quality is superior, the AI engine may suggest increasing the intake of fresh air to improve indoor conditions. This may be done in support of a Building Management System (BMS) integrated to indoor sensors 184, outdoor sensors 183, and the HVAC system 182. The AI engine may also look for the presence of BMS system and analyze the BMS system in detail if present. If the BMS system is not present, the AI engine may suggest integrating one in the building design.

Referring now to FIG. 1H, an exemplary portion 190 of a design plan is illustrated, which is analyzed by the AI engine for comprehensive compliance analysis related to airflow standards within a building. The design portion 190 specifically represents a first unit 191 of the building, which may be a residential room, office space, or any other enclosed area within the larger structure. The AI engine's analysis of the first unit 191 begins with the calculation of its area, taking into account the exact dimensions of the room to determine the volume of air that needs to be circulated to maintain optimal indoor air quality. The first unit 191 is detailed to include various airflow fixtures, which are identified and assessed by the AI engine.

Within the first unit 191, the AI engine identifies the presence of an air conditioning (AC) unit 193, which is connected to an external condenser unit 192A through an airflow line 193A. The AI engine analyzes this connection, evaluating whether the size and capacity of the AC unit 193 are appropriate for the area of the first unit 191. The analysis also considers the placement of the AC unit 193 within the room, determining if it is positioned in a way that allows for efficient cooling and air distribution. The AI engine also examines the airflow line 193A, which connects the internal AC unit 193 to the condenser unit 192A. It evaluates whether this line is properly insulated and securely connected to avoid any potential leaks or inefficiencies that may compromise the cooling process.

In addition to the AC unit 193, the AI engine also identifies a ceiling fan 195 located centrally in the first unit 191. The AI engine analyzes the position of the ceiling fan 195 relative to other airflow fixtures, such as the AC unit 193 and an exhaust vent 194. It determines whether the ceiling fan 195 is effectively circulating air within the first unit 191, preventing stagnation and helping to distribute conditioned air evenly throughout the space. The AI engine also assesses whether the ceiling fan 195 is correctly sized for the room, considering its diameter and speed settings, and the area of the first unit, to maximize airflow without causing excessive drafts.

The AI engine further evaluates the exhaust vent 194, which serves as an outlet for stale air from the first unit 191. This vent is useful for maintaining air quality by removing excess moisture, odors, and airborne contaminants. The AI engine examines the exhaust vent's 194 placement on the wall, assessing whether it is positioned to efficiently draw out stale air 194A from the room without creating negative pressure zones that may hinder the performance of other airflow fixtures. In this exemplary scenario, the AI engine identifies a significant obstruction in the airflow path where the exhaust vent 194 is located. The AI engine detects that the table, where the TV 196 is placed, is directly blocking the exhaust vent 194. This obstruction prevents the efficient removal of stale air from the room, leading to potential issues such as poor air quality, increased humidity, and accumulation of airborne contaminants. The AI engine recognizes this non-compliance with ventilation standards and suggests relocating the table or repositioning the TV 196 to an area that does not interfere with the vent 194.

The AI engine also evaluates the sufficiency of the available airflow fixtures, including the air conditioning unit 193, ceiling fan 195, and exhaust vent 194, within the first unit 191. To determine whether these fixtures are adequate, the AI engine considers several key factors. First, it calculates the area of the first unit 191, factoring in the room's dimensions to assess the overall volume of air that needs to be circulated, cooled, or ventilated. Next, the AI engine analyzes the intended use of the first unit 191, which may be a living room, bedroom, office, or another type of space, each with specific airflow requirements. The AI engine cross-references these requirements with relevant building deployment objectives to determine the minimum airflow rates and ventilation needs specific to the unit's use. The AI engine then examines the placement, capacity, and coverage area of each airflow fixture. For example, the AI engine evaluates whether the air conditioning unit 193 has sufficient capacity to cool the entire space effectively, whether the ceiling fan 195 provides adequate air circulation throughout the room, and whether the exhaust vent 194 can efficiently remove stale air from the unit.

Additionally, the AI engine assesses the spatial relationship between these fixtures, checking for optimal placement that allows for even distribution of air without dead zones or areas of poor circulation. If the AI engine finds that the current quantity, type, or configuration of airflow fixtures does not meet the required standards, it may identify discrepancies and recommend specific modifications, such as adding additional vents, upgrading the capacity of existing fixtures, or repositioning the fixtures to achieve better airflow and compliance with relevant building deployment objectives.

The AI engine analyzes the indoor sensors 197 and outdoor sensors 198 to evaluate their effectiveness in maintaining the desired environmental conditions within the first unit 191. These sensors, which may include air quality sensors, temperature sensors, humidity sensors, and occupancy sensors, are examined for their ability to accurately monitor both the indoor and outdoor environments. The AI engine assesses the placement, functionality, and integration of these sensors within the unit's overall environmental control system to determine how well they contribute to maintaining optimal air quality, temperature, and comfort levels (for example, as discussed in FIG. 1G above).

The AI engine may also consider the presence of other units adjacent to the first unit 191 by analyzing the spatial relationship and airflow interactions among these units. It evaluates the dominance rank of each unit within the building, including the first unit 191, to determine which spaces hold greater priority in compliance considerations. For example, the AI engine may assign higher dominance ranks to living spaces like the first unit 191 compared to utility or storage areas, which may influence how resources such as airflow or access to external air may be distributed.

Based on these dominance ranks, the AI engine may suggest modifications to the design. If the first unit 191 has a higher dominance rank compared to an adjacent space, the AI engine may recommend merging portions of adjacent common areas into the first unit 191 to meet compliance requirements, such as increasing the available airflow or adjusting spatial layout to accommodate more efficient ventilation. The AI engine may also analyze the placement and function of the other condenser units 192B-192E, which serve the surrounding units, so that their operation does not negatively impact the airflow or environmental conditions within the first unit 191.

Referring now to FIG. 2A, a given two-dimensional reference 200 may have a number of elements that an observer and/or an AI engine may classify as features 201-209 such as, for example, one or more of: exterior walls 201; interior walls 202; doorways 204; windows 203; plumbing components, such as sinks 205, toilets 206, showers 207, water closets or other water or gas related items; kitchen counters 209 and the like. The two-dimensional references 200 may also include narrative or text 208 of various kinds throughout the two-dimensional references. For example, the AI engine may identify the locations of windows, supply vents, fans, and exhaust vents to determine if they are positioned correctly relative to walls and doorways to meet building deployment objectives related to airflow related requirements.

Identification and characterization of various features 201-209 and/or text may be included in the input two-dimensional references. Generation of values for variables included in generating a bid may be facilitated by splitting features into groups called ‘disparate features’ 201-209 and boundary definitions and generation of a numerical value associated with the features, wherein numerical values may include one or more of: a quantity of a particular type of feature; size parameters associated with features, such as the square area of a wall or floor; the complexity of features (e.g. a number of angles or curves included in a perimeter of an area; a type of hardware that may be used to construct a portion of a building, a quantity of a type of hardware that may be used to construct a portion of the building; or other variable value. For example, the AI engine may calculate the total number of airflow fixtures in a given area and compare it with the requirements set by the relevant building deployment objectives.

In some embodiments, a recognition step may function to replace or ignore a feature. For example, for a task goal of the result shown in FIG. 2B, features such as windows 203, and doorways, 204, may be recognized and replaced with other features consistent with exterior walls 201 or interior walls 202 (as shown in FIG. 2A). Other features may be removed, such as the text 208, the plumbing features and other internal appliances and furniture which may be shown on drawings used as input to the processing. Again, such feature recognition may be useful to accomplish other goals, but for a goal of boundary 211 definition that delineates a floorplan 210 as illustrated in FIG. 2B a pictorial representation may be purposefully devoid of such features, as illustrated. This simplification allows the AI engine to focus on useful structural elements, so that boundary definitions are precise and unencumbered by unnecessary details.

Referring now to FIG. 2B, a boundary 211 is illustrated around a grouping of defined spaces 213-216. Spaces are areas within a boundary (which may include, but are not limited to rooms, hallways, stairwells etc.). For example, the AI engine may identify various rooms in the building and outline its boundary, to determine if all required airflow fixtures are within this space and correctly positioned relative to one another and according to the usage of room.

FIG. 2B illustrates an AI predicted boundary 211 based upon an analysis of the floorplan 210 illustrated in FIG. 2A. A transition from FIG. 2A to FIG. 2B illustrates how an AI engine successfully distinguishes between wall features and other features such as a shower 207, kitchen counter 209, toilet 206, bathroom sink 205, etc. shown in FIG. 2A. This distinction is for accurately determining the spatial relationships between airflow fixtures and other structural elements by the AI engine to evaluate adherence with building deployment objectives.

In another aspect, in some embodiments, a boundary may include a polygon 211B. A polygon may be any shape that is consistent with a design submitted for AI analysis. For example, a rectangular polygon 211B may be based upon a wall segment 211A and have a width X 218 and a length Y 219. Boundaries that include polygons are useful, for example, in creating a three-dimensional representation of a design plan. This three-dimensional representation can then be analyzed for airflow objectives, to determine if all airflow fixtures are placed within appropriate spaces and meet spatial requirements such as clearance for maintenance and obstruction free airflow.

According to the present invention, a boundary may be represented on a user interface as one or both of: one or more line segments, and one or more polygons. In addition, a feature may be represented as a single point, a polygon, an icon, or a set of polygons. In some embodiments, a point may be placed in a centroid position for the feature, and the centroid points may be counted, summarized, subtracted, averaged, or otherwise included in mathematical processes. For example, the AI engine may place a centroid at the center of a vent opening and calculate its distance from nearby walls to verify adherence with clearance preferences.

In some embodiments, an analytical use for a boundary may influence how a boundary is represented. For example, the determination of a length of a wall section, or size of a feature may be supported via a boundary that includes a line segment. A count of feature type may be supported with a boundary that includes a single point or predefined polygon or set of polygons. Extrapolation of a two-dimensional reference into a three-dimensional representation may be supported with a boundary that includes polygons. This capability allows the AI engine to perform complex spatial analyses, such as verifying that airflow fixtures are correctly spaced within a room and that their placement adheres to building deployment objective requirements.

A scale 217 may be used to indicate a size of features included in a technical drawing included in the two-dimensional reference. As indicated above, executable software may be operative with a controller to count pixels on an image and apply a scale to a bitmapped image. Alternatively, a user may input a drawing scale for a particular image, drawing or other two-dimensional reference. Standard measurement units referenced in a scale include inches: feet, centimeters: meters, or any other appropriate unit. For example, if the scale indicates that each pixel represents one inch, the AI engine can accurately calculate the distance between a vent opening and the TV stand (as depicted in FIG. 1H) to determine adherence with spacing requirements specified by the relevant airflow related building deployment objectives.

In some embodiments, a scale 217 may be determined by manually measuring a room, a component, or other empirical basis for assessing a relative size. Examples therefore include a scale included as a printed parameter on two-dimensional reference or obtained from dimensioned features in the drawing. For example, if it is known that a particular wall is thirty feet in length, a scale may be based upon a length of the wall in a particular rendition of the two-dimensional reference and proportioned according to that length. This scaling process is useful for the AI engine to accurately assess the size and spacing of airflow fixtures within the design plan, to determine if they comply with all relevant building deployment objectives and preferred practices.

Referring now to FIG. 2C, a user interface 220 is illustrated with multiple regions 221-224. The multiple regions 221-224 may be presented via different hatch representations or other distinguishing patterns (in some embodiments regions may also be represented as various colors etc.). During the training of AI engines, and in some embodiments, when a submitted design drawing includes highly customized or unique features, a user may wish to adjust an automated identification of boundaries and automated filling of space within the boundaries. For example, if the AI engine incorrectly identifies a kitchen area as a drawing room due to unusual layout features, the user can manually adjust these boundaries in the interface.

During training processes executed by a controller, such as those included in an AI engine made operative by the controller, and in some embodiments, when a submitted design drawing includes highly customized or unique features, an automated identification of boundaries and automated filling of space within the boundaries may be included in the interactive user interface may not be according to a particular need of a user. Therefore, in some embodiments of the present invention, an interactive user interface may be generated that presents a user with a display of one or more boundaries and pattern or color filled areas arranged as a reproduction of a two-dimensional reference input into the AI engine. This allows users to make manual corrections where the AI engine's automatic boundary assignments are not accurate enough, especially in complex areas like multi-functional rooms where airflow fixtures may serve multiple purposes.

In some embodiments, the controller may generate a user interface 220 that includes indications of assigned vertices and boundaries, and one or more filled areas or regions with user changeable editing features to allow the user to modify the vertices and boundaries. For example, the user interface may enable a user to transition an element such as a vertex to a different location, change an arc of a curve, move a boundary, of change an aspect of polylines, polygons, arcs, circles, ellipses, splines, NURBS or predefined subsets of the interface. The user can thereby “correct” an assignment error made by the AI engine, or simply rearrange aspects included in the interface for a particular purpose or liking. For example, if a user needs to adjust the boundary of a drawing room area to accommodate a specific number of fixtures, the user interface allows these adjustments to be made easily, thereby enhancing the accuracy of the airflow objective analysis.

In some embodiments, modifications and/or corrections of this type can be documented and included in training datasets of the AI model, also in processes described in later portions of the specification. This feedback loop allows the AI engine to improve over time, becoming more accurate in identifying and categorizing spaces and airflow fixtures in future analyses.

Discrete regions may be regions associated with an estimation function. A region that is contained within a defined wall feature may be treated in different ways such as ignoring all areas in a boundary, to counting all areas in a boundary (even though regions do not include boundaries). If the AI engine counts the area, it may also make an automated decision on how to allocate the region to an adjacent region or regions that the region defines. For example, if a drawing room and a hallway share a boundary, the AI engine may allocate space between these areas so that airflow fixtures like vents and exhaust fans have sufficient clearance.

Referring to FIG. 2D, an exemplary user interface 230 illustrates a user interface floorplan model 231 with boundaries 236-237 between adjacent regions 233-234 with interior boundaries 236-237 that may be included in an appropriate region of a dynamic component. The AI may incorporate a hierarchy where some types of regions may be dominant over others, as described in more detail in later sections. Regions with similar dominance ranks may a share space, or regions with higher dominance ranks may be automatically assigned to a boundary. For example, a kitchen may take precedence over a pantry in terms of space allocation, so that all necessary airflow fixtures are correctly placed In general, a dominance ranking schema will result in an area being allocated to the space with the higher dominance rank. In some embodiments, a dominance rank will allocate an area that may be used in determining an occupancy load. Moreover, in those embodiments that analyze a dynamic file (such as, for example, a Revit® compatible file) a dominance rank may be included, or added to, one or more dynamic features and be modified as the dynamic feature is modified.

In some embodiments, an area 235A between interior boundaries 236-237 and an exterior boundary 235 may be fully assigned to an adjacent region 232-234. An area between interior boundaries 235A may be divided between adjacent regions 232-234 to the interior boundaries 236-237. In some embodiments, an area 235A between boundaries 236-237 may be allocated equally, or it may be allocated based upon a dominance scheme where one type of area is parametrically assessed as dominant based upon parameters such as its area, its perimeter, its exterior perimeter, its interior perimeter, and the like. Parameters may also be based upon items that are automatically counted using AI analysis of pixel patterns that identify a pattern as an item, such as, by way of non-limiting example, one or more of: doors or other paths of egress; plumbing fixtures; fixed obstacles; stairs; inclines; and declines. For example, if a bathroom is identified as a dominant space, the AI engine may allocate more area to accommodate additional airflow fixtures, providing adherence with relevant building deployment objectives.

In some examples, a boundary 235-237 and associated area 235A may be allocated to a region 232-234 according to an allocation schema, such as, for example, an area dominance hierarchy, to prioritize a kitchen over a bathroom, or a larger space over a smaller space. In some embodiments, user selectable parameters (e.g., a bathroom having parameters such as two showers and two sinks may be more dominant over a kitchen having parameters of a single sink with no dishwasher). These parameters may be used to determine boundary and/or area dominance. A resulting computed floorplan model may include a designation of an area associated with a region as illustrated in FIGS. 2A-2D. In various embodiments, different calculated features are included in a user interface floorplan model 231 such as features representing aspects of a wall, such as, for example, center lines, the extent of the walls, zones where doors open and the like, and these features may be displayed in selected circumstances.

Some embodiments may also include AI analysis of a dynamic file, such as a Revit or Revit compatible file and/or a raster file with patterns of dots, the AI may generate a likelihood that a region or area represented by one or both of a polygon or pattern of dots, includes a common path or dead end or an area definable for determining an occupancy load, egress capacity, travel distance and/or other factor that may influence a decision on adherence with an objective.

Once boundaries have been defined a variety of calculations may be made by the system. A controller may be operative to perform method steps resulting in calculation of a variable representative of a floorplan area, which in some embodiments may be performed by integrating areas between different line features that define the regions. For example, the AI engine may calculate the total floor area allocated to a drawing room to determine if the number of airflow fixtures is adequate for the expected occupancy load.

Alternatively, or in addition to method steps operative to calculate a value for a variable representative of an area, a controller may be operative to generate a value for element lengths, which values may also be calculated. For example, if ceiling heights are measured, presented on drawings, or otherwise determined, then the volume for the room and surface area calculations for the walls may be made. There may be numerous dimensional calculations that may be made based on the different types of model output and the user input calibration factors and other parameters entered by the user. These calculations may include determining the slope of vents or the height of the chimney from the stove to confirm that these fixtures meet building deployment objective requirements.

In some embodiments, a controller may be provided with two dimensional references that include a series of architectural drawings with disparate drawings representing different elevations within a structure. A three-dimensional model may be effectively built based upon a sequenced stacking of the disparate drawings representing different levels of elevations. In other examples, the series of drawings may include cross sectional representation as well as elevation representation. A cross-section drawing, for example, may be used to infer a common three-dimensional nature that can be attributed to the features, boundaries and areas that are extracted by the processes discussed herein. Elevation drawings may also present a structure in a three-dimensional perspective. Feature recognition processes may also be used to create three-dimensional model aspects. Feature recognition processes may also be used to create three-dimensional model aspects, further enhancing the accuracy of airflow objective analysis by considering vertical clearances and the routing of ducts across different ceilings.

Referring now to FIG. 2E, an exemplary design plan 240 illustrates a hospital ward 241, which the AI engine evaluates to assess and recommend the most appropriate setup for optimal airflow and environmental management within the space. The ward 241, as depicted in the design plan 240, is a confined space bounded by structural elements that the AI engine identifies and categorizes. The AI engine carries out a comprehensive analysis of the airflow dynamics and spatial configuration of the ward 241.

The AI engine first identifies the patient bed settings 241A-241B within the ward 241. These bed settings are areas where patients will spend most of their time, necessitating a well-considered airflow system to maintain air quality and comfort. The AI engine identifies that the bed settings 241A-241B are confined within partitions 245 and 246, which are likely intended to provide privacy and a controlled environment for each patient. However, the AI engine also recognizes that these partitions 245-246 may pose challenges to the airflow within the ward 241, potentially creating areas of stagnant air that may affect patient comfort and health.

As the AI engine delves deeper into the analysis, it examines an airflow 243 provided by an HVAC system 242. The airflow 243 is primarily directed into the corridors 244, which are central to the ward's layout. The AI engine assesses this setup and determines that while the corridors 244 receive adequate airflow, the patient areas (241A and 241B) may not benefit from the same level of air circulation. The partitions 245 and 246, while effective in creating separate spaces, may also act as barriers that limit the free flow of air from the corridors 244 into the patient areas. This restriction in airflow can lead to a buildup of stale air, which may, in turn, contribute to the spread of infections or cause discomfort to the patients.

To address this issue, the AI engine may suggest several modification suggestions to improve airflow within the patient areas. One recommendation may be the installation of additional vents or air ducts directly above or near the patient beds 241A-241B to enhance air circulation in these useful areas. The AI engine may also propose modification suggestions to the partition design, such as incorporating louvered panels or adjustable openings that allow air to pass through while still maintaining privacy. These changes may help to distribute the conditioned air more evenly throughout the ward 241, thereby improving air quality and reducing the risk of airborne contaminants accumulating around the patients.

The AI engine also identifies the presence of a nearby water closet area 247 within the ward. The water closet is an essential facility in any hospital environment, requiring effective ventilation to manage odors and humidity. However, the AI engine determines that the water closet area 247 lacks an adequate exhaust mechanism, such as an exhaust fan, to expel odors and moisture. This absence can lead to a buildup of unpleasant smells and potentially higher humidity levels, which may affect the overall environment within the ward 241.

In response to this finding, the AI engine may recommend the installation of an exhaust fan within the water closet area 247. The exhaust fan is tasked with removing stale air, odors, and excess moisture from the water closet area 247, thereby maintaining a fresher and more hygienic environment. The AI engine may also suggest integrating the exhaust system with the existing HVAC setup to optimize airflow throughout the entire ward 241, so that the air remains clean and comfortable for both patients and healthcare providers.

Furthermore, the AI engine may assess the overall impact of these airflow issues on patient recovery and well-being. Poor ventilation in the patient areas may slow down recovery by increasing the likelihood of infections or making the environment less conducive to healing. The AI engine may simulate different scenarios based on the proposed modifications, allowing hospital administrators (or stakeholders) to see the potential benefits of improved airflow before implementing any changes. These simulations can provide valuable insights into how adjustments to the HVAC system 242, partition design, and exhaust mechanisms may enhance patient comfort and outcomes.

The AI engine also considers the efficiency of the current HVAC system 242 in maintaining the desired temperature and humidity levels within the ward 241. It analyzes whether the HVAC system 242 has the capacity to handle the specific needs of the space, particularly with the added demands of maintaining separate environments within the partitioned patient areas. If the system is found to be lacking, the AI engine may recommend upgrades to the HVAC system 242, such as increasing its capacity or adding supplementary units so that all areas of the ward 241 are adequately served.

Additionally, the AI engine evaluates the potential for long-term improvements in the ward's design to better support patient care. This may include suggestions for reconfiguring the layout to allow for more efficient airflow, optimizing the placement of patient beds 241A-241B to align with the air distribution, and considering the use of advanced air filtration systems to further enhance the air quality.

Referring now to FIGS. 2F-2H, these figures illustrate different types of HVAC ducts, along with their associated duct supports, as analyzed by the AI engine for airflow objective within a building. These figures provide a detailed view of various duct configurations that can be found in different sections of a building, each serving specific functions within the HVAC system. The AI engine systematically examines each type of duct and its supports to determine if they meet the required building deployment objectives and preferred practices for airflow, safety, and efficiency.

FIG. 2F presents a flexible duct unit 250, which is widely used in HVAC systems due to its flexibility and ease of installation. Flexible ducts are made from a combination of materials, including a metal wire coil covered with a plastic or rubber-like material that allows the duct to bend and curve around obstacles. This flexibility makes them ideal for spaces with limited access or where rigid ducts cannot be installed. However, the AI engine identifies that flexible ducts have some drawbacks, such as the potential for airflow restrictions if not installed correctly. The bends and curves can create areas of turbulence, leading to reduced airflow efficiency. Additionally, flexible ducts are more susceptible to damage, such as punctures or tears, which can result in air leaks. The AI engine may analyze the flexible duct unit 250 to determine if the installation meets the proper standards by checking for any excessive bends or kinks that may impede airflow. The AI engine also examines the ducts supports 251-252, specifically analyzing their heights 251A-252B from the ceiling. Proper height is required for maintaining the duct's shape and preventing sagging, which can further restrict airflow. The AI engine also evaluates the distances 253 between the duct supports 251-252. These distances are useful, as inadequate support spacing can cause the duct to sag or even collapse under its own weight, while excessive spacing may not provide enough stability, leading to potential long-term damage.

FIG. 2G illustrates another type of duct unit 260, which is a rigid duct constructed from sheet metal. Rigid ducts are commonly used in HVAC systems due to their durability and ability to maintain consistent airflow with minimal resistance. The AI engine examines the duct unit 260, focusing on its structural integrity and installation accuracy. The rigid duct 260 is supported by duct hangers 261-263, which are used for holding the duct 260 in place and preventing it from shifting over time. The AI engine assesses the distances 264 between the duct hangers 261-263 to verify if they provide adequate support. If the hangers 261-263 are spaced too far apart, the duct may experience sagging or vibration, which may lead to noise issues or even duct separation at the joints. Conversely, if the hangers 261-263 are too close together, it may indicate over-engineering, which may unnecessarily increase installation costs. The AI engine considers various scenarios, such as the potential impact of thermal expansion and contraction on the duct system, which may affect the distances between support hangers 261-263. It also analyzes the height 265 of the hangers 261-263 from the ceiling, determining if the ducts are installed at the appropriate level to connect seamlessly with other components of the HVAC system.

FIG. 2H showcases a rectangular duct unit 270, which is commonly used in commercial buildings where large volumes of air need to be moved efficiently. Rectangular ducts are known for their ability to handle high airflow rates, but they also require careful installation to avoid issues such as air leakage or noise. The AI engine scrutinizes the duct unit 270, focusing on the alignment and sealing of the duct sections to prevent any air from escaping. The duct supports 271-272 are analyzed for their height 274 from the ceiling, which is required for maintaining the duct's position and alignment with other components, such as diffusers or grilles. The AI engine also examines the distance 273 between the duct supports 271-272 to determine if the duct 270 is adequately supported along its entire length. In some cases, the AI engine may detect that the duct is sagging or vibrating due to insufficient support, and it may recommend additional supports to stabilize the system. The AI engine also evaluates the width of the duct 270, as variations in duct width can affect airflow velocity and pressure, leading to imbalances in the HVAC system. For example, if the duct width is too narrow, it may create high-velocity airflows that can cause noise and reduce comfort in occupied spaces.

The AI engine is equipped to handle a variety of scenarios when analyzing these different types of duct units. For example, it may consider the building's usage, occupancy levels, and climate conditions when determining the appropriate duct size, material, and support configuration. In a scenario where the building is located in a region with significant temperature fluctuations, the AI engine may recommend using flexible ducts in certain areas to accommodate thermal expansion while suggesting rigid ducts in other areas for their durability and stability. Additionally, the AI engine may analyze the building's design to identify any potential obstacles that the ducts need to navigate, such as beams, walls, or other structural elements. In these cases, the AI engine may suggest specific types of duct supports that can be adjusted in height or orientation to maintain proper airflow despite the obstacles.

Furthermore, the AI engine may assess the ductwork's overall design to identify any areas where airflow may be compromised due to poor duct placement or support configuration. For example, if the ductwork includes long horizontal runs without adequate support, the AI engine may detect potential sagging issues and recommend the installation of additional supports to maintain a consistent airflow path. The AI engine may also evaluate the impact of duct insulation on airflow efficiency. In situations where the duct is located in unconditioned spaces, such as attics or crawl spaces, the AI engine may suggest adding insulation to prevent heat loss or gain, which may affect the HVAC system's performance.

Referring now to FIG. 2I, an exemplary design plan for a water closet area 280 is analyzed in detail by the AI engine in some embodiments of the present invention. The AI engine conducts a thorough examination of the water closet area 280 to identify various airflow and non-airflow fixtures that are useful to meet relevant building deployment objectives. The AI engine identifies the presence of the water closet area 280 in the design plan by recognizing fixtures that are commonly found in such spaces. These fixtures may include a water closet 281, a sink 282, a mirror 283, and a soap dispenser 284. Each of these fixtures is analyzed by the AI engine to determine their placement, size, and functional relationship within the space.

For airflow objective analysis, the AI engine specifically focuses on the presence or absence of airflow fixtures such as an exhaust fan and a window 285. In the scenario depicted in FIG. 2I, the AI engine identifies the window 285 as the primary means of ventilation within the water closet area 280. The AI engine calculates several key dimensions associated with the window 285, which are used for determining the effectiveness of ventilation in the space. One of the dimensions calculated by the AI engine may be the height 285A of the window 285 from the floor. The AI engine examines whether the window is positioned at an appropriate height to facilitate natural ventilation, considering factors such as the typical placement of windows in water closet areas and the overall layout of the space.

Additionally, the AI engine calculates the size 285B of the window 285, which is a significant factor in evaluating the potential for adequate air exchange within the water closet area 280. The size of the window directly impacts the volume of air that can be moved in and out of the space, which is required for maintaining air quality and removing odors. The AI engine compares the window size 285B with standard ventilation requirements set forth by the relevant building deployment objectives to determine if it meets the necessary criteria.

The AI engine also assesses the relationship between the identified airflow fixtures and the non-airflow fixtures within the water closet area 280. For example, the proximity of the window 285 to the water closet 281 and the sink 282 is analyzed to determine if the placement allows for effective ventilation of moisture and odors generated during use. If the window 185 is positioned too far from these fixtures, the AI engine may flag this as a potential issue and recommend modifications, such as the addition of an exhaust fan or repositioning of the window 185.

In some embodiments, the AI engine may provide recommendations for improving airflow within the water closet area 280. For example, if the window 285 is found to be insufficient in size or improperly positioned, the AI engine may suggest installing an exhaust fan to supplement ventilation. The AI engine may also recommend adjustments to the window's dimensions or height to enhance natural airflow. Additionally, the AI engine may analyze the material and design of the window 185 to determine its impact on ventilation efficiency. For example, a window with limited operability or obstructed by curtains or blinds may be flagged by the AI engine as needing modification to improve airflow.

Furthermore, the AI engine considers the overall design and configuration of the water closet area 280 to assess whether the ventilation provided by the window 285 is adequate for the expected occupancy and use patterns. The AI engine may use data from similar spaces or historical data on air quality in water closet areas to make informed recommendations.

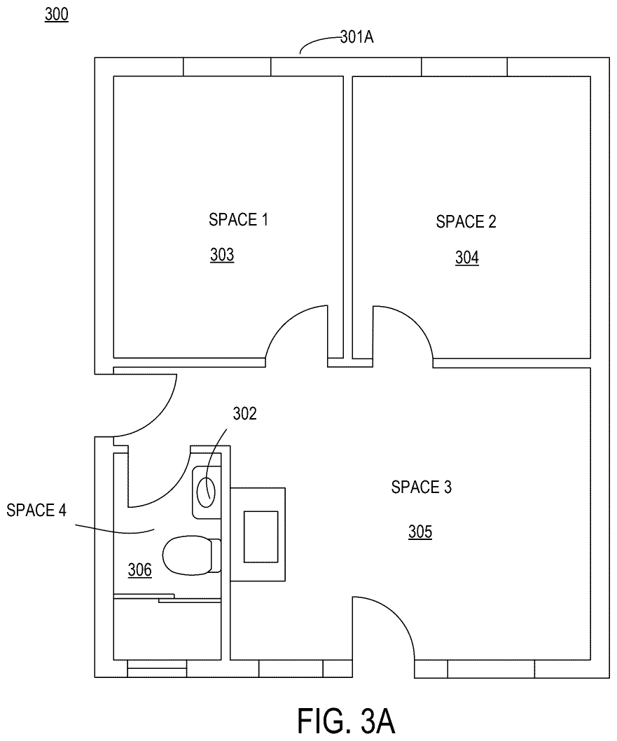

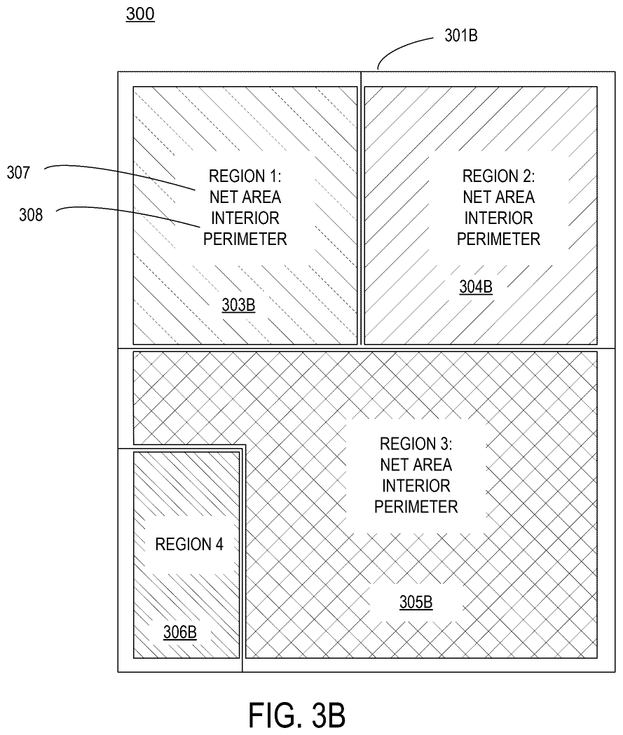

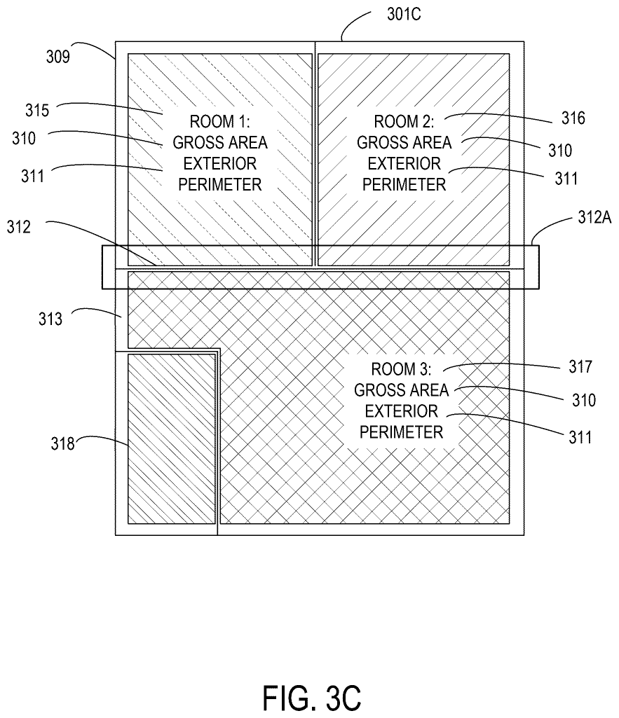

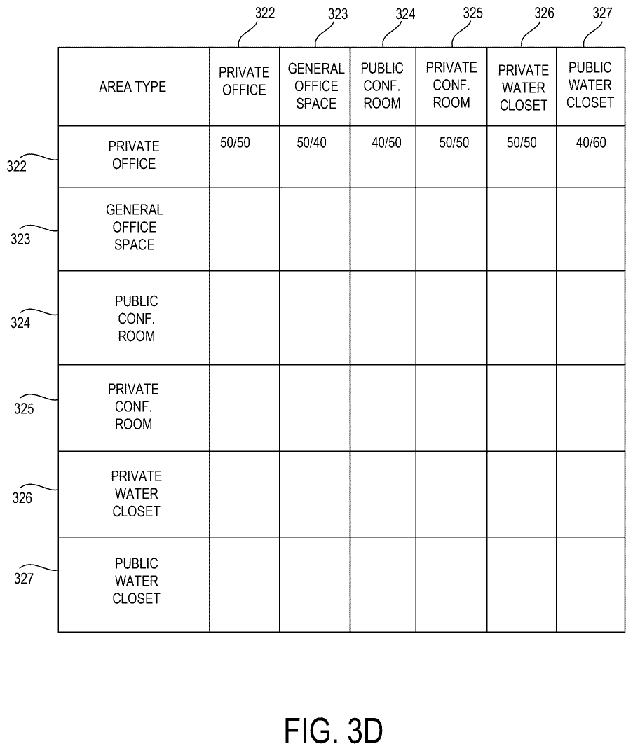

Referring now to FIGS. 3A-3C a user interface 300 may generate multiple different user views, each view has different aspects related to the two-dimensional reference drawing input. For example, referring now to FIG. 3A, a user interface 300 with a replication view 301A may include replication of an original floor plan represented by a two-dimensional reference, without any controller added features, vectors, lines, or polygons integrated or overlaid into the floorplan. The replication view 301A includes various spaces 303-306 that are undefined in the replication view 301A but may be defined during the processes described herein. For example, these spaces may represent different rooms or areas within a building, such as bathrooms, kitchens, or utility rooms, which the AI engine will later analyze for airflow adherence. For example, some or all of a space 303-306 may correlate to a region in a region view 301B.

The replication view 301A, may also include one or more fixtures 302. A rasterized version (or pixel version) of the fixtures 302 may be identified via an AI engine. If a pattern is present that is not identified as a fixture 302, a user may train the AI engine to recognize the pattern as a fixture of a particular type. For example, if the AI engine does not recognize a newly designed exhaust or window, the user can manually classify it as such, allowing the system to tally this fixture type accurately. The controller may generate a tally of multiple fixtures 302 identified in the two-dimensional reference. The tally of multiple fixtures 302 may include some or all of the fixtures identified in the two-dimensional reference and be used to generate an estimate for completion of a project illustrated by, or otherwise represented by the two-dimensional reference.

Referring now to FIG. 3B, in the user interface 300 a user may specify to a controller that one of multiple views available to be presented via the interface. For example, a user may designate via an interactive portion of a screen displaying the user interface 300 that a region view 301B be presented. The region view 301B may identify one or more regions and/or spaces 303B-306B identified via processing by a controller, such as for example, via an AI engine running on the controller. The AI engine may, for example, automatically delineate a kitchen area based on the airflow fixtures like chimneys or supply vents, presenting this in the region view for further analysis. The region view 301B may include information about one or more regions 303-306 delineated in the region view 301B of the user interface 300. For example, the controller may automatically generate and/or display information descriptive of one or more of: user displays, printouts or summary reports showing a net interior area 307 (e.g., a calculation of square footage available to an occupant of a region), an interior perimeter 308, a type of use a region 303B-306B will be deployed for, or a particular material to be used in the region 303B-306B. For example, Region 4 306B may be designated for use as a bathroom; and flooring and wall board associated with Region 4 may be designated as needing to be waterproof material. Region 4 306B may be designated as a kitchen, and the system may automatically suggest a chimney and an exhaust vent based on this designation.

Referring now to FIG. 3C, a gross area region view 301C and 309 is illustrated. As illustrated in FIG. 3B, a user interface may include interactive devices for display of additional parameters, such as, for example, one or more of: a net interior area 307 may generate a designation of a value that is in contrast to a gross area 310 and exterior perimeter 311. The selection of gross area 310 may be more useful to a proprietor charging for a leased space, but may be less useful to an occupant than a net interior area 307 and interior perimeter 308. For airflow adherence, the AI engine may analyze both net and gross areas to determine whether sufficient space is available for required airflow fixtures, so that the drawing room area has adequate ceiling area for adherence with preferred objectives. One or more of the net interior areas 307, interior perimeter 308 gross area 310 and exterior perimeter 311 may be calculated based upon analysis by an AI engine of a two-dimensional reference.

In addition, a height for a region may also be made available to the controller and/or an AI engine, then the controller may generate a net interior volume and vertical wall surface areas (interior and/or exterior). For example, if the AI engine detects that a drawing room's ceiling height is below the minimum required for proper ventilation installation, it may flag this as an adherence issue, providing suggestions for rectifying the situation.

In some embodiments, an output, such as a user interface of a computing device, smart device, tablet and the like, or a printout or other hardcopy, may illustrate one or both of: a gross area 310 and/or an exterior perimeter 311. Either output may include automatically populated information, such as the gross area of one or more rooms (based upon the above boundary computations) or exterior perimeters of one or more rooms. These outputs are particularly useful in verifying that sufficient space has been allocated for ventilation systems or air filtration systems, so that large commercial buildings have enough gross area to meet building deployment objective requirements for the number of airflow fixtures and user capacity.

In some embodiments, the present invention calculates an area bounded within a series of polygon elements (such as, for example, using mathematical principals or via pixel counting processes), and/or line segments. For example, the AI engine may calculate the area of a drawing room based on its polygonal boundaries and determine whether it is large enough to accommodate the necessary number of airflow fixtures while maintaining mandated clearances around each fixture according to building deployment objectives.

In some embodiments, in an area of a bounded by lines intersecting at vertices, the vertices may be ordered such that they proceed in a single direction such as clockwise around the bounded area. The area may then be determined by cycling through the list of vertices and calculating an area between two points as the area of a rectangle between the lower coordinate point and an associated axis and the area of the triangle between the two points. When a path around the vertices reverses direction, the area calculations may be performed in the same manner, but the resulting area is subtracted from the total until the original vertex is reached. Other numerical methods may be employed to calculate areas, perimeters, volumes, and the like. These calculations are used for determining whether spaces such as restrooms or kitchens meet spatial requirements for airflow fixtures, particularly when dealing with complex room shapes or layouts.

These views may be used in generating estimation analysis documents. Estimation analysis documents may rely on fixtures, region area, or other details. By assisting in generating net area, estimation documents may be generated more accurately and quickly than is possible through human-engendered estimation parameters. For example, the system may generate a report estimating the materials needed to install a complete airflow system in a new residential development, including vents, exhaust, fans, and windows, based on the analyzed floor plan.

With reference now again to FIGS. 3B and 3C, regions 303B-306B defined by an AI engine may include one or more Rooms in FIG. 3B subsequently have regions assigned as “Rooms” in FIG. 3C. For example, if the AI engine identifies a region as a kitchen in FIG. 3B, it will carry over this classification into FIG. 3C for further detailed analysis, such as determining whether the kitchen has sufficient airflow infrastructure to support appliances like stoves. Referring now to FIG. 3D, a table is illustrated containing hierarchical relationships between area types 322-327 that may be defined in and/or by an AI engine and/or via the user interface. The area types 322-327 may be associated with dominance relationship values in relation to adjacent areas. For example, a border region 312-313 (as illustrated in FIG. 3C) will have an area associated with it. According to the present invention, an area 315-318 associated with the border region 312-313 may have an area type 322-327 associated with the area 315-318. An area 312A included in the border region 312-313 may be allocated according to a ratio based upon a dominance ranking of one feature as compared to another feature, which may be represented as a hierarchical relationship between the features, such as, for example, adjacent areas (e.g., area 315 and area 317 or area 317 and area 318). This hierarchical relationship may be used to prioritize the allocation of space between different functional areas in a building, such as prioritizing a larger drawing room area over a smaller storage room to comply with building deployment objectives. The hierarchical relationship may be used to generate a dominance ranking of one area of another area, or to ascertain factors useful in determining whether a building meets an applicable building deployment objective. For example, a dominance ranking may allocate space used to calculate one or more of: an occupancy load; a width and/or area of an egress path; a width and/or area of a common path; a length of a dead end; egress capacity; and travel distance from a furthest point.

Some embodiments of the present invention allocate one or more areas according to a user input (wherein the user input may be programmed to override and automated hierarchical relationship or be subservient to the automated hierarchical relationship). For example, as indicated in the table, a private office located adjacent to a private office may have an area in a border region split between the two adjacent areas in a 50/50 ratio, but a private office adjacent to a general office space may be allocated 60 percent of an area included in a border region, and so on. This feature allows for fine-tuning of space allocation, so that each area meets its intended purpose while also complying with airflow and building deployment objectives. Dominance associated with various areas may be systemic throughout a project, according to customer preference, indicated on a two-dimensional reference by two-dimensional reference basis or another defined basis.

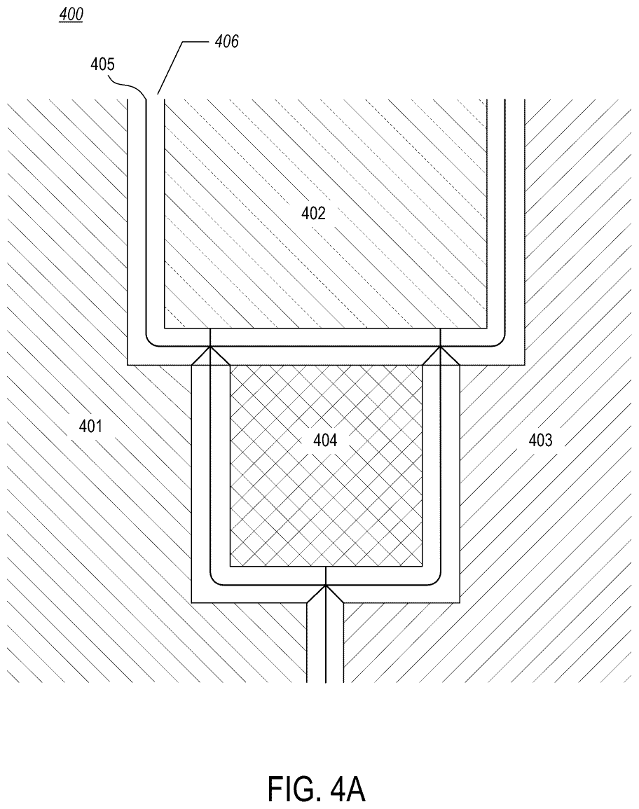

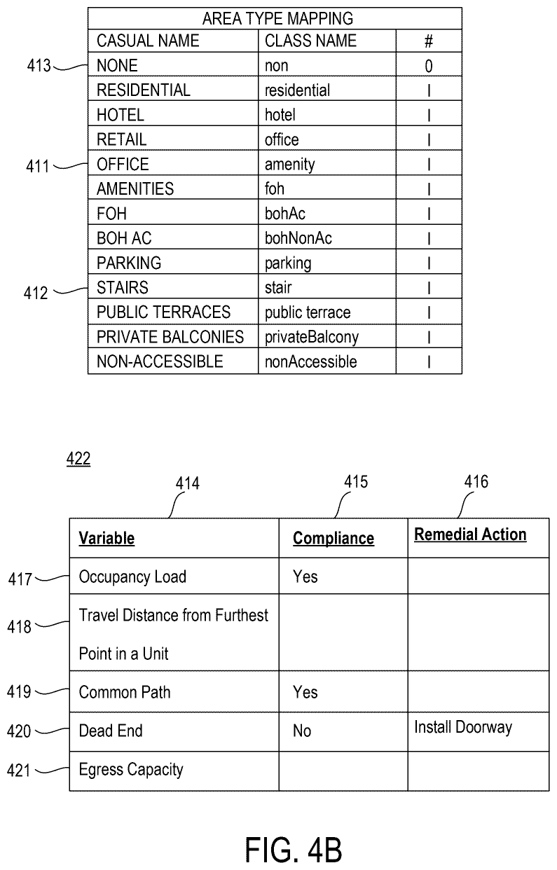

Referring now to FIG. 4A, an exemplary user interface 400 may include boundaries (which, as discussed above, may include one or more of: line segments, polygons, and icons) and regions overlaid on aspects included in a two-dimensional reference is illustrated. A defined space within a boundary (sometimes referred to as a region or area) may include an entire area within perimeters of a structure. For example, the AI engine may analyze these boundaries to determine how different regions such as drawing rooms, bathrooms, kitchens, and utility spaces are defined and interconnected, providing a foundation for further adherence testing.

For example, a controller running an AI engine may determine locations of boundaries, edges, and inflections of neighboring and/or adjacent areas 401-404. There may be portions of boundary regions 405 and 406 that are initially not associated with an adjacent area 401-404. The controller may be operative via executing software in the AI engine to determine the nature of respective adjacent areas 401-404 on either side of a boundary, and apply a dominance-based ranking upon an area type, or an allocation of respective areas 401-404. For example, a bathroom may be ranked higher in dominance than a storage room if airflow objectives are a focus, thereby influencing how boundary space is allocated and analyzed. Different classes or types of spaces or areas may be scored to be equal to, dominant (e.g., above) others or subservient (e.g., below) others.

Referring now to FIG. 4B, an exemplary table A indicating classes of space types and their associated ranks. In some embodiments, a controller may be operative via execution of software to determine relative ranks associated with a region on one or either side of a boundary. For example, area 402 may represent office space and area 404 may represent a stair well. An associated rank lookup value for office space may be found at rank 411, and the associated rank lookup value for stairwells may be found at rank 413. Since the rank 413 of stairwells may be higher, or dominant, over the rank 411 of office space then the boundary space may be associated with the dominant stairs 412 or stairwell space. In some embodiments, a dominant rank may be allocated to an entirety of boundary space at an interface region. In other examples, more complicated allocations may be made where the dominant rank may get a larger share of boundary space than another rank allocated by some functional relationship. In still other examples (Table B), controller may execute logical code to be operative to assign pre-established work costs to elements identified within boundaries.

In some embodiments, a boundary region may transition from one set of interface neighbors to a different set. For example, again in FIG. 4A, a boundary 405 between office region 402 and stairwell 404 may transition to a boundary region between office region 402 and unallocated space 403. The unallocated space may have a rank associated with the unallocated space 403 that is dominant. Accordingly, the nature of allocated boundary space 405 may change at such transitions where one space may receive allocation of boundary space in one pairing and not in a neighboring region. The allocation of the boundary space 405 may support numerous downstream functionalities and provide an input to various application programs. Summary reports may be generated and/or included in an interface based upon a result after incorporation of assignment of boundary areas. For example, a report may highlight how the reallocation of space affects overall airflow fixture counts or objective requirements.

In another aspect, in FIG. 4B, a table 422 illustrates fields 414-416 that may have variable 417-421 values designated by an AI engine or other process run by a controller based upon the two-dimensional reference, such as a floor plan, design plan or architectural blueprint. The variables 417-421 include aspects that may affect adherence with conditions that must be met in order to meet a building deployment objective, such as, for example, remedial actions. For example, occupancy load 417 may dictate the number of airflow fixtures required in a particular space, while travel distance from a furthest point 418 may influence the placement of fixtures so that they are within a specified proximity. Variables 417-421 may include occupancy load 417, travel distance from a furthest point 418, Common path 419, dead end 420, and egress capacity 421.

### Area Takeoff Classification

The determination of boundary definitions for a given inputted design plan, which may be a single drawing or set of drawings or other image, has many important uses and aspects as has been described. However, it can also be important for a supporting process executed by a controller, such as an AI algorithm to take boundary definitions and area definitions and generate classifications of a space. This process may, for example, classify different regions within a floor plan as residential, commercial, or mixed-use based on the dominant features detected within each region, influencing subsequent adherence checks. As mentioned, this can be important to support processes executed by a controller that assigns boundary areas based on dominance of these classifications.

Classification of areas can also be important for further aggregations of space. In a non-limiting example, accurate automatic classification of room spaces may allow for a combination of all interior spaces to be made and presented to a user. Overlays and boundary displays can accordingly be displayed for such aggregations. For example, an AI engine may classify all drawing rooms within a building, allowing the user to quickly verify whether these spaces collectively meet the building's airflow requirements for fixture counts and spacing. There may be numerous functionalities and purposes for automatic classification of regions from an input drawing.

An AI engine or other process executed by a controller may be refined, trained, or otherwise instructed to utilize a number of recognized characteristics to accomplish area classification. For example, the AI engine may learn to classify rooms based on their geometric shapes, standard sizes, or the presence of specific fixtures like sinks or toilets, which are commonly associated with bathrooms. An AI engine may base predictions for a type “/“category” of a region with a starting point of the determination that a region exists from the previous predictions by the segmentation engine.

In some embodiments, a type may be inferred from text located on an input drawing or other two-dimensional reference. An AI engine may utilize a combination of factors to classify a region, but it may be clear that the context of the recognized text may provide direct evidence upon which to infer a decision. For example, a recognized textual label such as “Common room” in a region may allow the AI engine to automatically assign this area as a drawing room, and accordingly, classify neighboring spaces like adjoining corridors or lobbies with relevant categories for further analysis. For example, a recognized textual comment in a region may directly identify the space as a bedroom, which may allow the AI engine to make a set of hierarchical assignments to space and neighboring spaces, such as adjoining bathrooms, closets, and the like.

Classification may also be influenced by, and use, a geometric shape of a predicted region. Common shapes of certain spaces, like rectangular kitchens or square utility rooms, may be well-represented in training sets used to instruct the AI engine, thereby enhancing the accuracy of space classification. Common shapes of certain spaces may allow a training set to train a relevant AI engine to classify a space with added accuracy. Furthermore, certain space classes may fall into ranges of areas which also may aid in the identification of a region's class. Accordingly, it may be important to influence the makeup of training sets for classification that contain common examples of various classes as well as common variations on that theme.

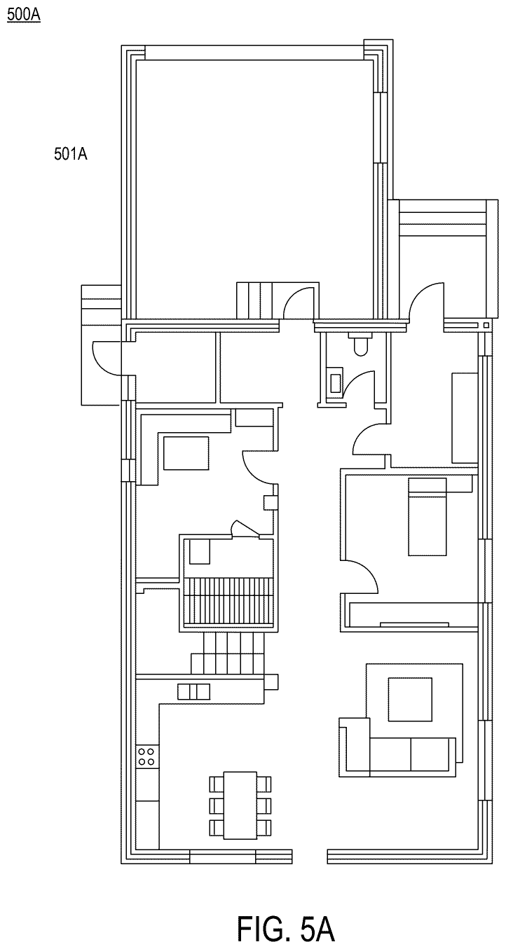

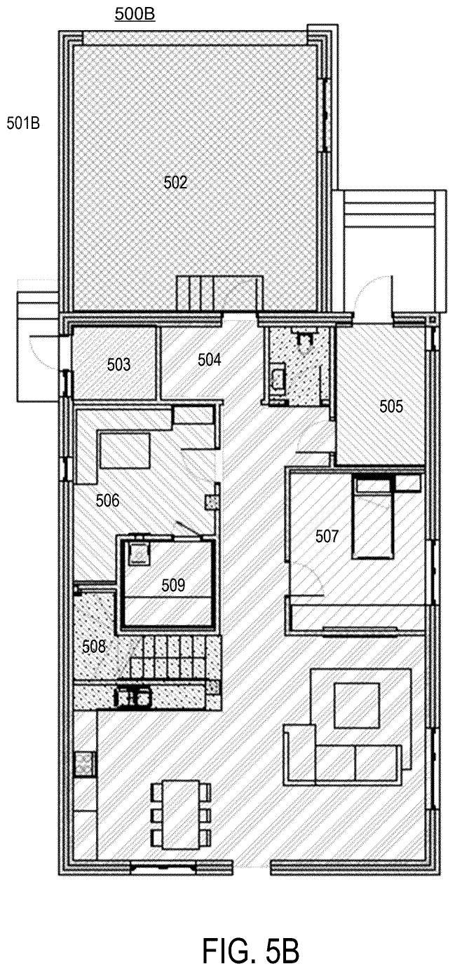

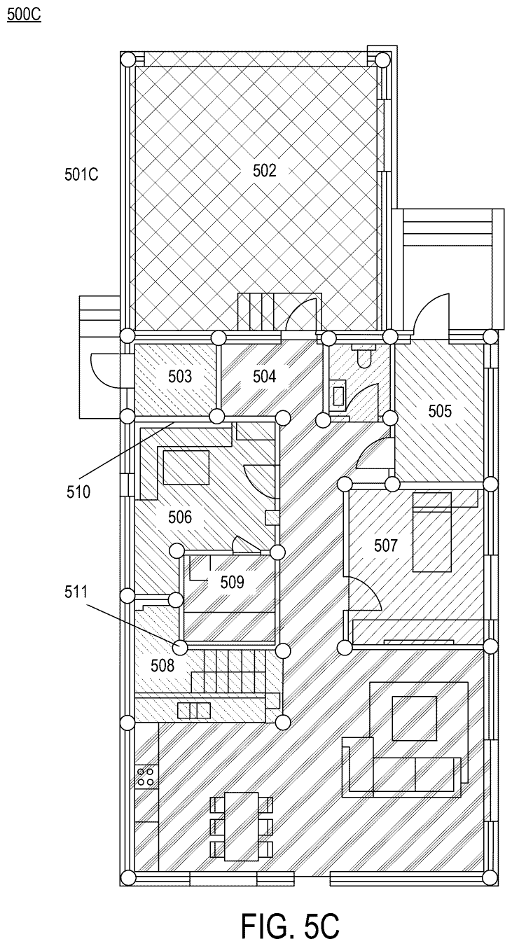

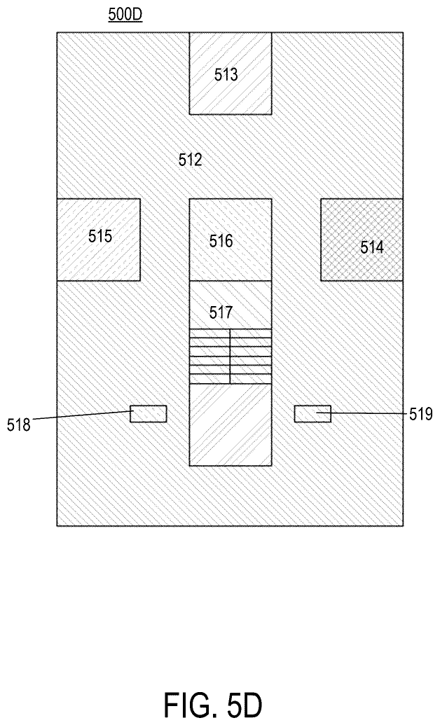

Referring now to FIGS. 5A-5D, a progressive series of outputs that may be included in various user interfaces are illustrated and provide examples of a recognition process that may be implemented in some embodiments of the present invention. Referring now to FIG. 5A, a relatively complex drawing of a floorplan may be input as a design plan 501A into a controller running an AI engine. This design plan may represent a detailed layout of a building, including various rooms, fixtures, and structural elements, which the AI engine will analyze to extract relevant features for further processing. The two-dimensional reference 501 may be included in an initial user interface 500A.

An AI engine based automated recognition process executes method steps via a controller, such as a cloud server, and identifies multiple disparate regions 502-509. Designation of the regions 502-509 may be integrated according to a shape and scale of the two-dimensional reference and presented as a region view 501B user interface 500B, with symbolic hatches or colors etc., as shown in FIG. 5B.

The region view 501B may include the multiple regions 502-509 identified by the AI engine arranged based upon a size and shape and relative position derived from the two-dimensional reference 501.

Referring now to FIG. 5C, a line segment view 501C may include identified boundary line segments 510 and vertices 511 may also be presented as an overlay of the regions 502-509 illustrated as delineated symbolic hatches or colors etc., as illustrated in FIG. 5C. Said line segments 510 may also be represented as symbols such as but not limited to dots. Such an interactive user interface 500C may allow a user to review and correct assignments in some cases. A component of the AI engine may further be trained to recognize aggregations of regions 502-509 spaces, or areas, such as in a non-limiting sense the aggregation of internal regions 502-509, spaces or areas.

Referring now to FIG. 5D, an illustration of exemplary aggregation of regions 512-519 is provided where a user interface 500D includes patterned portions 512-519 and the patterned portions 512-519 may be representative of regions, spaces, or areas, such as, for example, aggregated interior living spaces.

In some embodiments, integrated and/or overlaid aggregations of some or all of: regions; spaces; patterned portions; line segments; polygons; symbols; icons or other portions of the user interfaces may be assembled and presented in a user output and our user interface, or as input into another automated process. This may be used to create a detailed report for architects or engineers, highlighting how different spaces are utilized and where potential adherence issues may arise, especially in areas such as airflow fixture placement and accessibility.

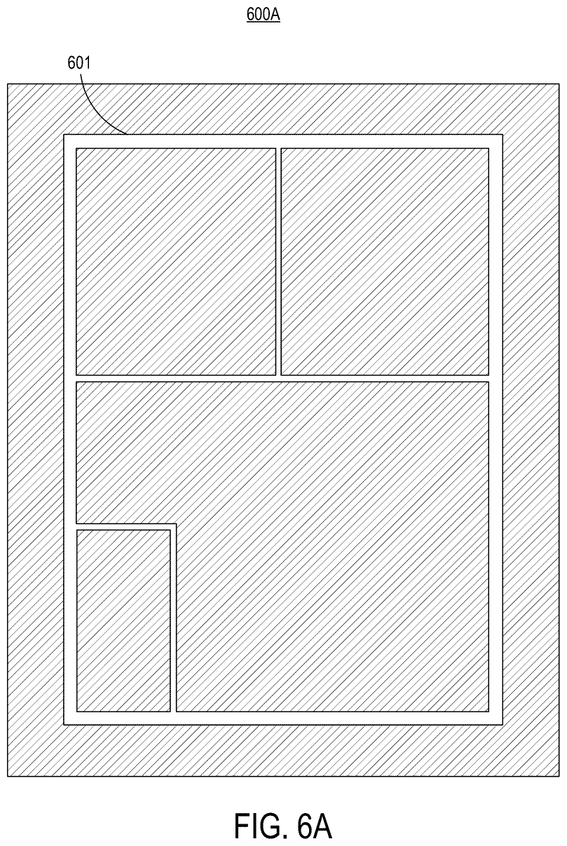

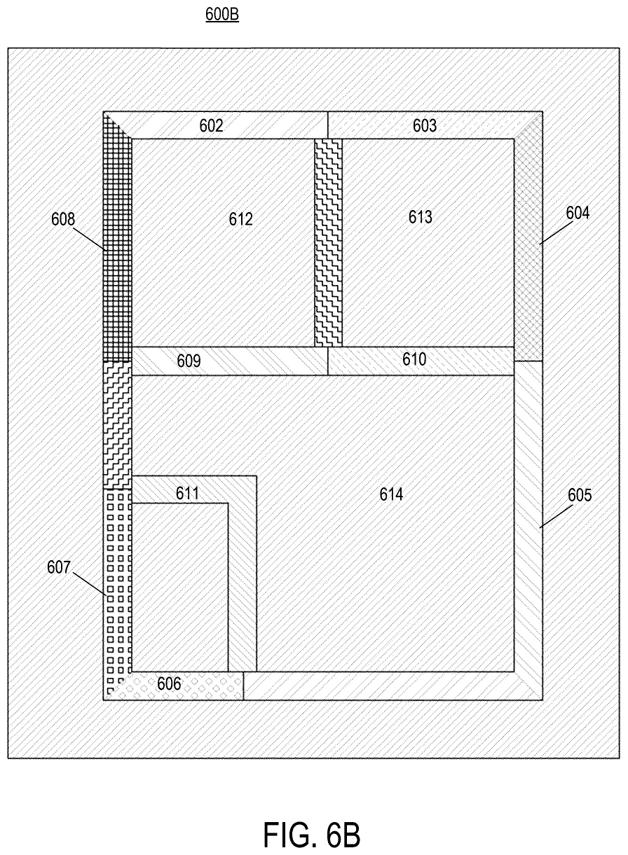

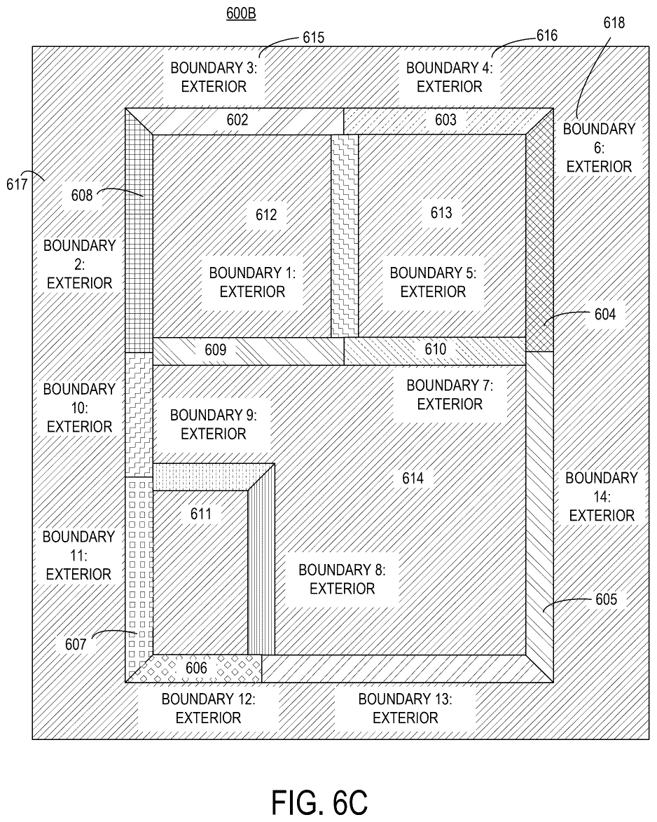

Referring now to FIGS. 6A-6C, in some embodiments, automated and/or user-initiated processes may include refinement of regions, spaces, or areas that may involve one or both of a user and a controller identifying individual wall segments 211A from previously defined boundaries. For example, a user may need to refine the boundary of a restroom so that all airflow fixtures are accurately accounted for in the adherence analysis.

For example, in some embodiments, a controller running an AI engine may execute processes that are operative to divide a previously predicted boundary into individual wall segments. In FIG. 6A, a user interface 600A includes a representation of a design plan with an original boundary 601 defined from an inputted design.

In FIG. 6B, an AI engine may be operative to take one or more original boundaries 601 and isolate one or more individual line segments 602-611 as shown by different hatching symbols in an illustrated user interface 600B. The identification of individual line segments 602-611 of a boundary 601 enables one or both of a controller and a user to assign and/or retrieve information about the individual line segment 602-611 such as, for example, one or more of: the length of the segment 602-611, a type of wall segment 211A, materials used in the wall segment 211A, parameters of the segment 602-611, height of the segment 602-611, width of the segment 602-611, allocation of the segment 602-611 to a region 612-614 or another, and almost any digital content relevant to the segment.

Referring now to FIG. 6C, in some embodiments, a controller executing an AI engine or other method steps, may be operative, in some embodiments, to classify individual line segments 602-611 of a boundary 601 and present a user interface 600C indicating the classified individual line segments 602-611. The AI engine may be trained, and subsequently operative, to classify individual line segments 602-611 included in a boundary 601 in different classes. As a non-limiting example, an AI engine may classify walls as interior walls, exterior walls and/or demising walls that separate internal spaces.

As illustrated in FIG. 6C, in some embodiments, an individual line segment 602-611 may be classified by the AI engine and an indication of the classification 615-618, such as alphanumeric or symbolic content, may be associated with the individual line segment 602-611 and presented in the user interface 600C. For example, a segment may be labeled as a “fire-rated wall” or “soundproof partition,” providing immediate visual feedback to the user regarding the wall's status and necessary attributes.

In some embodiments, functionality may be allocated to classified individual line segments 602-611, such as, by way of non-limiting example, a process that generates an estimated materials list for a region or an area defined by a boundary, based on the regions or area's characteristics and its classification.

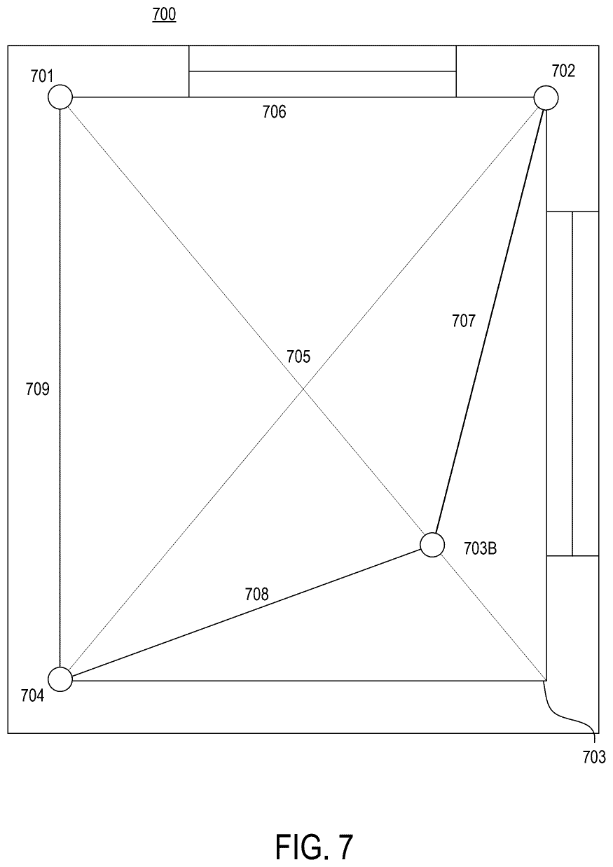

Referring now to FIG. 7 in some embodiments, a user interface 700 may include user interactive controls operative to execute process steps described herein (e.g. make a boundary determination, region classification, segmentation decision or the like) in an automated process (e.g. via an AI routine) and also be able to receive an instruction (e.g. from a user via a user interface, or a controller operative via executable software to perform a process) that modify one or more boundary segments. For example, a user may drag a boundary line to redefine the limits of a kitchen area, triggering the AI engine to reclassify the adjacent spaces and adjust the corresponding material and fixture requirements.

For example, a user interface may include one or more vertex 701-704 (e.g., points where two or more line segments meet) that may be user interactive such that a user may position the one or more vertex 701-704 at a user selected position. User positioning may include, for example, user drag and drop of the one or more vertex 701-704 at a desired location or entering a desired position, such as via coordinates. A new position for a vertex 703B may allow an area 705 bounded by user defined boundaries 706-709 User interactive portions of a user interface 700 are not limited to vertex 701-704 and can be any other item 701-709 in the user interface 700 that may facilitate achievement of a purpose by allowing one or both of: the user, and the controller, to control dynamic sizing and/or placement of a feature or other item 701-709.

Still further, in some embodiments, user interaction involving positioning of a vertex 701-704 or modification of an item 705-709 may be used to train an AI engine to improve performance.

An important aspect of the operation of the systems as have been described is the training of the AI engines that perform the functions as have been defined. A training dataset may involve a set of input drawings associated with a corresponding set of verified outputs. In some embodiments, a historical database of drawings may be analyzed by personnel with expertise in the field. user, including in some embodiments experts in a particular field of endeavor may manipulate dynamic features of a design plan or other aspects of a user interface to be used to train an AI engine, such as by creating or adding to an AI referenced database.

In some other examples, a trained version of an AI engine may produce user interfaces and/or other outputs based on the trained version of the AI engine. Teams of experts may review the results of the AI processing and make corrections as required. Corrected drawings may be provided to the AI engine for renewed training.

Aspects that are determined by a controller running an AI engine to be represented in a design plan may be used to generate an estimate of what will be required to complete a project. For example, according to various embodiments of the present invention, an AI engine may receive as input a two-dimensional reference and generate one or more of: boundaries, areas, fixtures, architectural components, perimeters, linear lengths, distances, volumes, and the like may be determined by a controller running an AI engine to be required to be required to complete a project.

For example, a derived area or region comprising a room and/or a boundary, perimeter or other beginning and end indicator may allow for a building estimate that may integrate choices of materials with associated raw materials costs and with labor estimates all scaled with the derived parameters. The boundary determination function may be integrated with other standard construction estimation software and feed its calculated parameters through APIs. In other examples, the boundary determination function may be supplemented with the equivalent functions of construction estimation to directly provide parametric input to an estimation function. For example, the parameters derived by the boundary determinations may result in estimation of needed quantities like cement, lumber, steel, wall board, floor treatments, carpeting and the like. Associated labor estimates may also be calculated.

As described herein, a controller executing an AI engine may be functional to perform pattern recognition and recognize features or other aspects that are present within an input two-dimensional reference or other graphic design. In a segmentation phase used to determine boundaries of regions or other space features, aspects that are recognized as some artifact other than a boundary may be replaced or deleted from the image. An AI engine and/or user modified resulting boundary determination can be used in additional pattern recognition processing to facilitate accurate recognition of the non-wall features present in the graphic.

For example, in some embodiments, a set of architectural drawings may include many elements depicted such as, by way of non-limiting example, one or more of: windows, exterior doors, interior doors, hallways, elevators, stairs, electrical outlets, wiring paths, floor treatments, lighting, appliances, and the like. In some two-dimensional references, furniture, desks, beds, and the like may be depicted in designated spaces. AI pattern recognition capabilities can also be trained to recognize each of these features and many other such features commonly included in design drawings. In some embodiments, a list of all the recognized image features may be created and also used in the cost estimation protocols as have been described.

In some embodiments of the present invention, a recognized feature may be accompanied by a drawing with textual description which may also be recognized by the AI image recognition capabilities. The textual description may be assessed in the context of the recognized physical features in its proximity and used to supplement the feature identification. Identified feature elements may be compared to a database of feature elements, and matched elements may be married to the location on the architectural plan. In some embodiments, text associated with dimensioning features may be used to refine the identity of a feature. For example, a feature may be identified as an exterior window, but an association of a dimension feature may allow for a specific window type to be recognized. Also, a text input or other narrative may be recognized to provide a more specific identification of a window type.

Identified features may be associated with a specific item within a features database. The item within the features database may have associated records that precisely define a vector graphics representation of the element. Therefore, an input graphic design may be reconstituted within the system to locate wall and other boundary elements and then to superimpose a database element graphic associated with the recognized feature. In some embodiments, various feature types and text may be associated into separate layers of a processed architectural design. Thus, in a user interface or other output display or on reports, different layers may be illustrated at different times along with an associated display of estimation results.

In some embodiments, a drawing may be geolocated by user entry of data associated with the location of a project associated with the input architectural plans. The calculations of raw material, labor and the like may then be adjusted for prevailing conditions in the selected geographic location. Similarly, the geolocation of the drawing may drive additional functionality. The databases associated with the systems may associate a geolocation with a set of building deployment objectives, standards and the like and review the discovered design elements for adherence. In some embodiments, a list of variances or discovered potential issues may be presented to a user on a display or in a report form. In some embodiments, a function may be offered to remove user entered data and other personally identifiable information associated with the database with a processing of a graphic image.

In some embodiments, a feature determination that is presented to a user in a user interface may be assessed as erroneous in some way by the user. The user interface may include functionality to allow the user to correct the error. The resulting error determination may be included in a training database for the AI engine to help improve its accuracy and functionality.

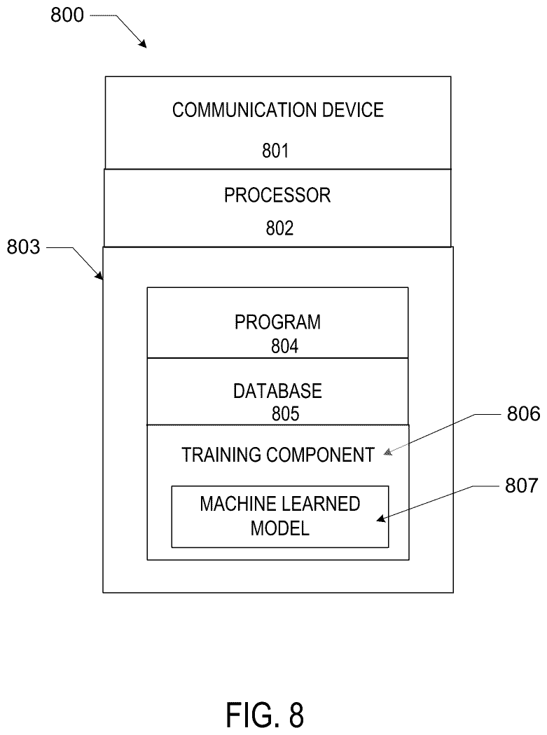

Referring now to FIG. 8, an automated controller is illustrated that may be used to implement various aspects of the present disclosure, in various embodiments, and for various aspects of the present disclosure, controller 800 may be included in one or more of: a wireless tablet or handheld device, a server, a rack mounted processor unit. The controller may be included in one or more of the apparatuses described above, such as a Server, and a Network Access Device. The controller 800 includes a processor unit 802, such as one or more semiconductor-based processors, coupled to a communication device 801 configured to communicate via a communication network (not shown in FIG. 8). The communication device 801 may be used to communicate, for example, with one or more online devices, such as a personal computer, laptop, or a handheld device.

The processor 802 is also in communication with a storage device 803. The storage device 803 may comprise any appropriate information storage device, including combinations of magnetic storage devices (e.g., magnetic tape and hard disk drives), optical storage devices, and/or semiconductor memory devices such as Random Access Memory (RAM) devices and Read Only Memory (ROM) devices.

The storage device 803 can store a software program 804 with executable logic for controlling the processor 802. The processor 802 performs instructions of the software program 804, and thereby operates in accordance with the present disclosure. In some embodiments, the processor may be supplemented with a specialized processor for AI related processing. The processor 802 may also cause the communication device 801 to transmit information, including, in some instances, control commands to operate apparatus to implement the processes described above. The storage device 803 can additionally store related data in a database 805. The processor and storage devices may access an AI training component 806 and database, as needed which may also include storage of machine learned models 807.

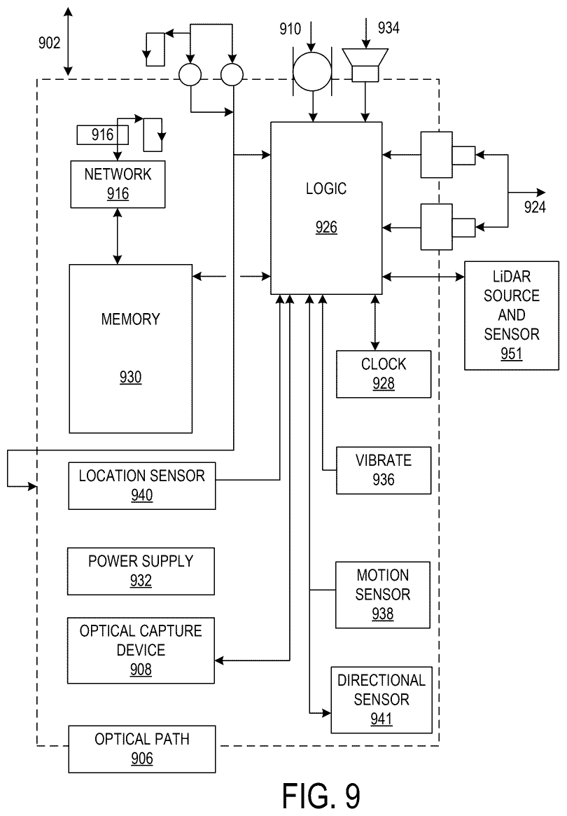

Referring now to FIG. 9, a block diagram of an exemplary mobile device 902 is illustrated. The mobile device 902 comprises an optical capture device 908 to capture an image and convert it to machine-compatible data, and an optical path 906, a lens, an aperture, or an image conduit to convey the image from the rendered document to the optical capture device 908. The optical capture device 908 may incorporate a Charge-Coupled Device (CCD), a Complementary Metal Oxide Semiconductor (CMOS) imaging device, or an optical Sensor 924 of another type.

A microphone 910 and associated circuitry may convert the sound of the environment, including spoken words, into machine-compatible signals. Input facilities may exist in the form of buttons, scroll wheels, or other tactile Sensors such as touchpads. In some embodiments, input facilities may include a touchscreen display.

Visual feedback to the user is possible through a visual display, touchscreen display, or indicator lights. Audible feedback 934 may come from a loudspeaker or other audio transducer. Tactile feedback may come from a vibrate module 936.

A motion Sensor 938 and associated circuitry convert the motion of the mobile device 902 into machine-compatible signals. The motion Sensor 938 may comprise an accelerometer that may be used to sense measurable physical acceleration, orientation, vibration, and other movements. In some embodiments, motion Sensor 938 may include a gyroscope or other device to sense different motions.

A location Sensor 940 and associated circuitry may be used to determine the location of the device. The location Sensor 940 may detect Global Position System (GPS) radio signals from satellites or may also use assisted GPS where the mobile device may use a cellular network to decrease the time necessary to determine location.

The mobile device 902 comprises logic 926 to interact with the various other components, possibly processing the received signals into different formats and/or interpretations. Logic 926 may be operable to read and write data and program instructions stored in associated storage or memory 930 such as RAM, ROM, flash, or other suitable memory. It may read a time signal from the clock unit 928. In some embodiments, the mobile device 902 may have an on-board power supply 932. In other embodiments, the mobile device 902 may be powered from a tethered connection to another device, such as a Universal Serial Bus (USB) connection.

The mobile device 902 also includes a network interface 916 to communicate data to a network and/or an associated computing device. Network interface 916 may provide two-way data communication. For example, network interface 916 may operate according to the internet protocol. As another example, network interface 916 may be a local area network (LAN) card allowing a data communication connection to a compatible LAN. As another example, network interface 916 may be a cellular antenna and associated circuitry which may allow the mobile device to communicate over standard wireless data communication networks. In some implementations, network interface 916 may include a Universal Serial Bus (USB) to supply power or transmit data. In some embodiments other wireless links may also be implemented.

As an example of one use of mobile device 902, a reader may scan an input drawing with the mobile device 902. In some embodiments, the scan may include a bit-mapped image via the optical capture device 908. Logic 926 causes the bit-mapped image to be stored in memory 930 with an associated timestamp read from the clock unit 928. Logic 926 may also perform optical character recognition (OCR) or other post-scan processing on the bit-mapped image to convert it to text.

A directional sensor 941 may also be incorporated into the mobile device 902. The directional device may be a compass and be based upon a magnetic reading or based upon network settings.

A LiDAR sensing system 951 may also be incorporated into the mobile device 902. The LiDAR system may include a scannable laser light (or other collimated) light source which may operate at nonvisible wavelengths such as in the infrared. An associated sensor device, sensitive to the light of emission may be included in the system to record the time and strength of the returned signal that is reflected off of surfaces in the environment of the mobile device 902. In some embodiments, as have been described herein, a 2-dimensional drawing or representation may be used as the input data source, and vector representations in various forms may be utilized as a fundamental or alternative input data source. Moreover, in some embodiments, files which may be classified as BIM input files may be directly used as a source on which method steps may be performed. BIM and CAD file formats may include, by way of non-limiting example, one or more of: BIM, RVT, NWD, DWG, IFC and COBie. Features in the BIM or CAD datafile may already have defined boundary aspects having innate definitions such as walls and ceilings and the like. An interactive user interface may be generated that receives input from a user indicating a user choice of types of innate boundary aspects a user provides instruction to the controller to perform subsequent processing on.

In some embodiments, a controller may receive user input enabling input data from either a design plan format or similar such formats, or also allow the user to access BIM or CAD formats. Artificial intelligence may be used to assess boundaries in different manners depending on the type of input data that is initially inputted. Subsequently, similar processing may be performed to segment defined spaces in usable manners as has been discussed. The segmented spaces may also be processed to determining classifications of the spaces.

As has been described, a system may operate (and AI Training aspects may be focused upon) recognition of lines or vectors as a basic element within an input design plan. However, in some embodiments, other elements may be used as a fundamental element, such as, for example, a polygon and/or series of polygons. The one or more polygons may be assembled to define an area with a boundary, as compared, in some embodiments, with an assembly of line segments or vectors, which together may define a boundary which may be used to define an area. Polygons may include different vertices; however common examples may include triangular facets and quadrilateral polygons. In some embodiments, AI training may be carried out with a singular type of polygonal primitive element (e.g., rectangles), other embodiments will use a more sophisticated model. In some other examples, AI engine training may involve characterizing spaces where the algorithms are allowed to access multiple diverse types of polygons simultaneously. In some embodiments, a system may be allowed to represent boundary conditions as combinations of both polygons and line elements or vectors.

Depending upon one or more factors, such as processing time, a complexity of the feature spaces defined, and a purpose for AI analysis, simplification protocols may be performed as have been described herein. In some embodiments, object recognition, space definition, or general simplification may be aided by various object recognition algorithms. In some embodiments, Hough type algorithms may be used to extract diverse types of features from a representation of a space. In other examples, Watershed algorithms may be useful to infer division boundaries between segmented spaces. Other feature recognition algorithms may be useful in determining boundary definitions from building drawings or representations.

In some embodiments, the user may be given access to movement of boundary elements and vertices of boundary elements. In examples where lines or vectors are used to represent boundaries and surrounding area, a user may move vertices between lines or center points of lines (which may move multiple vertices). In other examples, elements of polygons such as the user may move vertices, sides, and center points. In some embodiments, the determined elements of the space representation may be bundled together in a single layer. In other examples, multiple layers may be used to distinguish distinct aspects. For example, one layer may include the AI optimized boundary elements, another layer may represent area and segmentation aspects, and still another layer may include object elements. In some embodiments, when the user moves an element such as a vertex the effects may be limited only to elements within its own layer. In some examples, a user may elect to move multiple or all layers in an equivalent manner. In still further examples, all elements may be assigned to a single layer and treated equivalently. In some embodiments, users may be given multiple menu options to select disparate elements for processing and adjustment. Features of elements such as color and shading and stylizing aspects may be user selectable. A user may be presented with a user interface that includes dynamic representations of features or other aspects of a design plan, and associated values and changes may be input by a user. In some embodiments, an algorithm and processor may present to the user comparisons of various aspects within a single model or between different models. Accordingly, in various embodiments, a controller and a user may manipulate aspects of a user interface and AI engine.

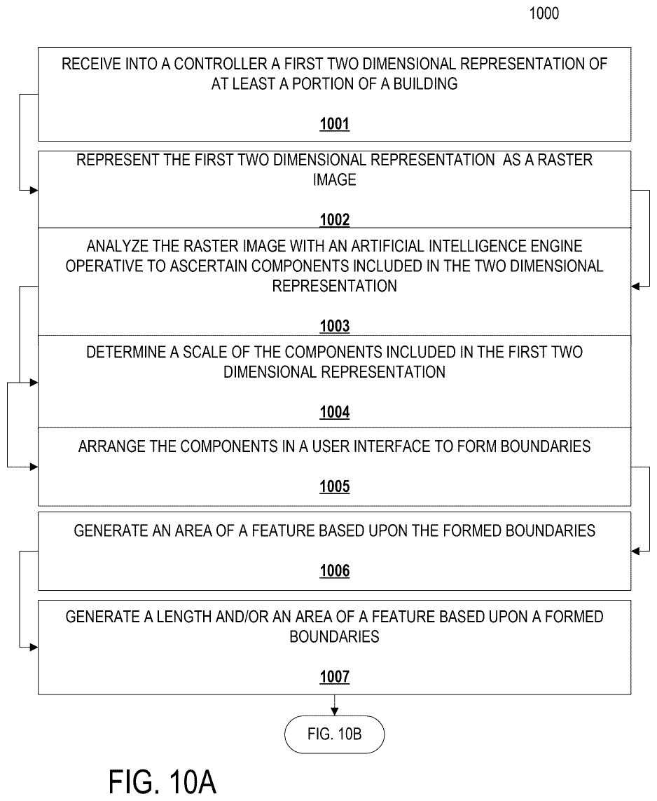

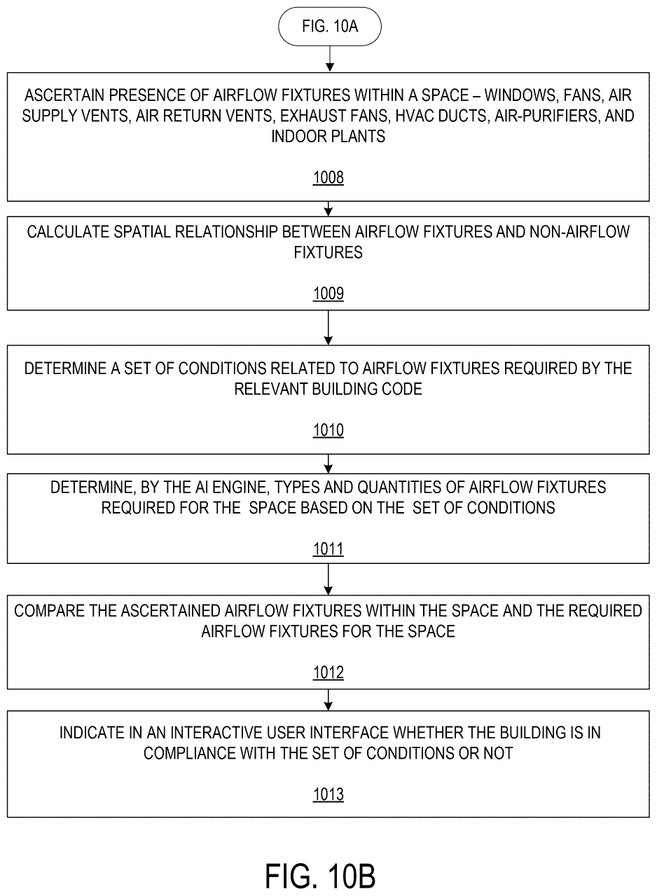

Referring now to FIGS. 10A-10B, an exemplary flowchart 1000 outlines method steps for quantifying the requirements for airflow adherence based on an artificial intelligence (AI) analysis of a design plan. The method enables a comprehensive assessment of whether the airflow aspects of a building's design adhere to relevant building deployment objectives, so that the final construction is safe, functional, and compliant with building deployment objectives.

At step 1001, the process begins with receiving a design plan into a controller, which serves as the central processing unit, including the AI engine. The design plan may include various forms of architectural drawings, floor plans, or other design documentation that depict at least a portion of a building. These documents are received in digital formats such as PDFs, CAD files, or images, which can be easily processed by the AI engine. The design plan provides the foundational data from which all subsequent analysis will be derived, and it must accurately represent the building's intended layout, including all airflow fixtures and systems.

At step 1002, the received design plan is represented as a raster image or another image type conducive to AI analysis. Raster images are pixel-based and allow the AI engine to interpret the visual data in a structured format. The design plan is transformed from a static representation into a format that can be analyzed computationally. The rasterization process involves converting vector graphics or other types of design representations into a grid of pixels, each of which can be analyzed individually by the AI engine.

Once the design plan is represented as a raster image, step 1003 involves analyzing this image using the AI engine. The AI engine is programmed to recognize and identify various components within the design plan, such as walls, rooms, plumbing fixtures (e.g., toilets, sinks, stove, sofa), and associated duct systems. The AI engine uses pattern recognition and machine learning algorithms to detect these components based on their shapes, positions, and relationships within the design. For example, it can identify a kitchen by recognizing the common outline and placement commonly associated with such a fixture in kitchen layouts.

After identifying the components, step 1004 focuses on determining the scale of these components within the design plan. The scale is used for accurately measuring dimensions, distances, heights, and areas in the design. It may be determined by referencing a scale indicator or ruler included in the design plan or by identifying components of known dimensions, such as standard-sized fixtures. The AI engine uses this scale to convert pixel measurements into real-world units (e.g., inches, feet, meters), enabling precise calculations of space and clearance.

At step 1005, a user interface is generated that incorporates the components identified by the AI engine. The user interface is interactive, allowing users to view and manipulate the design plan within a digital environment. The user interface presents a clear visual representation of the building's layout, highlighting the airflow systems and fixtures. Users can zoom in on specific areas, adjust views, and interact with the components to gain a deeper understanding of the design's spatial relationships and configurations.

Step 1006 involves arranging the identified components within the user interface to form boundaries. These boundaries may represent the edges of rooms, the extent of airflow systems, or the clearances required around fixtures. The AI engine may draw a boundary around a duct layout to indicate the required clearance for maintenance accessibility, so that there is enough space for a maintenance person to approach the fixture.

Once boundaries are formed, step 1007 allows for the generation of lengths, heights, and areas based on these boundaries. For example, the AI engine can calculate the area of a drawing room, the length of a duct run, or height of an airflow fixture. These measurements are used for determining whether the design meets specific building deployment objective requirements related to space allocation, fixture placement, and duct lengths. Accurate measurements help identify potential issues such as overcrowding in various room layouts or insufficient spaces for safe and accessible airflow.

At step 1008, the AI engine ascertains the presence of various airflow fixtures within a space (e.g., a first unit). These fixtures may include windows, fans, air supply vents, air return vents, exhaust fans, HVAC ducts, air-purifiers, and even indoor plants. The AI engine systematically identifies each of these airflow fixtures by analyzing the design plan provided. For example, in a residential building, the AI engine may detect windows in living rooms and bedrooms, fans in dining areas, and exhaust fans in bathrooms and kitchens. Additionally, the engine may identify HVAC ducts and air supply/return vents in centralized heating and cooling systems. The presence of air purifiers, often found in spaces requiring enhanced air quality, and indoor plants, which contribute to natural air purification, are also recorded. This step involves recognizing the physical locations of these fixtures, their types, quantities, and dimensions.

At step 1009, the AI engine calculates the spatial relationships between the identified airflow fixtures and the non-airflow fixtures present within the same space. Non-airflow fixtures may include furniture such as beds, sofas, tables, cupboards, and even smaller items like lamps or bookshelves. The AI engine evaluates how these non-airflow fixtures may impact the effectiveness of the airflow fixtures. For example, if a large sofa is positioned directly in front of an air return vent, it may obstruct proper air circulation within the room. Similarly, a bed placed too close to a window may block natural ventilation, especially if the window is the primary source of fresh air in the room. The AI engine considers such factors in its calculations, determining whether the current setup allows for optimal airflow or if adjustments are necessary.

In some embodiments, the AI engine is designed to determine the spatial relationships between airflow fixtures within a given space, considering one or both the area of the space and its expected occupancy. The AI engine evaluates the positioning and distance between airflow fixtures, such as air supply vents, return vents, exhaust fans, and windows, to determine if these elements are optimally placed to provide effective ventilation throughout the space.

The AI engine recognizes that closely spaced airflow fixtures can create issues such as redundancy and reduced efficiency. For example, if two air supply vents are placed too close to each other in a large room, the air distribution may become uneven, leading to areas of stagnation where the airflow is insufficient. This situation may cause certain parts of the room to feel stuffy, while other parts may be overly ventilated, resulting in discomfort for the occupants and inefficient energy use. The AI engine may recommend adjusting the placement of these vents to create a more balanced airflow, so that the entire space is adequately ventilated.

On the other hand, the AI engine also considers the impact of excessive spacing between airflow fixtures. For example, in a large room with a high occupancy level, if the air supply and return vents are placed too far apart, there may be sections of the room where the air circulation is weak. This situation can lead to pockets of poor air quality, where contaminants and stale air accumulate. The AI engine calculates the optimal distance between airflow fixtures based on the specific area of the space and its expected occupancy, so that every part of the room receives consistent and effective ventilation. For example, in a densely occupied conference room, the AI engine may determine that additional vents are needed or that existing vents should be repositioned to maintain air quality throughout the room.

Furthermore, the AI engine analyzes the interaction between different types of airflow fixtures. For example, in a scenario where an exhaust fan and an air supply vent are located too close to each other, the exhaust fan may prematurely draw in the fresh air supplied by the vent, reducing the effectiveness of both fixtures. The AI engine may suggest increasing the distance between these fixtures or altering their placement to enhance the overall airflow pattern within the space. Additionally, the AI engine may identify scenarios where airflow fixtures are positioned in ways that interfere with each other's functionality, such as a ceiling fan placed directly below an exhaust vent, which may disrupt the vent's ability to expel air effectively.

At step 1010, the AI engine determines a set of conditions related to airflow fixtures required by one or more relevant building deployment objectives. These conditions may be based on factors such as a proposed use of the building (residential, commercial, industrial), a type of space (living room, kitchen, office, etc.), and the specific requirements outlined in the building deployment objective for that use. For example, a kitchen area may require an exhaust fan to manage cooking fumes, while a bedroom may necessitate a certain number of air changes per hour to maintain air quality. The AI engine cross-references the building deployment objective requirements with the types of spaces identified in the design plan to establish the baseline conditions that must be met.

At step 1011, based on the set of conditions determined in the previous step, the AI engine calculates the types and quantities of airflow fixtures required for the space. This calculation involves considering the space's area, occupancy levels, and any specific ventilation needs dictated by the building's proposed use. For example, in a large conference room designed to accommodate numerous people, the AI engine may determine that multiple air supply vents are needed to maintain adequate ventilation. The AI engine may also calculate the size and placement of these vents so that air is evenly distributed throughout the space. In a bathroom, the AI engine may specify the need for a high-capacity exhaust fan to quickly remove moisture and odors.

At step 1012, the AI engine compares the identified airflow fixtures already present within the space with the required airflow fixtures as determined in the step 1011. This comparison reveals any discrepancies between the current setup and what is needed to meet building deployment objective requirements. For example, the AI engine may find that a living room has only one small window when the building deployment objective requires two for adequate ventilation. Or it may discover that a kitchen has an improperly sized exhaust fan, leading to insufficient removal of cooking odors. The AI engine flags these discrepancies and categorizes them by severity, from minor issues that can be easily corrected to major non-adherence s that may require significant redesign or retrofitting.

At step 1013, the AI engine indicates in the interactive user interface whether the building meets a set of conditions relating to an airflow objective. This step involves generating a comprehensive report that outlines the findings of the AI engine, including any discrepancies or issues identified in the previous steps. The user interface may present this information visually, using color-coded indicators to show compliant and non-compliant areas. For example, compliant areas may be highlighted in green, while areas requiring attention may be highlighted in red or yellow. The user interface may also offer detailed recommendations for addressing any issues, such as repositioning airflow fixtures, adding new ones, or modifying existing ones to better meet the required conditions.

In some embodiments of the present invention, the AI engine may analyze a design plan that includes multiple office spaces and meeting rooms across different floors. By calculating the occupancy load for each space and floor, the AI engine determines the minimum required airflow rates, the number of vents, and the size of air conditioning units necessary to maintain adherence with building deployment objectives. If a particular floor is designed to accommodate a large number of employees, the AI engine may reference the applicable ventilation practices to verify that the HVAC system is capable of providing adequate air circulation during peak occupancy periods. If the system does not meet these requirements, the AI engine may automatically generate revision suggestions, such as adding more air vents, upgrading the HVAC system, or reconfiguring the ductwork to improve airflow efficiency.

In terms of dominance rank, the AI engine may automatically prioritize adherence checks for areas of higher traffic or greater importance within the building. For example, in a hospital design plan, operating rooms or intensive care units (ICUs) may be considered dominant areas due to their functions and the stringent airflow requirements they must meet to maintain a sterile and safe environment. The AI engine may assess these areas first, so that the HVAC systems are robust enough to handle the demanding airflow needs, including maintaining positive or negative pressure zones as required. If the AI engine detects that the design lacks sufficient ventilation or airflow management in these areas, it may suggest reallocating resources from less-required areas to enhance the HVAC system's capacity in the high-priority zones.

Another example may involve a large residential complex where the AI engine assesses the HVAC systems based on the dominance rank of specific units. Penthouse apartments or units located on the top floors may be given a higher dominance rank due to their premium status and the expectation of superior amenities, including enhanced air quality and climate control. The AI engine may suggest upgrading the HVAC systems in these units, such as by installing more powerful air conditioning units or adding additional vents for optimal airflow. Conversely, for standard units with lower dominance ranks, the AI engine may focus on basic adherence, recommending only the required upgrades needed to meet the minimum building deployment objective requirements, thereby balancing performance with cost efficiency. In some embodiments, a user may specify dominance ranks to two or more spaces within a design plan, thereby instructing the AI engine to analyze the adherence accordingly.

Furthermore, the AI engine may also consider future scalability in its analysis. For example, in an office building expected to expand its workforce over time, the AI engine may recommend HVAC systems that can be easily upgraded or expanded to accommodate the increased demand for airflow. This may involve suggesting larger ductwork that can handle greater volumes of air or designing the system layout in a way that allows for the easy addition of new components, such as extra air conditioning units or additional vents, without significant alterations to the existing infrastructure. Thus, the building remains compliant with airflow regulations both now and in the future, even as occupancy levels change and new requirements emerge.

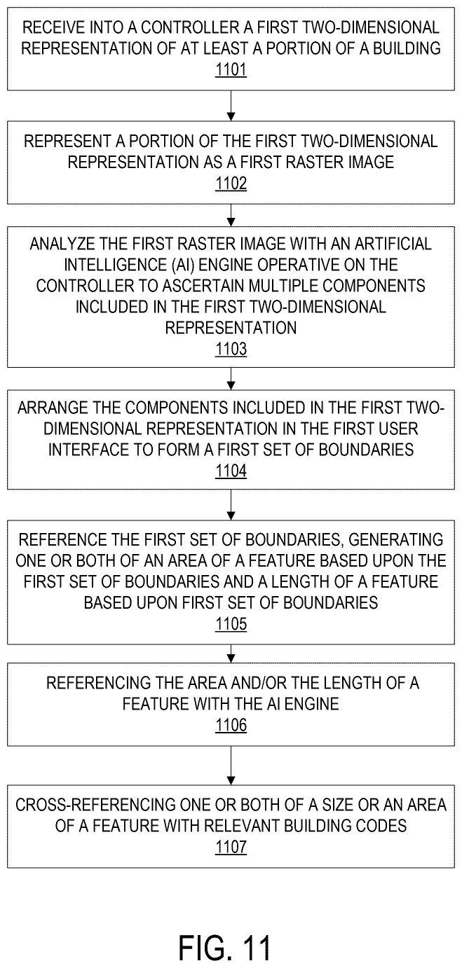

Referring now to FIG. 11, a flowchart illustrates an exemplary method for quantifying whether the airflow design within a portion of a building complies with relevant building deployment objectives, utilizing an AI-driven system. The system comprises one or more controllers that execute the specified operations or actions through software, firmware, hardware, or a combination thereof. The process detailed in the flowchart harnesses AI technology to analyze design plans, identify airflow components, and verify adherence, thereby determining whether the building meets all necessary ventilation and air quality objectives.

At step 1101, the method initiates by receiving a two-dimensional representation of at least a portion of a building into the controller. This two-dimensional representation is an architectural design plan, which may include a floor plan, a blueprint, or a digital design file, such as CAD or Revit files. The design plan serves as an input for the AI engine's analysis, offering a detailed depiction of the building's layout, including the placement of airflow components such as vents, ducts, and HVAC units. For example, the design plan may depict the layout of a commercial office space, illustrating the locations of air supply and exhaust vents, ductwork paths, and air conditioning units, all of which are required for determining adherence with indoor air quality standards and relevant building deployment objectives.

At step 1102, the controller processes the design plan by converting a portion of it into a raster image. The raster image, being pixel-based, allows the AI engine to analyze the design in a structured format that supports pattern recognition and component identification. This conversion is provided for transforming the static design plan into a format that the AI engine can effectively manipulate and evaluate. For example, the raster image may represent a section of a building's ventilation system, where the AI engine can begin identifying specific elements like air vents, ducts, and HVAC components based on their pixel patterns and spatial arrangements.

Following the rasterization, step 1103 involves analyzing the raster image with the AI engine to ascertain multiple airflow components included in the design. The AI engine is programmed to recognize and differentiate various airflow components within the design, such as air supply and exhaust vents, ducts, and air conditioning units. Sophisticated algorithms enable the AI engine to detect these components by analyzing their shapes, spatial relationships, and standard configurations within the building. For example, the AI engine may identify an air vent by recognizing its rectangular outline and its proximity to connecting ducts and walls, so that all necessary ventilation components are accurately identified and accounted for.

Step 1104 focuses on arranging the identified components into a user interface to form a first set of boundaries. These boundaries may delineate zones within the design plan, such as areas where specific airflow or ventilation requirements must be met. The user interface generated at this step is interactive, providing users with a visual representation of the design that clearly demarcates compliant and non-compliant areas. For example, the AI engine may outline the minimum clearance area required around an air vent for unobstructed airflow and for maintaining adequate ventilation as per building deployment objectives. Users can interact with these boundaries, making necessary adjustments to the design within the user interface to achieve full adherence with the relevant building deployment objectives.

At step 1105, the method may involve generating one or both of an area of a feature based on the first set of boundaries and a length of a feature derived from the first set of boundaries. This step is integral to quantifying specific elements within the airflow design, where the AI engine analyzes the designated zones and features within the design plan. For example, the AI engine may determine the total area occupied by an air supply vent or the length of ductwork required to connect various parts of the ventilation system. These measurements are for assessing whether the design meets the spatial and dimensional requirements outlined in the relevant building deployment objectives, particularly for sufficient coverage for effective air distribution and ventilation.

At step 1106, the method involves using the AI engine to reference at least one of-the area of the feature or the length of the feature, previously calculated. This referencing step allows the AI engine to cross-check the measured areas or lengths against established standards and guidelines within the building deployment objectives. For example, the AI engine may reference the calculated length of a duct to verify that it aligns with the required specifications for airflow velocity and pressure loss over distance. Similarly, the area of a vent may be compared against the necessary ventilation rate for a given room size for adequate air exchange and indoor air quality. This cross-referencing is useful for identifying potential non-adherence issues, where the design may fall short of building deployment objective requirements due to improper sizing or placement of airflow components.

At step 1107, the process involves cross-referencing one or both of the size (length-width) or the area of a feature related to airflow performance with relevant building deployment objectives. In this step, the AI engine undertakes a detailed examination of specific features within the design plan that impact airflow, such as windows, air vents, ducts, and other ventilation-related components. For example, the AI engine may retrieve the size of an air vent and compare it to the minimum or maximum size requirements dictated by building deployment objectives. These building deployment objectives often specify dimensions based on the room's intended use, occupancy, and size, so that the airflow is sufficient to maintain healthy indoor air quality. If the AI engine identifies that a vent is too small for a large space, or unnecessarily large for a small room, it may flag these discrepancies and suggest resizing or repositioning the vents.

Additionally, the AI engine may analyze the area of windows in relation to the space they serve, checking whether they provide adequate natural ventilation as required by the building deployment objectives. For rooms that rely on mechanical ventilation, such as air conditioning or HVAC systems, the AI engine evaluates the duct sizes and compares them to the area they are meant to service. Moreover, the AI engine also considers the spatial distribution of these features, as improper spacing can affect airflow efficiency. For example, closely spaced vents may create air pressure imbalances, while widely spaced vents may lead to uneven air distribution. By cross-referencing these spatial considerations with the building deployment objectives, the AI engine determines not only if the design meets regulatory requirements but also optimizes airflow throughout the building.

Throughout the process, the AI engine automates much of the verification work, reducing the potential for human error and speeding up the review process. By systematically analyzing the design plan, identifying main components, and evaluating them against established building deployment objectives, the AI engine provides a powerful tool for architects, engineers, and builders to determine if their designs are not only functional but also fully compliant with all relevant airflow regulations.

Any or all of steps 1101-1107 may be repeated for different portions of the two-dimensional reference descriptive of the building. This iterative process allows the AI engine to perform a comprehensive analysis across various sections of the building, so that every area from individual rooms to entire floors, meets the necessary airflow and ventilation requirements. By repeating these steps, the AI engine systematically identifies and addresses any potential adherence issues, providing detailed feedback and recommendations that can be used to refine the design plan before construction begins. Due to this repetition of steps, the building, as a whole, achieves optimal air quality, ventilation, and safety in accordance with the relevant building deployment objectives and preferred practices.

In some embodiments, a scale of one or more components or fixtures may be determined and a parameter of one or both of a polygon and a line segment (related to the fixtures) may be modified based upon receipt of an instruction for a user; and a boundary may be set based upon reference to a boundary allocation hierarchy.

The steps may be performed multiple times and may include two or more two dimensional references to be processed and be compared one against the other to ascertain when a change has been made to a two-dimensional reference that places a building in adherence with a selected building deployment objective. In various embodiments, a change in subsequent two-dimensional references may be used to generate a change in one or more of a take-off, labor costs, project management input, or other aspects that may impact the construction of a building and/or associated costs.

Implementations may include one or more of the following features. The method additionally determining a scale of the components included in the design plan and/or generating a user interface including user interactive areas to change at least one of: a size and shape of at least one of the dynamic components, the dynamic components may include, by way of non-limiting example, one or more of: architectural features, polygons or arcuate shapes; regions, areas, spaces, travel paths, egress paths, dominance hierarchies, occupancy loads, doorways, stairs, or other portion of a design plan that may be modified.

In some embodiments dynamic components may include a polygon and/or arcuate shape. A method of practice of the present invention may further include the steps of: receiving an instruction via the interactive user interface to modify a parameter of the polygon and modifying the parameter of the polygon based upon the instruction received via the interactive user interface. The parameter modified may include one or both of: an area of the polygon; and a shape of the polygon.

In another aspect a dynamic component may include a line segment and/or arcuate segment, and methods of practice may include one or more of: receiving an instruction via an interactive user interface to modify a parameter of the line segment, and the method further includes the step of modifying the parameter of the line segment based upon the instruction received via the interactive user interface. The parameter of the line segment may include a length of the line segment, and the method may additionally include modifying a length of a wall based upon the modifying the length of the line segment.

The parameter modified may additionally include a direction of the line segment and the method may additionally include modifying an area of a room based upon the modifying of the length and direction of the line segment. A boundary may be set based upon reference to a boundary allocation hierarchy.

In another aspect, a price may be associated with each of the quantities of items to be included in construction of the building. In addition, a type of labor associated with at least one of the items to be included in construction of the building may be designated based upon AI analysis of the first two-dimensional reference and the second two-dimensional reference, respectively.

Methods of practice may additionally include the steps of: determining whether a design plan received into the controller includes a vector image, and if one of the first and the second design plans received into the controller includes a vector image converting at least a portion of the vector image into a raster image. Implementations of the described techniques may include hardware, a method or process, or computer software on a computer-accessible medium.

Methods of practice may additionally include one or more of the steps of: generating a user interface including user interactive areas to change at least one of: a size and shape of at least one of the dynamic components. At least one of the dynamic components may include a polygon and the method further includes the steps of: receiving an instruction via the interactive user interface to modify a parameter of the polygon and modifying the parameter of the polygon based upon the instruction received via the interactive user interface. The parameter modified may include an area of the polygon and/or a shape of the polygon. Moreover, a modification of a dynamic component included in a polygon may change a calculation of an area of a unit, or other defined space. A change in the area of a unit may allow for a recalculation that results in a modification of one or more of: an occupancy load; a length of a path of egress; an length and/or area of a common path; a width of a stair; a travel distance to traverse a dead end; an existence of a dead end; or other variable referenced in determination of adherence with a set of conditions, such as a building deployment objective relevant to a geopolitical locality and a building.

A dynamic component may include a line segment and/or vector, and the method may further include the steps of: receiving an instruction via the interactive user interface to modify a parameter of the line segment and/or vector and modifying the parameter of the line segment and/or vector based upon the instruction received via the interactive user interface. The parameter modified may include a magnitude of the line segment and/or vector and/or a direction of the vector.

The methods may additionally include one or more of the steps of setting a boundary based upon reference to a boundary allocation hierarchy; associating a price with each of the quantities of items to be included construction of the building; totaling the aggregated prices of items to be included construction of the building; designating a type of labor associated with at least one of the items to be included construction of the building; designating a quantity of the type of labor associated with the at least one of the items to be included in construction of the building; repeating the steps of designating a type of labor associated with at least one of the items to be included construction of the building and designating a quantity of the type of labor associated with the at least one of the items to be included in construction of the building for multiple items, and generating an aggregate quantity of the type of labor.

The method may additionally include the step of training the AI engine based upon a human identifying portions of a design plan to indicate that it includes a particular type of item; or to identify portions of the design plan that include a boundary. The AI engine via may also be trained by reference to a boundary allocation hierarchy.

The methods may additionally include the steps of: determining whether the design plans received into the controller includes a vector image, and if the design plan received into the controller does include a vector image converting at least a portion of the vector image into a raster image; and/or whether a design plan includes a vector image format. Implementations of the described techniques and method steps may include hardware (such as a controller and/or computer server), a method or process, or computer software on a computer-accessible medium.

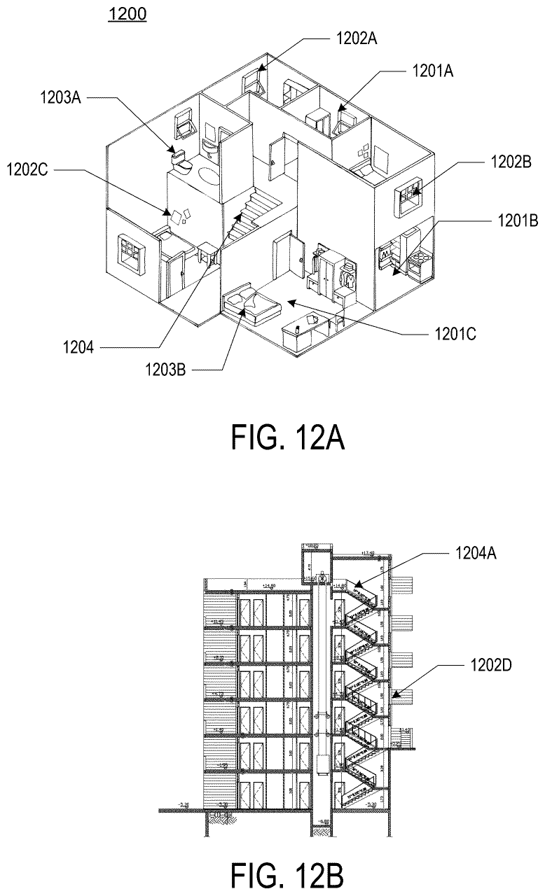

Referring now to FIGS. 12A-12B, an exemplary design plan of a multi-story building 1200 is illustrated. The AI engine meticulously analyzes the design plan for airflow within the framework of relevant building deployment objectives. The AI engine initiates its analysis by identifying and categorizing different units within the building, such as units 1201A, 1201B, and 1201C. Each unit represents a distinct space, potentially designated for various functions, including residential, commercial, or utility purposes. The AI engine evaluates these units to determine the adequacy and placement of airflow fixtures required for maintaining proper ventilation and indoor air quality.

The AI engine may ascertain the presence of various airflow fixtures 1202A-1202D, including but not limited to vents, fans, and air conditioning units. For example, the airflow fixtures may also include supply vents, return vents, exhaust fans, and ceiling fans. The AI engine examines each type of airflow fixture in detail, considering factors such as the quantity of each type required for optimal airflow, their dimensions, their placement within the unit, and their overall effectiveness in circulating air throughout the space. The AI engine may analyze the size and capacity of these fixtures to determine whether they meet the necessary building deployment objectives for the area they serve, taking into account the unit's occupancy, intended use, and physical dimensions.

For example, in the case of an exhaust fan located in a bathroom or kitchen area, the AI engine may assess the fan's capacity to expel air, determining if it is capable of removing moisture, odors, and pollutants efficiently. The AI engine may cross-reference the fan's specifications with the requirements set forth in the relevant building deployment objectives, determining if the airflow rate meets or exceeds the minimum standards (building deployment objectives) required for such spaces. Similarly, the AI engine may evaluate the placement and size of air supply vents within a living room or bedroom, determining if fresh air is distributed evenly throughout the space without creating drafts or dead zones.

In addition to airflow fixtures, the AI engine also ascertains the presence of non-airflow fixtures within each unit (1201A-1201C). Non-airflow fixtures 1203A-1203B may include items such as lighting fixtures, furniture, plumbing components, and structural elements like walls and partitions. The AI engine evaluates these fixtures to determine their impact on airflow within each unit, assessing how their placement may obstruct or facilitate the movement of air. For example, the placement of large furniture pieces near air vents may impede airflow, reducing the effectiveness of the ventilation system. The AI engine may recommend repositioning such fixtures to optimize air circulation within the space.

The AI engine also identifies useful areas within the building, such as points of egress 1204, which are used for safety and emergency evacuation. Stairwells or vertical openings 1204A, as depicted in FIG. 12B, are of particular importance in this analysis. The AI engine examines these areas for sufficient airflow, determining if they are equipped with appropriate airflow fixtures 1202D, such as stairwell pressurization fans or additional exhaust vents. These fixtures are required for maintaining air quality and removing smoke or other harmful substances in stairwells 1204A during an emergency. The AI engine assesses the size, placement, and capacity of these fixtures to determine if they meet the required standards for safety and functionality.

Furthermore, the AI engine analyzes the overall design of the stairwells 1204A, considering factors such as the height, width, and connection points to other units within the building. This analysis may include evaluating whether the stairwell 1204A is adequately ventilated to prevent heat buildup or the spread of contaminants between floors. The AI engine may recommend the installation of additional airflow fixtures if the current setup is found lacking, or it may suggest modifications to the stairwell's design to improve airflow and meet a deployment objective.

The AI engine's analysis is not limited to identifying discrepancies; it also provides actionable recommendations for bringing the building design into adherence. For example, if a particular unit is found to lack sufficient ventilation, the AI engine may suggest increasing the size or number of airflow fixtures, adjusting their placement, or incorporating additional features like air purifiers or dehumidifiers to enhance indoor air quality. These recommendations may be tailored to the specific needs of each unit and are based on the AI engine's comprehensive understanding of the building's design, the intended use of each space, and the applicable building deployment objectives.

In addition to its analysis of individual units, the AI engine also considers the building 1200 as a whole, determining if the cumulative effect of all airflow fixtures meets the overall requirements for ventilation and air quality. This holistic approach allows the AI engine to identify potential issues that may not be apparent when analyzing units in isolation. For example, the AI engine may detect that the combined airflow from multiple units could lead to pressure imbalances within the building, which may affect the performance of HVAC systems or create discomfort for occupants. The AI engine may then provide recommendations to address these issues, such as adjusting the settings on HVAC equipment or adding dampers to balance airflow.

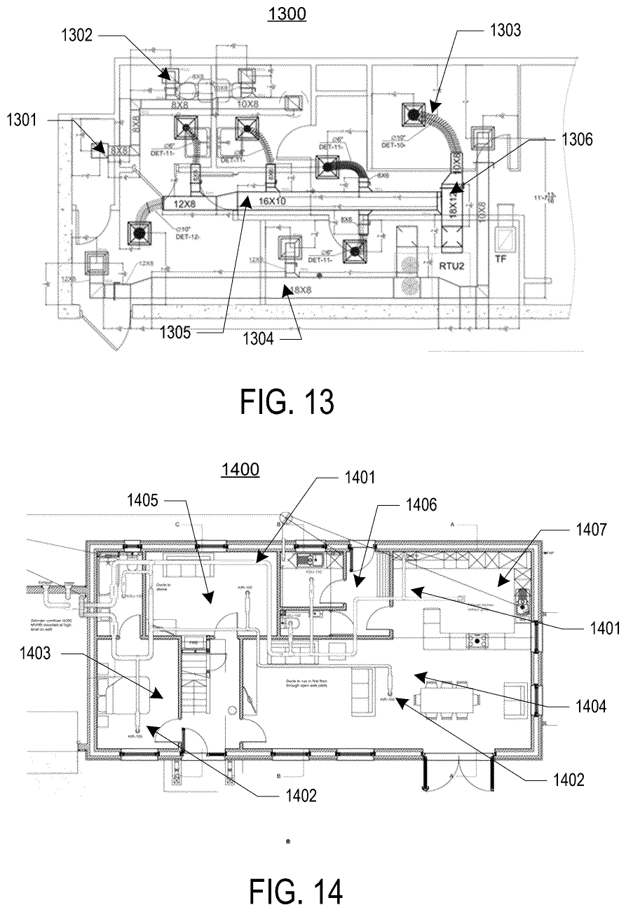

Referring now to FIG. 13, a design plan 1300 illustrates the layout of a building with several airflow paths 1301-1306 identified by the AI engine. These paths represent the routes through which air circulates within the building, as facilitated by the HVAC system. The AI engine analyzes these paths to assess whether they meet the necessary standards for effective airflow management and indoor air handling.

In some embodiments, the AI engine conducts a detailed analysis of these airflow paths to determine the volume of air that can be accommodated and transported through each designated route. For buildings with complex layouts, the AI engine determines whether the volume of air that can pass through each pathway is sufficient to meet the needs of all occupants and maintain a comfortable indoor environment. For example, in a hospital or a large commercial building, where the air needs to be refreshed frequently to maintain air quality, the AI engine calculates whether the existing duct sizes and airflow paths are capable of handling the maximum expected occupancy load. The AI uses the design plan 1300 to simulate different occupancy scenarios and calculates the airflow volume requirements for each. If the analysis by AI engine, reveals that certain paths 1301-1306 are insufficient to carry the required air volume, the AI may flag these areas for revision, suggesting modifications such as increasing duct sizes or adding additional pathways to alleviate potential bottlenecks.

The AI engine analyzes airflow paths for volume, in which various relevant building deployment objectives may be referenced that dictate a minimum airflow rate required for different types of rooms or spaces within a building. These building deployment objectives can vary based on the intended use of the space, the number of occupants, and the specific requirements for temperature control and air quality. By comparing the calculated airflow volumes against these building deployment objectives, the AI can determine if the current design is adequate or if modifications are needed to meet building deployment objective requirements. The building will operate efficiently once constructed, without requiring costly retrofits or adjustments later on.

In some embodiments of the present invention, the AI engine also analyzes the airflow paths 1301-1306 for unimpeded pathways, which include both straight runs and turns. The AI assesses whether the airflow paths are free from obstructions that may impede air movement, such as sharp bends in the ductwork, improperly sized ducts, or other physical barriers. The presence of such impediments can significantly reduce the efficiency of the HVAC system by creating resistance to airflow, leading to uneven distribution of air throughout the building. The AI engine analyzes each section of the path, identifying areas where the airflow may be restricted and determining the potential impact on overall system performance.

For example, in analyzing a turn within an airflow path, the AI engine considers the angle of the turn and the velocity of the air moving through it. If the turn is too sharp, it may cause turbulence, leading to a drop in pressure and reduced airflow. The AI may suggest redesigning the duct layout to include a smoother, more gradual turn that allows for more efficient air movement. Similarly, if a straight run is too long without adequate support, it may lead to sagging or warping of the duct, which may also impede airflow. The AI may detect such potential issues and recommend reinforcing the duct or rerouting the airflow to avoid these problems.

Furthermore, the AI engine's analysis of unimpeded pathways includes an evaluation of the duct material and its impact on airflow. Different materials can have varying levels of friction, which affects how easily air can pass through the ducts. The AI assesses whether the chosen materials are appropriate for the expected airflow volumes and velocities, and whether alternative materials may offer better performance. This aspect of the analysis is particularly relevant in buildings where energy efficiency is a priority, as reducing friction within the ducts can lead to significant energy savings over time by reducing the workload on the HVAC system.

Another element of the AI's analysis of unimpeded pathways is the detection of potential blockages or areas where the airflow may be compromised due to external factors. For example, the AI may detect that a particular section of the ductwork is too close to a structural beam or other obstacle, which may cause partial blockage of the airflow. The AI engine may recommend repositioning the ducts or adjusting the building design to eliminate these obstructions and maintain a clear, unobstructed path for air movement. This proactive approach helps to avoid potential issues that may arise during construction or operation, thereby saving time and resources.

In buildings with multiple zones or areas that require different levels of airflow, the AI engine's analysis of unimpeded pathways becomes even more complex. The AI engine allows each zone to receive the appropriate amount of air without interference from other zones. For example, in a mixed-use building where some areas are designated for office use and others for residential use, the airflow requirements may differ significantly. The AI engine analyzes the paths so that each zone is properly isolated from others, preventing cross-contamination of air so that each zone's specific needs are met. If the AI detects that the current design may lead to air from one zone seeping into another, it may recommend modifications to the duct layout or the addition of dampers to control airflow between zones.

Moreover, the AI engine's ability to analyze airflow paths for unimpeded pathways includes a focus on energy efficiency. By identifying and eliminating areas of resistance or obstruction, the AI engine allows the HVAC system to operate with maximum efficiency, reducing the energy required to maintain the desired indoor environment. This not only lowers operating costs but also contributes to the building's overall sustainability. For example, by minimizing pressure drops in the ductwork, the AI reduces the need for the HVAC system to compensate by working harder, which in turn reduces energy consumption and extends the lifespan of the equipment.

Finally, the AI engine's analysis of airflow paths for both volume and unimpeded pathways is not limited to the design phase of a building project. In some embodiments, the AI engine can also be used during the construction and operational phases to monitor and adjust the HVAC system as needed. For example, during construction, the AI may detect deviations from the original design plan, such as changes in duct placement or unexpected obstacles. The AI may provide real-time feedback to the construction team, allowing them to make adjustments to the final installation so that it meets the design specifications and building deployment objective requirements. Similarly, during operation, the AI may continuously monitor the HVAC system's performance, detecting issues such as duct leaks or blockages and recommending corrective actions to maintain optimal airflow.

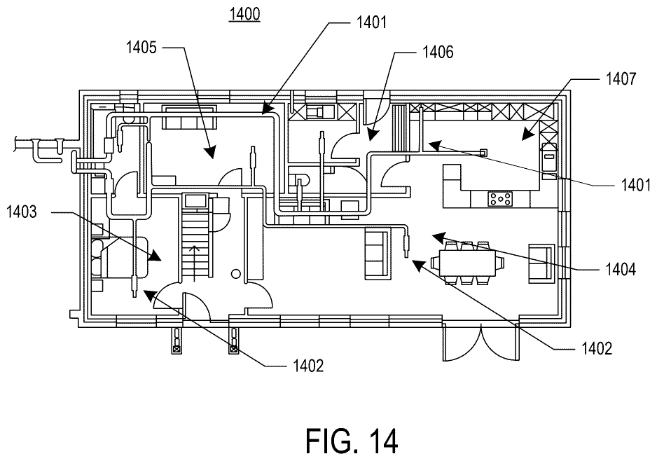

Referring now to FIG. 14, the design plan 1400 illustrates the layout of a building equipped with various airflow equipment items 1401-1402 that are strategically positioned to manage the distribution of air throughout the structure. These items may include, for example, air handling units, vents, and ducts, each playing a vital role in maintaining proper airflow. In some embodiments of the present invention, the AI engine identifies and analyzes these airflow equipment items 1401-1402 to determine whether they are capable of efficiently and adequately servicing the optimum or at least minimum airflow requirements for designated areas 1403-1407 within the building. This analysis is conducted with a focus on occupancy load, so that each area receives the necessary amount of air to maintain a comfortable and safe indoor environment.

In this embodiment, the AI engine begins by examining the capacity of each airflow equipment item 1401-1402. This includes an evaluation of the equipment's specifications, such as its airflow rate (measured in cubic feet per minute, or CFM), power consumption, and compatibility with the building's design and intended usage. For example, the AI may analyze whether an air handling unit 1402 located near area 1403 can deliver sufficient airflow to meet the needs of that space, which may have a high occupant load. The AI engine considers factors such as the size of the area, the number of occupants, and the specific environmental conditions required (e.g., temperature, and humidity) to determine if the existing equipment is adequate.

If the AI determines that an airflow equipment item 1401-1402 is insufficient to meet the airflow requirements for a particular area, it may suggest modifications or upgrades to the equipment. For example, if the AI engine finds that a vent 1402 serving area 1404 is too small to provide adequate ventilation, it may recommend replacing it with a larger vent or adding additional vents to increase airflow. Similarly, if an air handling unit 1401 is found to be underpowered for the space it serves, the AI engine may suggest upgrading to a more powerful unit or adding supplementary equipment to boost airflow.

The AI engine also analyzes the distribution of airflow throughout the building. It analyzes the placement and capacity of the airflow equipment items 1401-1402 in relation to the areas 1403-1407 they serve, determining if air is distributed evenly and efficiently. For example, the AI engine may assess whether the ductwork connecting an air handling unit 1401 to multiple areas 1403-1407 is properly sized and configured to deliver air to each area without significant losses in pressure or flow. If the AI engine detects any issues, such as imbalances in airflow between different areas, it may suggest reconfiguring the ductwork or adjusting the placement of airflow equipment to achieve a more balanced distribution.

In addition to assessing the capacity of individual airflow equipment items 1401-1402, the AI engine also evaluates the overall system's ability to maintain indoor air quality in areas 1403-1407. This includes an analysis of how well the system can filter and circulate air, remove contaminants, and maintain appropriate levels of humidity and temperature. For example, the AI engine may analyze whether the HVAC system is capable of maintaining a consistent indoor temperature in area 1406, where large windows may cause temperature fluctuations. If the AI determines that the existing system is inadequate, it may recommend adding supplemental heating or cooling equipment, or improving insulation to reduce heat loss or gain.

Moreover, the AI engine's analysis extends to the interaction between different airflow equipment items 1401-1402. In some cases, the performance of one piece of equipment may be affected by the operation of another. For example, if two air handling units 1402 are serving adjacent areas 1403 and 1404, the AI may analyze whether their operation is synchronized to avoid conflicts or inefficiencies, such as one unit overcompensating for the other's performance. The AI engine may recommend adjustments to the control system so that all equipment works together harmoniously to maintain optimal airflow throughout the building.

The AI engine also considers the potential for future changes in the building's usage or occupancy that may affect airflow requirements. For example, if area 1405 is expected to experience an increase in occupancy due to a change in its intended use, the AI may analyze whether the existing airflow equipment is capable of handling the increased demand. If not, the AI engine may provide recommendations for upgrading the system to accommodate the anticipated changes. This proactive approach helps the building's HVAC system to remain effective and efficient over time, even as its usage evolves.

In some embodiment, AI engine analyzes by simulating different environmental conditions and assessing how the airflow equipment items 1401-1402 will perform under various scenarios. For example, the AI engine may simulate a hot summer day and analyze whether the HVAC system can maintain a comfortable indoor temperature in area 1407, where solar heat gain may be a concern. Similarly, the AI may simulate a scenario where the building is fully occupied and analyze whether the system can maintain adequate ventilation and air quality in all areas 1403-1407. These simulations allow the AI engine to identify potential issues before they arise and provide recommendations for preemptive measures to address them.

Finally, the AI engine's analysis of airflow equipment items 1401-1402 may also include a focus on energy efficiency and sustainability. By optimizing the performance of the HVAC system, the AI helps to reduce energy consumption and minimize the building's environmental impact. For example, the AI engine may analyze whether the use of energy-efficient equipment or the implementation of energy-saving strategies, such as variable speed drives for air handling units, may reduce the building's overall energy usage. If the AI engine identifies opportunities for improvement, it may provide recommendations for implementing these strategies, helping to create a more sustainable and cost-effective building.

### User Interaction and Experience

In some embodiments, the present invention includes a controller operative to analyze a building described via one or more of: a floorplan, two-dimensional reference, and/or Revit® compatible file, to ascertain whether the building described possesses a set of conditions useful to determine adherence with building deployment objectives. In addition, in some embodiments, a process executed by an AI engine may ascertain building attributes and analyze the building attributes may be modified in order to bring the building into a state that meets one or more objectives. A user interface may present suggested modifications to a user. Some embodiments may also include designation and/or ranking of variables that may be modified in order to have the building meet an objective. By way of non-limiting example, variables may relate to one or more of: magnitude of structural changes, cost to implement changes, time to implement changes, impact of a change(s) on a desired use of the building, and duration of a proposed change.

In another aspect, in some embodiments, suggested modifications may be ranked according to a priority ranking of features input via a user interface. For example, a user may input priority rankings that dictate that a number of a certain type of room or unit must be maintained above a threshold within the plan, such as, for example, the plan must include: ten residential units, each unit with three bedrooms and two bathrooms and kitchen a living room; or at least four units with three bedrooms each; a second priority may include room sizes of a minimum and/o maximum size; a third priority may include a washer and dryer area; a fourth priority may include a common area of a minimum size; and other prioritized attributes to be included in a building design. AI and/or user input may modify a design of the building to have the building meet an applicable building deployment objective while also adhering to the priority ranking of features.

Still further, in some embodiments, the controller may assess how assignment of different classes of space to one or more designated areas may alter conformance of a design with a specified building deployment objective. Furthermore, in some embodiments, particular attributes of a building may be analyzed based upon laws or regulations in effect within a geopolitical boundary encompassing the building. In some embodiments, multiple disparate user interfaces may be used to communicate calculated parameters associated with determined attributes in order to give a user an improved experience while determining building deployment objective adherence within a given design plan, as well as changes in a determination of building deployment objective based upon a change in one or more of the building attributes.

In an example, a user interface may be designed for an optimal user experience in evaluating an existence (or non-existence) of attributes necessary in order for a design plan to be in alignment with a specified building deployment objective. In some embodiments a design may be evaluated by any of the various processes as have been described herein. After a design plan is received into a controller, an interface may be presented to a user to allow for interactive assessment of attributes required for alignment with building deployment objectives.

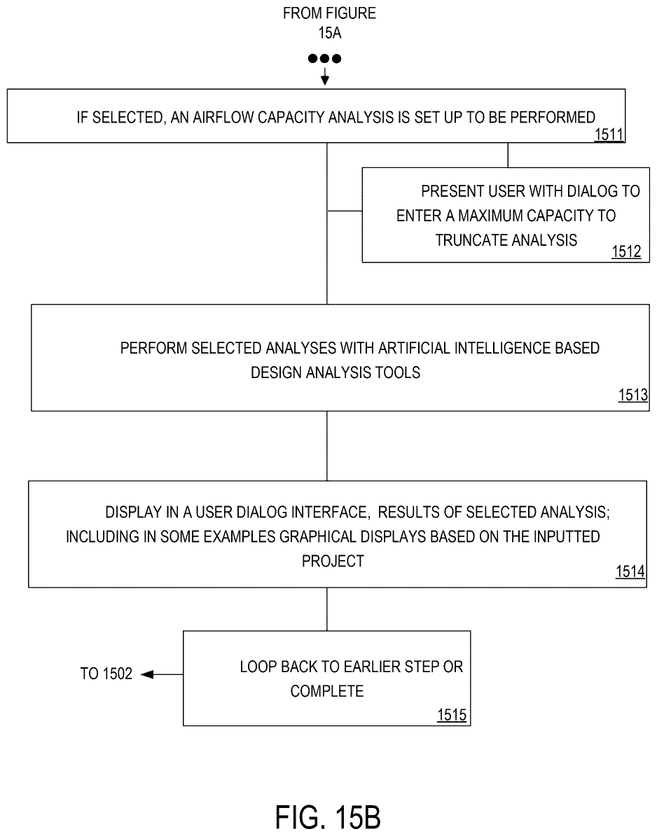

Referring now to FIGS. 15A-15B exemplary method steps that may be completed in accordance with the present invention are illustrated. The method steps may be part of a user experience.

At step 1500, boundaries may be defined. These boundaries serve as demarcations that distinguish various zones or areas within the building layout, which are provided for subsequent analyses related to airflow and ventilation. The AI engine of the present invention is programmed to automatically detect and define these boundaries based on the architectural features present in the design plan, such as walls, doors, windows, and HVAC components. By accurately establishing these boundaries, each zone is properly evaluated for airflow according to the relevant building deployment objectives, such as ASHRAE standards or local building deployment objectives.

At step 1501, the user may be provided with an interactive user interface that display project information including building attributes that are included in a determination of adherence with a set of conditions, such as, for example, building deployment objectives or preferred practices from which adherence will be determined. This interface allows the user to view and interact with various aspects of the building's design, providing a clear overview of the attributes that will be analyzed for airflow objectives. For example, the user can view details about the placement and dimensions of HVAC components, air supply and exhaust vents, and other airflow-related features. The interface may also highlight specific areas of concern, such as zones that require particular attention for adherence with ventilation related building deployment objectives.

At step 1502, the user may select an analysis to be performed. In some embodiments, the options for the analysis may include an analysis of a building for attributes that pertain to, one or more of: occupancy load, travel distance, a common path, dead end paths, and egress capacity of the spaces described in a design plan (or other references). In some examples, multiple analyses or all offered analyses may be chosen by the user. Since a choice of all analyses may proceed through all example analysis, the example in the illustration will proceed with this choice. For example, an occupancy load analysis may determine whether the ventilation system is capable of providing adequate air exchange for the number of occupants in a given space. The user has the flexibility to choose one or more of these analyses or to perform all available analyses sequentially. In the illustrated example, the process proceeds with the selection of all available analyses for a comprehensive assessment of the building's design.

At step 1503, in a first analysis occupancy load may be performed. In this step, the AI engine calculates the expected number of occupants for each zone within the building based on the design plan. The analysis considers factors such as room size, intended use, and occupancy classifications as defined by relevant building deployment objectives. The AI engine then evaluates whether the existing HVAC system can support the calculated occupancy load for sufficient airflow to maintain indoor air quality and comfort levels. If the analysis identifies potential issues, such as inadequate ventilation for high-occupancy areas, the AI engine may generate recommendations for modifying the design to achieve an objective.

At step 1504, in some examples, the user may decide on the types of space to be used along with an occupant load factor for the associated type of space. In some examples, the user may enter descriptions and factors manually. In other examples, a drop-down dialog may be presented to the user for them to choose the space types. In some examples, the user may enter associated occupant load factors. In other examples, an automatic look-up of the space's associated occupant load factor may occur with a choice of the type of space. In some examples, an associated building deployment objective to be used for appropriate regions may be displayed to the user. In some embodiments, optical character recognition may be performed on located objective documents to look up the appropriate occupant load factors automatically. Further, as mentioned in some examples, the user may input the types of area for a design, while in other examples algorithms may be used to automatically classify areas by type.

At step 1505, an airflow analysis may be performed. This analysis focuses on evaluating the efficiency and effectiveness of the building's ventilation system. The AI engine examines factors such as air distribution, airflow patterns, and the placement of HVAC components to determine whether the system meets the required building deployment objectives for indoor air quality. The analysis may also consider the impact of architectural features on airflow, such as the presence of barriers that may obstruct air movement or cause uneven distribution. Based on the findings, the AI engine may recommend adjustments to the placement or configuration of HVAC components to enhance airflow and to meet an objective.

At step 1506, the UI/UX may present the user with a dialog to allow the user to input units along with a number of those unit types and limits, such as the maximum inside, maximum outside, and total values. In some examples, the limit values may be automatically chosen. The limits may comprise just a max total value, or a combination of max total as well as max inside, or in some examples a max inside, a max outside, and a max total limit value. For example, the AI engine may recommend different limit values for residential and commercial units, taking into account factors such as building size, occupancy, and usage patterns. By defining these limits, the subsequent analyses are aligned with the specific requirements of the building's design.

At step 1507, a third analysis may be performed for the common path. The common path analysis assesses the design's ability to facilitate safe and efficient egress in the event of an emergency, with particular attention to airflow considerations. The AI engine evaluates the airflow patterns along common paths, such as hallways and corridors, to support proper ventilation and not create conditions that may hinder evacuation, such as smoke accumulation or reduced air quality. If issues are detected, the AI engine may suggest modifications to the design, such as repositioning HVAC components or altering the layout to improve airflow along these paths.

At step 1508, the user may input values associated with the common path analysis which in some examples may be the same values input at step 1506. This step allows the user to define specific parameters for the common path analysis that is tailored to the building's design and intended use. For example, the user may specify maximum allowable distances for common paths or set thresholds for airflow rates that must be maintained along these paths. The AI engine uses these inputs to perform a detailed analysis, identifying any areas where the design may fall short of a desired objective and providing recommendations for improvement.

At step 1509, a maximum load airflow analysis may be chosen and performed. This analysis evaluates the building's ventilation system under conditions of maximum occupancy or usage for it to maintain adequate airflow even during peak demand. The AI engine simulates various scenarios, such as full occupancy or extreme weather conditions, to assess the system's performance. If the analysis reveals potential weaknesses, such as insufficient airflow in high-demand areas, the AI engine may suggest design modifications to enhance system capacity and meet an objective under all conditions.

At step 1510, the user may modify the airflow design based on the results of the previous analyses. The interactive user interface allows the user to make adjustments to the design, such as repositioning HVAC components, resizing ducts, or altering the layout of rooms and corridors. The AI engine provides real-time feedback on the impact of these modifications on the updated design to meet the required building deployment objectives for airflow. This iterative process enables the user to refine the design until it achieves optimal performance and adherence to all relevant building deployment objectives and preferred practices.

At step 1511, an airflow capacity may be chosen and performed. This analysis focuses on determining whether the building's ventilation system has the capacity to handle the expected airflow demands based on the design plan. The AI engine calculates the total airflow capacity required for each zone and compares it to the system's capabilities, identifying any areas where the capacity may be insufficient. If necessary, the AI engine may recommend upgrades to the system, such as adding additional vents or increasing the size of ducts, so the building can maintain proper airflow under all conditions.

At step 1512, the process involves the user inputting capacity factors related to various structural and airflow elements within the building design. These capacity factors include, but are not limited to, doors, stairs, rooms, and airflow fixtures such as vents, fans, and ducts. For example, the capacity factors for doors may relate to their ability to facilitate proper airflow between spaces, especially in scenarios where natural ventilation is part of the airflow criteria. The size, type, and placement of doors can significantly impact the movement of air between rooms, and these factors are considered to evaluate whether the design will allow for adequate cross-ventilation or air exchange.

Similarly, airflow fixtures, such as vents, ducts, and fans, are directly linked to the capacity to maintain optimal air quality and temperature control. The user may input factors such as the expected air exchange rate, the power of mechanical fans, the size and placement of vents, and the efficiency of ducts. These inputs allow the AI engine to simulate airflow within the building and determine whether the design meets the necessary building deployment objectives for air distribution and quality. The AI engine evaluates these factors in relation to the building's overall design to identify any potential inefficiencies or issues.

At step 1513, with the parameters, designations and limits entered, the analysis may continue. In some examples, the design may be presented to the users along with icons, buttons and other active features that may allow the user to adjust the design, and the AI extracted feature elements. There may also be icons, buttons, and other features to activate chosen analysis types to be performed. The user can activate specific analyses as needed for thorough evaluation of the design for inadequate airflow. The AI engine provides detailed feedback on the analysis results, highlighting areas of concern and offering suggestions for improvement.

At step 1514, after the analyses are performed the interactive user interface may be generated with graphical presentations indicating analysis results. These presentations provide a visual summary of the objective status, making it easy for the user to identify areas that require attention. The graphical interface may include color-coded indicators, charts, and diagrams that illustrate the airflow patterns, capacity, and other factors. This visual feedback is invaluable for making informed decisions about the design to meet all relevant airflow related building deployment objectives and preferred practices.

At step 1515, the process may loop back to an earlier step or conclude. If the user chooses to revisit a previous step, they can make further modifications to the design and rerun the analyses to verify that an objective is met. Alternatively, the process may conclude if the design has been fully optimized and meets all necessary requirements. This flexible workflow allows the user to iteratively refine the design to achieve the highest standards of airflow management and alignment with relevant building deployment objectives.

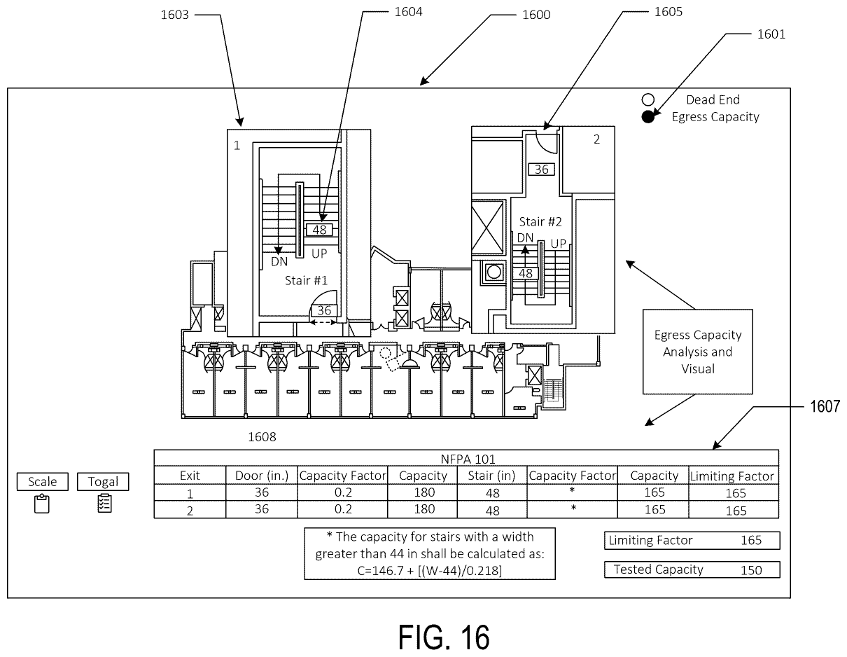

Referring now to FIG. 16, an exemplary interactive user interface 1600 illustrates building attributes referenced in an analysis of airflow capacity of a design plan. Airflow capacity may be defined as the number of people an airflow system may accommodate efficiently during deployment of a building. The interactive user interface 1600 integrates a graphic description of a structure's design plan 1608, which is central to the analysis. The graphic serves as a visual representation of the building layout, enabling users to correlate specific areas within the design to the airflow capacity analysis 1601. This analysis is to provide insight into whether the designed airflow systems are adequate to maintain indoor air quality and temperature control for the anticipated occupancy load, thus the building layout adheres to relevant building deployment objectives and preferred practices.

In some embodiments, the AI engine may analyze a portion 1602 of the design plan 1608 for the presence and placement of specific architectural elements that are required for the airflow management of the building. Among these elements, stairwells 1603 and doors 1605 are particularly significant as they influence both the distribution of airflow and the building's egress capacity in emergency situations. For example, the AI engine may evaluate the positioning and number of stairwells within a multi-story building to determine if they are sufficient to allow for effective vertical air movement and evacuation. Additionally, the engine examines the dimensions of these features, specifically focusing on the stairwell width 1604 and door width 1606, as these measurements directly affect airflow patterns and egress capacity. After identifying these features, the AI engine determines their adherence with predefined building deployment objectives. Algorithms within the AI engine utilize the measured widths of stairwells and doors, potentially in conjunction with user-entered parameters, to generate an egress capacity analysis. This analysis is pivotal as it calculates the ability of the building's layout to facilitate the rapid and safe evacuation of occupants, while also maintaining adequate airflow during such events. For example, in the event of a fire, the design may be such that smoke and toxic fumes are managed by the airflow system to provide a clear and safe passage through stairwells and exits. The results of this egress capacity analysis are then displayed to the user, often in a tabular format such as the exemplary table 1607, which provides a clear, quantitative summary of the building's adherence with airflow capacity standards.

The interactive user interface 1600 is designed to be highly intuitive, allowing users to easily navigate through the different aspects of the airflow capacity analysis. For example, users can click on specific areas of the design plan 1608 to view detailed information about the airflow capacity in that particular zone, including how many individuals the system can support and whether it meets the local building deployment objective requirements. This feature is particularly useful in large, complex buildings where different sections may have varying airflow needs. The interface also allows users to adjust parameters, such as occupancy load or the number of operational HVAC units, to see how these changes impact the overall airflow capacity of the building.

Moreover, the interface may provide visual indicators, such as color-coded overlays on the design plan, to highlight areas of concern where the airflow capacity may be insufficient. For example, a red overlay may indicate a section of the building where the current design does not meet the required building deployment objectives, prompting the user to investigate further or make necessary adjustments.

In addition to the primary analysis functions, the interactive user interface 1600 may also include advanced features such as scenario testing and predictive modeling. These tools allow users to simulate different operational conditions, such as peak occupancy times or partial system failures, to assess how the airflow capacity may be affected. For example, the AI engine may simulate a scenario where one of the main HVAC units fails and analyze whether the remaining system can still maintain adequate airflow for safe egress. This level of analysis is useful for designing resilient buildings that can withstand unexpected events without compromising occupant safety.

Furthermore, the interface may offer customization options for users to tailor the analysis to specific regulatory requirements or project needs. For example, a user working on a hospital design may need to comply with stricter airflow and egress standards (building deployment objectives) compared to a standard office building. The interface allows the user to input these specific building deployment objectives, for precise analysis. This flexibility makes the present invention adaptable to a wide range of building types and regulatory environments, enhancing its utility across different construction projects.

Finally, after the analysis is completed, the results are presented in a comprehensive report that not only details areas of meeting an objective and not meeting an objective, but also provides actionable recommendations. For example, if the AI engine identifies that a certain section of the building lacks sufficient airflow capacity, it may suggest apparatus and HVAC design to increase airflow capability. These recommendations guide architects, engineers, and builders in making necessary adjustments to the design before construction begins, thereby the final building meets all airflow requirements.

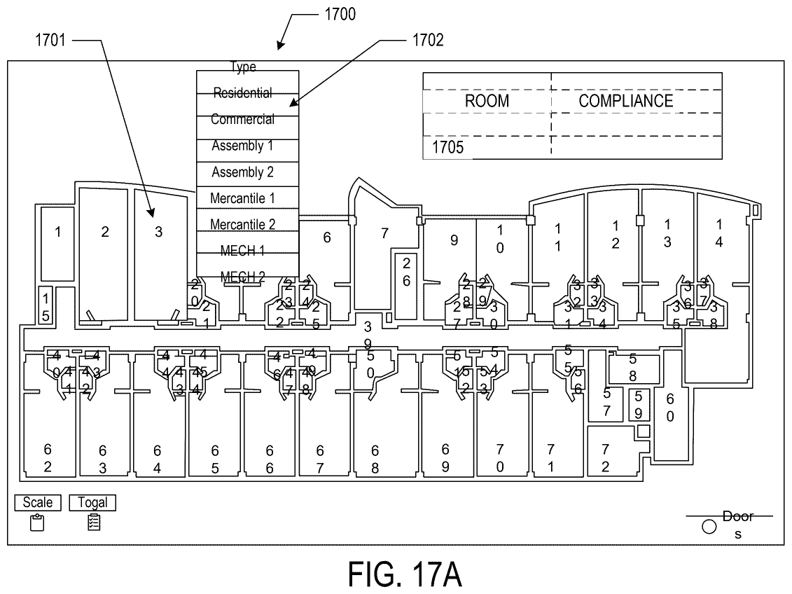

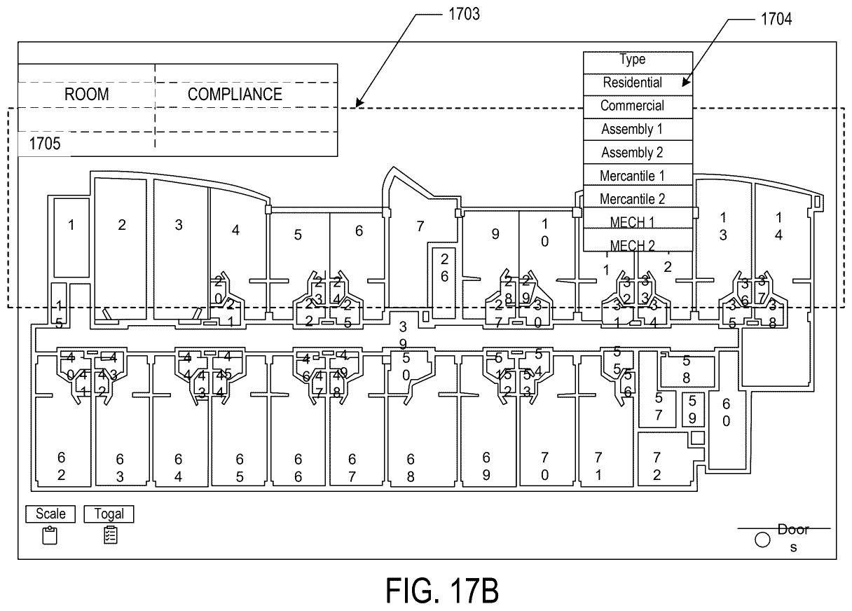

Referring now to FIG. 17A, it illustrates an exemplary interactive user interface 1700 that provides visual indicators for compliant and non-compliant spaces within a design plan undergoing airflow compliance analysis by the AI engine. The interface 1700 is designed to offer a clear, color-coded representation of the airflow compliance status of various areas within the building design, allowing users to quickly identify which parts of the design plan meet the relevant building deployment objectives and which do not. The AI engine performs a detailed analysis of each space, checking the types and quantities of airflow fixtures, such as air supply and return vents, windows, exhaust fans, and their placement and spatial relationships.

In FIG. 17A, the spaces within the design plan are color-coded, with red areas 1701 indicating non-compliant spaces and green areas 1702 representing compliant spaces. The AI engine is responsible for analyzing each space within the design plan against a comprehensive set of building deployment objectives and airflow regulations. When a space is highlighted in red, it signifies that the area has failed to meet one or more of these airflow criteria. For example, a red-colored area may indicate that the airflow fixtures are insufficient to meet the ventilation needs of the space, or that there is an imbalance between supply and return vents leading to poor air circulation. The AI engine evaluates parameters such as the dimensions of the room, the number of occupants, and the intended use of the space to determine whether an objective has been met.

Once the AI engine identifies a space wherein an objective is not being met, it can take several corrective actions. The system may provide a detailed explanation of why the space is not meeting an objective, specifying the exact building deployment objectives that are not being met, such as insufficient air changes per hour or inadequate vent placement. This information is used by architects, engineers, or project managers to understand the necessary adjustments. Additionally, the AI engine may suggest modifications, such as adding more vents, adjusting their placement, or recommending different types of airflow fixtures to provide proper ventilation. These suggestions help streamline the design revision process, allowing users to address issues efficiently and bring the design plan into adherence with an objective.

The green areas within the design plan represent spaces that have been thoroughly analyzed by the AI engine and found to be fully compliant with the relevant airflow related building deployment objectives and preferred practices. These compliant spaces have met all necessary criteria, confirming that they are suitable for construction as designed. This visual confirmation provides users with the assurance that these parts of the design are ready for implementation without further modifications. This feature is especially valuable in large-scale projects where multiple spaces need to be checked for adherence, offering a quick and reliable overview of the building's readiness for construction.

Moreover, the interactive user interface 1700 may include additional features, such as a detailed pop-up window that provides in-depth information about each analyzed area. This window may show details like the type of airflow fixtures analyzed, the specific building deployment objectives applied, and any relevant dimensions or spatial relationships considered during the adherence check. For example, a pop-up may display that a particular room was analyzed for adherence with natural ventilation requirements, confirming the adequacy of window size and placement for sufficient airflow. This feature allows users to dig deeper into the analysis of each space, making informed decisions about potential modifications.

In some embodiments, the interface 1700 may also allow users to interact with the design plan directly, enabling modifications to be made within the user interface. Users may adjust the dimensions of non-compliant areas, change the location of vents, or alter the intended use of a space to achieve adherence. The AI engine can then re-analyze the modified design in real-time, updating the adherence status and color-coding accordingly. This iterative process facilitates a dynamic workflow, where users can quickly adapt their designs to meet regulatory requirements, so that the final design is both functional and compliant with all relevant building deployment objectives.

Referring now FIG. 17B, it illustrates an exemplary interactive user interface 1700 designed for detailed airflow adherence analysis within a design plan. This interface allows users to select specific portions of the design plan for focused analysis by the AI engine. In the depicted interface, a portion 1703 of the design plan has been selected, highlighting certain areas that require closer examination. The selection process within the user interface 1700 is highly flexible, enabling users to define the scope of the analysis through various methods, such as click-and-drag or selecting multiple non-contiguous areas. This flexibility is useful for allowing users to focus the AI engine's analysis on the most relevant sections of the design, so that resources are allocated efficiently.

Once a portion 1703 of the design plan is selected, the AI engine initiates a comprehensive airflow adherence analysis, assessing the selected areas against relevant building deployment objectives and regulations. The AI engine may evaluate a variety of factors, including the type and quantity of airflow fixtures present, their spatial relationships, and whether these fixtures meet the required standards for proper ventilation and air circulation. For example, if the selected portion includes a series of offices and meeting rooms, the AI engine may check for sufficient air changes per hour, proper vent placement, and the overall effectiveness of the airflow system in these areas.

As the AI engine performs its analysis, a color-coded feedback system provides immediate visual cues about the adherence status of the analyzed areas. In FIG. 17B, compliant areas are marked in green, while non-compliant areas are marked in red, such as the area 1701. This instant visual feedback allows users to quickly identify problematic areas within the selected portion of the design plan. Moreover, the user interface 1700 includes a detailed pop-up window 1704 and a comprehensive results table 1705. The pop-up window 1704 provides real-time insights into the adherence status of the selected areas, offering specific details such as the types of airflow fixtures analyzed, and the corresponding building deployment objectives applied. The results table 1705 offers a summary of the adherence analysis, listing metrics such as area size, airflow fixture types, and whether each space meets the required building deployment objectives.

This interactive system not only facilitates detailed analysis but also supports a dynamic and iterative design process. Users can modify the design directly from the interface based on the AI engine's feedback, re-analyze the modified areas, and immediately see updated adherence results. This capability is particularly useful for resolving adherence issues quickly and efficiently, so that the design plan meets all necessary airflow requirements before moving forward in the construction process. The interface also allows for scenario-based analysis, where different design variations can be compared to optimize both adherence and functionality, ultimately contributing to a more effective and compliant building design.

In some examples, where there are non-compliant aspects, a trained artificial intelligence analysis of numerous examples of non-compliant designs and their subsequent design changes that remediated the issues may be used to suggest modifications based on an analysis of the design under review. In other examples, other algorithms may be used to provide such suggestions, such as by review of databases which track common required changes to make a building conform to requirements. Examples of improvements which AI engine may recommend to a user may include adding a new door or other feature to create a new path of egress. In other examples, design elements such as doors may be relocated to address non-adherence. Other examples may include adding structure to block aspects such as dead ends. Still, further examples may address non-adherence aspects by adding features such as by suggesting the adding of a doorway to a dead-end corridor as a non-limiting example.

Highlighting, such as in the ways previously described, may be used to indicate one or both of points of adherence and points of non-adherence. The relevant portions of the building deployment objectives may be displayed such as in an overlay, or a pop-up window and may be matched in various manners to the design under analysis, such as with coloration as a non-limiting example. Alternatively, points of non-adherence may be highlighted. These aspects of the user interface experience may improve effectiveness and/or efficiency for inspectors by providing this highlighting or other summarization of points of adherence and points of non-adherence.

Other tools may also be provided through the user interface experience to support users such as, for example, allowing the user to click and drag a cursor over a space designated as a room. Various symbols and icons may be overlayed on the design to indicate various artifacts, corners, stairs, measurements such as door width, access to measurements or design data of various kinds and the like. The user may be able to zoom into portions of the drawing for a more detailed review and/or the display of more detailed measurements and design data. Furthermore, the user may be able to zoom to features such as in a non-limiting example a doorway to allow a check of calibration of the scale of the design or even a recalibration of the scale, where such a recalibration may drive a reassessment of adherence by the AI engine.

In some embodiments, an AI system may receive an architectural file with intelligent features of various kinds which will be discussed in further detail following. The present system may operate in concert with a BIM or CAD design system for example, as an add-in to these design systems and then the present system may have access to design elements, location data, and the like directly. In other examples, the present system may access BIM or CAD design system data by loading data files from said systems. In still further examples, the present system may operate to capture data from display screens that are displaying designs from the said BIM or CAD design systems.

In a non-limiting example, the present system may receive a file in one of the REVIT native formats such as files of types RVT, RFA, RTE and RFT. Embodiments may also include receiving non-Revit compatible file formats, such as, one or more of: BMP, PNG, JPG, JPEG, and TIF.

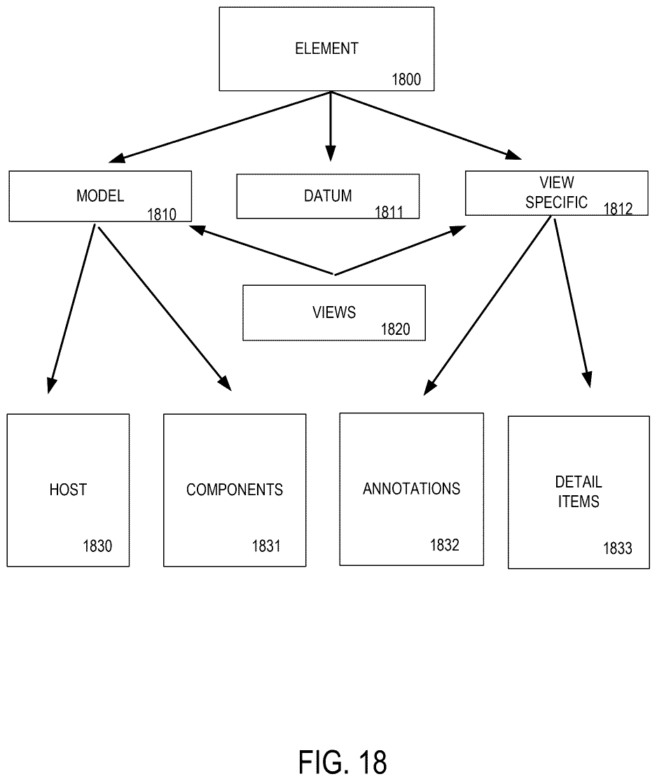

Referring now to FIG. 18, a high-level overview of the types of information that may be stored in a digital file is provided, focusing on the context of airflow adherence analysis using an AI-powered system. FIG. 18 illustrates the hierarchical structure of elements 1800 within a design file, which may be a Revit file or a similar building information modeling (BIM) format. These elements are categorized into different types: model elements 1810, datum elements 1811, and view-specific elements 1812.

Model elements 1810 correspond to the physical components that are to be constructed within a building. These components may include foundational elements such as floors, walls, ceilings, and roofs, which may collectively be referred to as “Hosts” 1830. In the context of airflow adherence, these hosts provide the structural framework within which the HVAC and airflow systems are integrated. For example, walls in a room may host air conditioning units and ducts that are useful for maintaining proper air circulation, while floors may contain vents and diffusers for distributing air evenly throughout the space. The AI engine uses these model elements to understand where and how airflow systems are positioned within the building's framework, allowing it to assess whether these systems meet the necessary adherence standards for effective temperature regulation and ventilation.

The model elements also include components 1831, which are secondary but equally vital features within a building. These components may consist of HVAC units, air supply vents, exhaust vents, fans, and air filtration systems. The AI engine can analyze these components to verify that their installation and placements are compliant with building deployment objectives and industry standards (preferred practices). For example, the AI engine may check the spacing between air supply vents and exhaust vents to determine if it meets the minimum clearance requirements for optimal airflow, or it may assess the positioning of HVAC units to verify that they are placed for efficient air distribution. Additionally, components may include structural supports like beams and braces that may affect the routing of ductwork or the placement of vents. The AI engine considers these elements to determine if airflow systems interfere with the structural integrity of the building or not.

Datum elements 1811 are used to define the design context, providing a reference framework that organizes the model elements. This may include grids, levels, and reference planes, which are used for accurately placing and aligning components within the design. For airflow adherence analysis, datum elements help the AI engine to determine the exact location of airflow components in relation to the overall building layout. For example, a grid system may be used to position air supply and exhaust vents at consistent intervals across multiple rooms on different floors, while levels may be used so that all vents and HVAC units are installed at the correct heights relative to the building's floor levels. These datum elements help the AI engine maintain consistency and accuracy in the adherence analysis process.

View-specific elements 1812, on the other hand, are details and annotations that are visible only when certain views 1820 of the design are activated. These elements may include annotations 1832, such as keynotes, comments, tags, and dimensions, which provide additional context and information of specific parts of the design. For example, an annotation may indicate that a particular duct is insulated with a material that meets local energy efficiency standards, or it may note the expected airflow rate at a certain point in the system. The AI engine uses these annotations to cross-reference the design with airflow and HVAC related building deployment objectives, so that all specified materials and configurations are compliant.

Detail items 1833, another subset of view-specific elements, include lines, fills, and other graphic details that may represent ductwork connections, insulation around vents, or sealing materials used to prevent air leaks in certain areas. These details are provided for the AI engine's analysis, as they often contain the fine-grained information needed to assess adherence with specific airflow and ventilation standards. For example, the AI engine may examine detail lines that represent ductwork connections to determine if they are properly sealed and secured, or it may assess the fill materials around a vent to verify that they are adequate for preventing drafts and maintaining energy efficiency.

The AI engine leverages this multi-layered structure to perform a comprehensive airflow adherence analysis. Starting with the original reference and moving through the model, datum, and view-specific elements, the AI engine systematically evaluates each component's adherence with applicable airflow and ventilation related building deployment objectives. For example, it may start by assessing the overall layout of airflow systems within the host elements to determine if they are logically and efficiently arranged. Then, it can move on to analyzing the specific components like vents and HVAC units to verify if they meet size, spacing, and material requirements or not.

Additionally, the AI engine can use this layered structure to simulate different scenarios, such as changes in airflow patterns or temperature gradients, to predict how the ventilation system will perform under various conditions. By analyzing how these factors interact within the framework of the building's design, the AI engine can provide insights into potential issues before they arise, such as identifying areas where airflow may be insufficient to maintain comfort or where ventilation may be inadequate to remove contaminants effectively.

In some embodiments, various elements may be loaded from exemplary files and extracted for their relevant information. Other file types in addition to the Revit® types previously mentioned may include in a non-limiting sense DGN, DWF, DWG, DXF, IFC, SAT, SKP, ODBC, HTML, TXT, and gbXML file types. As mentioned, systems of the present type may be configured to extract information based on defined file structure of the input file times. In addition, learned aspects may be applied to interpret the designs and assign components or alter certain information about a component. For example, a wall definition may be recognized by the present system and have aspects of it modified, and additional model aspects defined such as an appropriate center line defined, or a set of different dividing line types assigned. The wall may have a designation assigned such as whether it is an internal or external wall. Other such learned assignments may be applied after data is loaded from an external file. As mentioned, the present system may also operate in manners where it has access to objects of the BIM or CAD design system directly as an add-in, or a parallel running system with access to memory locations running in the BIM or CAD design system. Still, further examples may derive from capturing design elements in displays of various kinds. Finally, such access to external file types may be used to verify models generated in the standard manners as have been described or add information such as annotations, descriptions, and other such aspects.

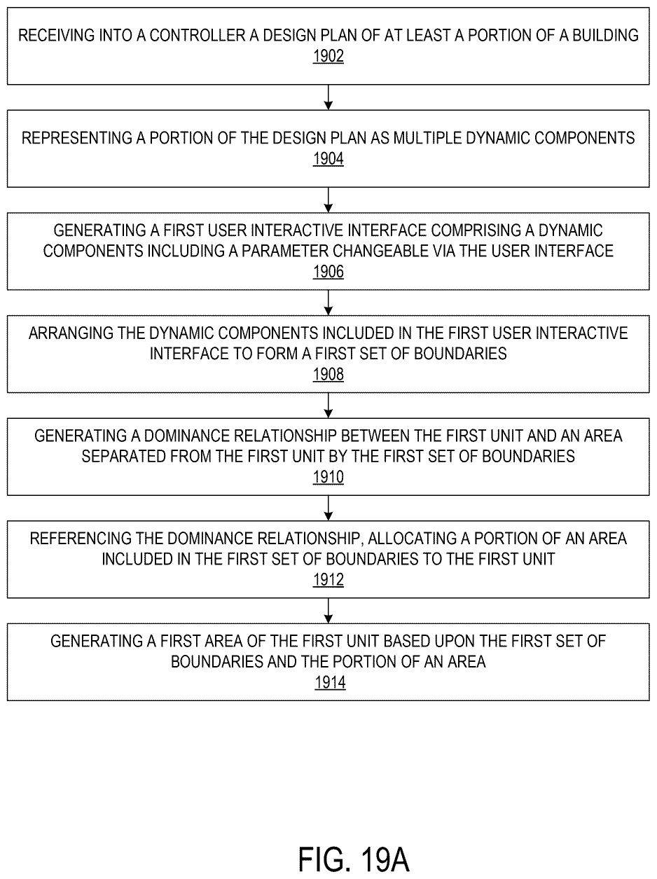

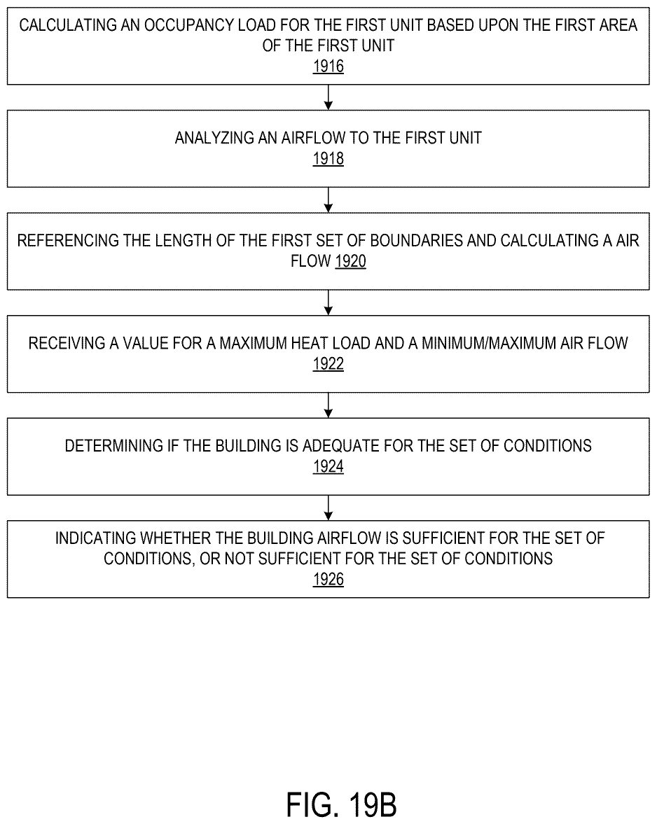

Referring now to FIGS. 19A and 19B, these flowcharts describe a method, according to some embodiments of the present disclosure. The method involves a series of steps carried out by one or more controllers that execute specific operations or actions. The AI engine integrated into the controller performs a detailed analysis of design plans, assesses airflow-related components, and determines adherence with relevant building deployment objectives, meets all necessary ventilation, heating, and cooling requirements. According to the present invention a method of practice may include the steps of:

At step 1902, the method begins by receiving into a controller a design plan representing at least a portion of a building. This design plan may be an architectural blueprint, a digital file such as CAD or BIM (Building Information Modeling), or any other format that provides a detailed depiction of the building's layout, including the placement of HVAC (Heating, Ventilation, and Air Conditioning) systems, windows, doors, ducts, and other relevant components. For example, the design plan may show a floor layout of a hospital ward, indicating the location of central air ducts, vents, and patient beds, which may be required for determining adherence with airflow regulations.

At step 1904, the method may include representing a portion of the design plan as multiple dynamic components. Each dynamic component corresponds to an airflow-related element within the building, such as air ducts, vents, windows, or any architectural feature that influences air movement. The AI engine processes these components, allowing for the analysis of their spatial relationships, dimensions, and placement within the design. This step is useful for enabling the system to understand how each component interacts with others and how they collectively contribute to the overall airflow in the building.

At step 1906, the method may include generating a first interactive user interface including at least some of the multiple dynamic components representing the portion of the design plan, each dynamic component including a parameter changeable via the interactive user interface. For example, a user may adjust the size or location of a vent or modify the airflow rate through a particular duct. Architects, engineers, and other stakeholders through the interactive user interface may visualize and modify the design in real-time and AI engine determines that any changes made by the users align with airflow requirements and adherence with building deployment objectives.

At step 1908, the method may include arranging the dynamic components included in the first interactive user interface to form a first set of boundaries, the first set of boundaries including a respective length and area, and the first set of boundaries defining at least a portion of a first unit.

At step 1910, the method may include generating a dominance relationship between the first unit and an area separated from the first unit by the first set of boundaries. This dominance relationship helps the AI engine prioritize certain areas within the building based on their importance or occupancy. For example, a high-traffic area like an emergency room may require more stringent airflow adherence checks than a storage room. AI engine, based on dominance relationships, prioritizes an emergency area so that it can receive the necessary airflow while maintaining overall adherence with building deployment objectives.

At step 1912, the method may include referencing the dominance relationship, and allocating a portion of an area included in the first set of boundaries to the first unit. For example, if the emergency room is identified as the dominant unit, the AI engine may recommend allocating additional airflow from adjacent areas so that the room maintains proper ventilation and air quality.

At step 1914, the method may include generating a first area of the first unit based upon the first set of boundaries and the portion of an area included in the first set of boundaries that may be allocated to the first unit. The AI engine calculates the area of the unit, and takes into account the boundaries and any allocated space. This calculated area is used to determine if the airflow requirements for the unit have been met considering both the spatial and ventilation needs of the building.

At step 1916, the method may include calculating an occupancy load for the first unit based upon the first area of the first unit. The AI engine determines the maximum number of occupants that the unit can safely accommodate, considering the area and airflow capacity. For example, a hospital ward designed for a specific number of patients must have sufficient airflow to maintain air quality and comfort, especially in high-occupancy scenarios.

In some embodiments, at step 1918, the method may include identifying and analyzing an airflow to the first unit. The AI engine evaluates whether the airflow provided to the unit is sufficient for its occupancy load and intended use. For example, in a hospital ward, the AI engine may analyze whether the airflow meets the requirements for infection control and patient comfort.

At step 1920, the method may include, with the controller, referencing the length of the first set of boundaries and calculating an airflow for the first unit. The AI engine uses the boundary length and other parameters to determine the airflow rate, to meet the necessary building deployment objectives for ventilation. For example, the AI engine may calculate the airflow rate required to achieve a certain number of air changes per hour (ACH) in a patient room (or other defined space).

At step 1922, the method may include receiving a value for including a maximum heat load and a minimum and/or maximum airflow to be sufficient for a set of conditions. The AI engine uses these values to compare the building design with specific airflow and occupancy requirements, adjusting the design as necessary to comply with relevant building deployment objectives.

In some embodiments, at step 1924, the method may include referencing the heat load first unit and the airflow, determining if the building meets the set of conditions. The AI engine may identify areas where the airflow does not meet building deployment objective requirements and suggest modifications to the design.

At step 1926, the method may include indicating in the interactive user interface indicating whether the building may be in compliance with the set of conditions, or not in compliance with the set of conditions. If the design is not in compliance, the AI engine provides recommendations for changes that will make the design meet a desired objective. This feedback is invaluable for architects and engineers, allowing them to make necessary adjustments before construction begins, in order for the building to meet airflow-related building deployment objectives.

In some embodiments, the method may additionally include determining a scale of the components included in the design plan and/or referencing the dynamic components and determining a width of one or more of: an airflow pathway, and a window.

In some embodiments, the method may also include training the AI engine via a human identifying portions of the design plan as a particular type of component and associating a pattern of pixels with the portions of the design plan.

Another aspect may include generating suggested modifications to a design plan in order to meet compliance with a set of conditions. Modifications may include, by way of non-limiting example, including a doorway, changing a length of a wall, widening the path of egress, eliminating a dead end, such as, for example, via inclusion of an additional wall.

In some embodiments, some steps of the processes described herein may be repeated for multiple units included in a design plan. For example, the steps of: arranging the dynamic components included in the first interactive user interface to form a first set of boundaries, the first set of boundaries comprising a respective length and area, and said first set of boundaries defining at least a portion of a first unit; generating a dominance relationship between the first unit and an area separated from the first unit by the first set of boundaries; referencing the dominance relationship, allocating a portion of an area included in the first set of boundaries to the first unit; generating a first area of the first unit based upon the first set of boundaries and the portion of an area included in the first set of boundaries that is allocated to the first unit; calculating an occupancy load for the first unit based upon the first area of the first unit; identifying a point of egress in the design plan; and with the controller, referencing the length of the first set of boundaries and calculating a travel distance to the point of egress from a designated point included in the first unit; may be repeated multiple times for multiple respective units.

Vertical openings are generally any openings between two or more floors (stories) in a building. They have a variety of uses and functions including, but not limited to: movement of occupants between floors during normal use and emergency use; exit stairs; convenience stairs/opening (limited to two floors); elevator shafts; installation of building services and features that serve multiple floors; plumbing systems; electrical systems (including telecom, data); heating/air conditioning ducts; fire protection equipment; trash and linen chutes; expansion/seismic joint; aesthetic value; communicating space; and atriums.

Some vertical openings have the same fundamental requirement regarding fire resistance rated construction. Other types of vertical opening have special rules that don't require enclosure but rather layer in added fire protection and safety features. The present invention allows for AI and machine learning processes to determine an existence of vertical openings, and automated processes apply an appropriate set of rules to determined vertical openings.

### Glossary:

“Artificial Intelligence” as used herein means machine-based decision making and machine learning including, but not limited to: supervised and unsupervised recognition of patterns, classification, and numerical regression. Supervised learning of patterns includes a human indicating that a pattern (such as a pattern of dots formed via the rasterization of a two-dimensional image) is representative of a line, polygon, shape, angle or other geometric form, or an architectural aspect, unsupervised learning can include a machine finding a pattern submitted for analysis. One or both may use mathematical optimization, formal logic, artificial neural networks, and methods based on one or more of: statistics, probability, linear regression, linear algebra, and/or matrix multiplication.

“AI Engine” as used herein an AI Engine (sometimes referred to as an AI model) refers to methods and apparatus for applying artificial intelligence and/or machine learning to a task performed by a controller. In some embodiments, a controller may be operative via executable software to act as an AI engine capable of recognizing aspects and/or tally aspects of a design plan that are relevant to generating an estimate for performing projects included in construction of a building or other activities related to construction of a building.

“Computer Aided Design,” sometimes referred to as “CAD,” as used herein shall mean the use of automation for the creation, modification, analysis, or optimization of a design plan or design plan file.

“Airflow” as used herein, means the ability of atmospheric gases to freely travel.

“Vector File” as used herein a vector file is a computer graphic that uses mathematical formulas to render its image. In some embodiments, a sharpness of a vector file will be agnostic to size within a range of sizes viewable on smart device and personal computer display screens.

commonly, a vector image includes segments with two points. The two points create a path. Paths can be straight or curved. Paths may be connected at connection points. Connected paths form more complex shapes. More points may be used to form longer paths or closed shapes. Each path, curve, or shape has its own formula, so they can be sized up or down and the formulas will maintain the crispness and sharp qualities of each path.

A vector file may include connected paths that may be viewed as graphics. The paths that make up the graphics may include geometric shapes or portions of geometric shapes, such as: circles, ellipsis, Bezier curves, squares, rectangles, polygons, and lines. More sophisticated designs may be created by joining and intersecting shapes and/or paths. Each shape may be treated as an individual object within the larger image. Vector graphics are scalable, such that they may be increased or decreased without significantly distorting the image.

The methods and apparatus of the present invention are presented herein generally, by way of example, to actions, processes, and deliverables important to industries such as the construction industry, by generating improved determination of compliance with specified building deployment objectives, based on inputted design plans, floor plans or other construction related diagrams, however, design plans may include almost any artifact that may be converted to a pixel pattern.

Some specific embodiments of the present invention include input of a design plan (e.g., a blueprint, design plan floorplan, or other two-dimensional artifact) so that it may be analyzed using artificial intelligence and used to generate a determination of compliance with specified conditions included in one or multiple building deployment objectives in a short time period. However, unless expressly indicated in an associated claim, the present invention is not limited to analysis of design plans for any particular industry. The examples provided herein are illustrative in nature and show that the present invention may use controllers and/or neural networks and artificial-intelligence (AI) techniques to identify aspects of a building described by a design plan and specify quantities for variables used to generate a bid or other proposal for completion of a project (or some subset of a project) represented by the design plan. For example, aspects of a building that are identified may include one or more of: walls or other boundaries; doorways; doors; plumbing; plumbing fixtures; hardware; fasteners; wall board; flooring; a level of complexity and other variables ascertainable via analysis of the design plan. AI analysis provides values for variables used in estimations involved in a project bidding process or related activity.

The present invention provides for systems of one or more computers that can be configured to perform particular operations or actions by virtue of having software, firmware, hardware, or a combination of them installed on the system that in operation causes or cause the system to perform the actions. One or more computer programs can be configured to perform artificial intelligence operations or actions by virtue of including instructions that, when executed by data processing apparatus, cause the apparatus to perform the actions.

### Conclusion

A number of embodiments of the present disclosure have been described. While this specification contains many specific implementation details, there should not be construed as limitations on the scope of any disclosures or of what may be claimed, but rather as descriptions of features specific to particular embodiments of the present disclosure. While embodiments of the present disclosure are described herein by way of example using several illustrative drawings, those skilled in the art will recognize the present disclosure is not limited to the embodiments or drawings described. It should be understood that the drawings, and the detailed description thereto are not intended to limit the present disclosure to the form disclosed, but to the contrary, the present disclosure is to cover all modification, equivalents and alternatives falling within the spirit and scope of embodiments of the present disclosure as defined by the appended claims.

The headings used herein are for organizational purposes only and are not meant to be used to limit the scope of the description or the claims. As used throughout this application, the word “may” be used in a permissive sense (i.e., meaning having the potential to), rather than the mandatory sense (i.e., meaning must). Similarly, the words “include,” “including,” and “includes” mean including but not limited to. To facilitate understanding, like reference numerals have been used, where possible, to designate like elements common to the figures.

The phrases “at least one,” “one or more,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C” and “A, B, and/or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted the terms “comprising,” “including,” and “having” can be used interchangeably.

Certain features that are described in this specification in the context of separate embodiments can also be implemented in combination in a single embodiment. Conversely, various features that are described in the context of a single embodiment can also be implemented in combination in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while method steps may be depicted in the drawings in a particular order, this should not be understood as requiring that such operations be performed in the particular order shown or in a sequential order, or that all illustrated operations be performed, to achieve desirable results.

Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order show, or sequential order, to achieve desirable results. In certain implementations, multitasking and parallel processing may be advantageous. Nevertheless, it will be understood that various modifications may be made without departing from the spirit and scope of the claimed disclosure.

1. A method for analyzing airflow compliance with a relevant building deployment objective using artificial intelligence to assess a design plan, the method comprising the steps of:
a. receiving, by a controller, a design plan of at least a portion of a building;
b. representing, by the controller, the design plan as multiple dynamic components;
c. generating, by the controller, a first interactive user interface comprising at least some of the multiple dynamic components representing the portion of the building, each dynamic component including a parameter changeable via the first interactive user interface;
d. arranging, by the controller, the multiple dynamic components included in the first interactive user interface to form a first set of boundaries, the first set of boundaries comprising a respective first length and a first area, and the first set of boundaries defining at least a portion of a first unit;
e. identifying, by an artificial intelligence (AI) engine operative on the controller, types and quantities of airflow fixtures positioned within the first unit;
f. determining a set of conditions related to the airflow fixtures required by the relevant building deployment objective based upon a proposed use for the building and a type of the first unit within the building;
g. by referencing the set of conditions, calculating, by the AI engine, an airflow requirement for the first unit based upon the first area of the first unit, wherein calculating the airflow requirement further comprises identifying the types and quantities of the airflow fixtures required for the first unit;
h. comparing the airflow fixtures positioned within the first unit with the airflow fixtures required for the first unit; and
i. indicating in the first interactive user interface whether the building meets a set of objectives for the building.

2. The method of claim 1, further comprising the step of: generating, by the controller, a dominance relationship between the first unit and a second area separated from the first unit by the first set of boundaries.

3. The method of claim 2, further comprising the step of: referencing, by the controller, the dominance relationship, allocating a portion of a third area included in the first set of boundaries to the first area of the first unit.

4. The method of claim 1, wherein the AI engine predicts an occupancy level for the first unit, and the method further comprising determining the types and quantities of the airflow fixtures required for the first unit based on the predicted occupancy level for the first unit.

5. The method of claim 4, wherein the AI engine predicts the occupancy level for the first unit based on one or more of: the first area of the first unit, the proposed use for the building, and the type of the first unit.

6. The method of claim 1, wherein the AI engine identifies the types of the airflow fixtures within the first unit, wherein the identified airflow fixtures including one or more of: air supply vents, air return vents, exhaust fans, ceiling fans, windows, and air purifiers.

7. The method of claim 6, wherein the AI engine further identifies a placement and orientation of the identified airflow fixtures within the first unit.

8. The method of claim 7, further comprising the step of: determining, by the AI engine, spatial relationships and dimensions associated with the identified airflow fixtures, wherein the step of determining the spatial relationships further comprises one or more of: calculating distances between the identified airflow fixtures, calculating distances of the identified airflow fixtures from walls, calculating distances of the identified airflow fixtures from non-airflow fixtures, calculating heights of the identified airflow fixtures from floor level, and determining clearances around the identified airflow fixtures.

9. The method of claim 8, wherein the AI engine identifies one or more obstructions to the identified airflow fixtures caused by the non-airflow fixtures, including one or more of: a furniture, a wall, or a partition for a space.

10. The method of claim 1, wherein the AI engine compares the airflow fixtures with historical data from similar building designs to predict potential issues.

11. The method of claim 1, wherein the AI engine cross-references the design plan with a database of building deployment objectives that is periodically updated.

12. The method of claim 11, wherein the AI engine automatically updates the set of conditions when the database of building deployment objectives is updated.

13. The method of claim 1, wherein the AI engine determines whether the airflow fixtures meet energy efficiency standards as required by the relevant building deployment objective.

14. The method of claim 1, wherein the parameter changeable via the first interactive user interface includes at least one of: a location of an airflow fixture, a type of the airflow fixture, a height of the airflow fixture from floor level, a distance of the airflow fixture from a wall, and a dimension of the airflow fixture.

15. The method of claim 1, wherein the AI engine identifies the airflow fixtures within the first unit by recognizing patterns based on predetermined templates stored in a database accessible by the AI engine.

16. The method of claim 1, wherein the proposed use for the building is selected from a group consisting of: residential, commercial, industrial, and institutional.

17. The method of claim 1, wherein the set of conditions related to the airflow fixtures comprises minimum and maximum requirements for air supply and exhaust rates for the proposed use of the building, or for the type of the first unit.

18. The method of claim 17, wherein the set of conditions further comprises spacing requirements between the airflow fixtures as specified by the relevant building deployment objective.

19. The method of claim 1, wherein the first interactive user interface provides visual alerts or color-coded indicators to signify compliance or non-compliance with the set of conditions.

20. The method of claim 1, further comprising the step of: providing, by the AI engine, automated suggestions for design modifications to address any identified non-compliance with the set of conditions.

21. The method of claim 20, wherein the automated suggestions comprise options including one more of: adding a new airflow fixture, relocating an airflow fixture, changing a type of the airflow fixture, and adjusting spacing between two airflow fixtures to meet the set of conditions.

22. The method of claim 1, further comprising the step of: determining dominance ranks for two or more spaces within the portion of the building.

23. The method of claim 22, further comprising the step of: analyzing, by the AI engine, the airflow compliance based on the determined dominance ranks for the two or more spaces within the portion of the building.

24. The method of claim 23, wherein the AI engine prioritizes an airflow compliance analysis for spaces with higher dominance ranks.

25. The method of claim 1, wherein the airflow fixtures comprise an HVAC system, and the AI engine analyzes the airflow compliance related to a configuration and performance of the HVAC system.

26. The method of claim 1, wherein a duct layout includes one or both of: air supply ducts and return ducts, and the AI engine analyzes routing, diameter, and connections of these ducts to determine compliance with the relevant building deployment objective.

27. The method of claim 1, wherein the AI engine identifies a need for an additional or upgraded airflow fixture based on the airflow fixtures.

28. The method of claim 1, wherein the step of identifying the airflow fixtures positioned within the first unit further comprises referencing a database of airflow fixtures.

29. The method of claim 28, wherein the database of airflow fixtures includes data related to one or more of: types, dimensions, operational characteristics, placement guidelines, materials, and costs for the airflow fixtures, and the AI engine uses said data to accurately classify and evaluate the identified airflow fixtures.

30. The method of claim 8, wherein the AI engine uses a scale to determine the spatial relationships and dimensions associated with the identified airflow fixtures.

31. An apparatus for analyzing airflow compliance with a relevant building deployment objective using artificial intelligence to assess a design plan, the apparatus comprising:
a. a display screen;
b. a digital storage medium comprising an executable software code; and
c. a controller including a processor, wherein the executable software code, when executed by the processor, causes the processor to:
i. receive, by the controller, a design plan of a portion of a building;
ii. represent, by the controller, the design plan as multiple dynamic components;
iii. generate, by the controller, a first interactive user interface on the display screen, the first interactive user interface comprising at least some of the multiple dynamic components representing the portion of the building, each dynamic component including a parameter changeable via the first interactive user interface;
iv. arrange, by the controller, the multiple dynamic components included in the first interactive user interface to form a first set of boundaries, the first set of boundaries comprising a respective first length and a first area, and the first set of boundaries defining at least a portion of a first unit;
v. identify, by an artificial intelligence (AI) engine operative on the controller, types and qualities of airflow fixtures positioned within the first unit;
vi. determine a set of conditions related to the airflow fixtures required by the relevant building deployment objective based upon a proposed use for the building and a type of the first unit within the building;
vii. by referencing the set of conditions, calculate, by the AI engine, an airflow requirement for the first unit based upon the-first area of the first unit, wherein calculating the airflow requirement further comprises determining types and quantities of the airflow fixtures required for the first unit;
viii. compare the airflow fixtures positioned within the first unit with the airflow fixtures required for the first unit; and
ix. indicate in the first interactive user interface whether the building is in compliance with the set of conditions relating to the airflow compliance for the building, or not in compliance with the set of conditions.

32. The apparatus of claim 31, wherein the AI engine cross-references the design plan with an Airflow Fixture Database to ascertain types and quantities of the airflow fixtures positioned within the first unit.

33. The apparatus of claim 31, wherein the AI engine further identifies spatial relationships between the airflow fixtures and calculates distances between them to assess airflow efficiency within the first unit.

34. The apparatus of claim 31, wherein the AI engine is configured to analyze an impact of non-airflow fixtures on the airflow compliance, including determining whether any non-airflow fixtures obstruct the airflow fixtures.

35. The apparatus of claim 31, further comprising a Non-Airflow Fixture Database, wherein the AI engine references the Non-Airflow Fixture Database to identify non-airflow fixtures within the first unit.

36. The apparatus of claim 31, wherein the AI engine determines whether the identified airflow fixtures meet energy efficiency standards as required by the relevant building deployment objective.

37. The apparatus of claim 31, wherein the AI engine is configured to predict potential airflow issues based on historical data from similar building designs stored in a building deployment objective database accessible to the controller.

38. The apparatus of claim 31, wherein the AI engine is configured to suggest additional airflow fixtures if one or more of the identified airflow fixtures do not satisfy the calculated airflow requirement for the first unit.

39. The apparatus of claim 31, wherein the AI engine further analyzes ductwork associated with the identified airflow fixtures to determine compliance with duct size and layout requirements specified in the relevant building deployment objective.

40. The apparatus of claim 31, wherein the AI engine determines whether the identified airflow fixtures are appropriately spaced according to the relevant building deployment objective for the type of the first unit.
